(19) United States
(12) Patent Application Publication
(10) Pub. No.: US 2023/0307550 A1
(43) Pub. Date: Sep. 28, 2023

(54) SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Yasumasa YAMANE, Atsugi (JP); Yoshinori ANDO, Atsugi (JP); Shigeki KOMORI, Isehara (JP); Ryota HODO, Atsugi (JP); Tatsuya ONUKI, Atsugi (JP); Shinya SASAGAWA, Chigasaki (JP)

(21) Appl. No.: 18/020,758

(22) PCT Filed: Aug. 17, 2021
(86) PCT No.: PCT/IB2021/057538

§ 371 Date: Feb. 10, 2023

(30) Foreign Application Priority Data
Aug. 27, 2020 (JP) 2020-143470

(51) Int. Cl. H01L 29/786

(52) U.S. Cl. CPC H01L 29/78693

(57) ABSTRACT

A semiconductor device with a small variation in transistor characteristics is provided. The semiconductor device includes a first device layer to an n-th (n is a natural number of 2 or more) device layer, each of which includes a first barrier insulating film, a second barrier insulating film, a third barrier insulating film, an oxide semiconductor device, a first conductor, and a second conductor. In each of the first device layer to the n-th device layer, the oxide semiconductor device is placed over the first barrier insulating film, the second barrier insulating film is placed to cover the oxide semiconductor device, the first conductor is placed so as to be electrically connected to the oxide semiconductor device through an opening formed in the second barrier insulating film, the second conductor is placed over the first conductor, the third barrier insulating film is placed over the second conductor and the second barrier insulating film, and the first barrier insulating film to the third barrier insulating film have a function of inhibiting diffusion of hydrogen.

### TECHNICAL FIELD

One embodiment of the present invention relates to a transistor, a semiconductor device, and an electronic device. Another embodiment of the present invention relates to a method for manufacturing a semiconductor device. Another embodiment of the present invention relates to a semiconductor wafer and a module.

In this specification and the like, a semiconductor device generally means a device that can function by utilizing semiconductor characteristics. A semiconductor element such as a transistor, a semiconductor circuit, an arithmetic device, and a storage device are each an embodiment of a semiconductor device. It can be sometimes said that a display device (a liquid crystal display device, a light-emitting display device, and the like), a projection device, a lighting device, an electro-optical device, a power storage device, a storage device, a semiconductor circuit, an imaging device, an electronic device, and the like include a semiconductor device.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

In recent years, semiconductor devices have been developed to be mainly used for LSI, CPUs, memories, and the like. A CPU is an assembly of semiconductor elements each including a semiconductor integrated circuit (including at least a transistor and a memory) which is taken out from a semiconductor wafer and provided with an electrode serving as a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) or an image display device (also simply referred to as a display device). A silicon-based semiconductor material is widely known as a semiconductor thin film applicable to the transistor and further, an oxide semiconductor has been attracting attention as another material.

It is known that a transistor using an oxide semiconductor has an extremely low leakage current in a non-conduction state. For example, a low-power-consumption CPU utilizing a feature of a low leakage current of the transistor using an oxide semiconductor is disclosed (see Patent Document 1). Furthermore, for example, a storage device that can retain stored contents for a long time by utilizing a feature of a low leakage current of the transistor using an oxide semiconductor is disclosed (see Patent Document 2).

In recent years, demand for an integrated circuit with higher density has risen with reductions in size and weight of electronic devices. Furthermore, the productivity of a semiconductor device including an integrated circuit is desired to be improved.

### REFERENCE

### Patent Document

[Patent Document 1] Japanese Published Patent Application No. 2012-257187
[Patent Document 2] Japanese Published Patent Application No. 2011-151383

### Non-Patent Document

### Summary of the Invention

### Problems to be Solved by the Invention

An object of one embodiment of the present invention is to provide a semiconductor device with a small variation in transistor characteristics. Another object of one embodiment of the present invention is to provide a semiconductor device with favorable electric characteristics. Another object of one embodiment of the present invention is to provide a semiconductor device with favorable reliability. Another object of one embodiment of the present invention is to provide a semiconductor device with a high on-state current. Another object of one embodiment of the present invention is to provide a semiconductor device with a high field-effect mobility. Another object of one embodiment of the present invention is to provide a semiconductor device with favorable frequency characteristics. Another object of one embodiment of the present invention is to provide a semiconductor device that can be miniaturized or highly integrated. Another object of one embodiment of the present invention is to provide a semiconductor device that can be downsized. Another object of one embodiment of the present invention is to provide a semiconductor device with low power consumption. Another object of one embodiment of the present invention is to provide a semiconductor device with a novel structure. Another object of one embodiment of the present invention is to provide a method for manufacturing any of the above semiconductor devices.

Note that the description of these objects does not preclude the existence of other objects. In one embodiment of the present invention, there is no need to achieve all these objects. Other objects are apparent from and can be derived from the description of the specification, the drawings, the claims, and the like.

### Means for Solving the Problems

One embodiment of the present invention is a semiconductor device including a first device layer to an n-th (n is a natural number of 2 or more) device layer which are stacked over a substrate in order. Each of the first device layer to the n-th device layer includes a first barrier insulating film, a second barrier insulating film, a third barrier insulating film, an oxide semiconductor device, a first conductor, and a second conductor. In each of the first device layer to the n-th device layer, the oxide semiconductor device is placed over the first barrier insulating film, the second barrier insulating film is placed to cover the oxide semiconductor device, the first conductor is placed so as to be electrically connected to the oxide semiconductor device through an opening formed in the second barrier insulating film, the second conductor is placed over the first conductor, the third barrier insulating film is placed over the second conductor and the second barrier insulating film, and the first barrier insulating film to the third barrier insulating film have a function of inhibiting diffusion of hydrogen.

In the above, the second barrier insulating film is preferably in contact with the first barrier insulating film in a region where the second barrier insulating film does not overlap with the oxide semiconductor device.

Another embodiment of the present invention is a semiconductor device including a first device layer to an n-th (n is a natural number of 2 or more) device layer which are stacked over a substrate in order. Each of the first device layer to the n-th device layer includes a first barrier insulating film, a second barrier insulating film, a third barrier insulating film, an oxide semiconductor device, a first conductor, and a second conductor. In the first device layer to the n-th device layer, the oxide semiconductor device is placed over the first barrier insulating film, the second barrier insulating film is placed over the oxide semiconductor device, the first conductor is placed so as to be electrically connected to the oxide semiconductor device through an opening formed in the second barrier insulating film, the second conductor is placed over the first conductor, the third barrier insulating film is placed over the second conductor and the second barrier insulating film, and the first barrier insulating film to the third barrier insulating film have a function of inhibiting diffusion of hydrogen. An opening reaching the first barrier insulating film in the first device layer is formed in the first device layer to the n-th device layer. The opening is provided so as to surround the oxide semiconductor devices in the first device layer to the n-th device layer. The second barrier insulating film in the n-th device layer is provided to cover the oxide semiconductor devices in the first device layer to the n-th device layer.

In the above, the second barrier insulating film in the n-th device layer is preferably in contact with the first barrier insulating film in the first device layer in a region where the second barrier insulating film in the n-th device layer does not overlap with the oxide semiconductor device in the first device layer to the n-th device layer.

In the above, the first barrier insulating film to the third barrier insulating film are preferably silicon nitride.

In the above, preferably, the third barrier insulating film includes a first layer and a second layer over the first layer, and the first layer has a lower hydrogen concentration than the second layer. In the above, the first layer is preferably an insulating film formed by a sputtering method. In the above, the second layer is preferably an insulating film formed by a PEALD method.

Another embodiment of the present invention is a semiconductor device including a first device layer to an n-th (n is a natural number of 2 or more) device layer which are stacked over a substrate in order. Each of the first device layer to the n-th device layer includes an oxide semiconductor device, a first conductor, and a second conductor. The first device layer includes a first barrier insulating film under the oxide semiconductor device. The n-th device layer includes a second barrier insulating film over the second conductor. The first barrier insulating film and the second barrier insulating film have a function of inhibiting diffusion of hydrogen. In each of the first device layer to the n-th device layer, the first conductor is placed over the oxide semiconductor device so as to be electrically connected to the oxide semiconductor device, and the second conductor is placed over the first conductor. An opening reaching the first barrier insulating film in the first device layer is formed in the first device layer to the n-th device layer. The opening is provided so as to surround the oxide semiconductor device in the first device layer to the n-th device layer. The second barrier insulating film in the n-th device layer is provided to cover the oxide semiconductor device in the first device layer to the n-th device layer.

In the above, the second barrier insulating film in the n-th device layer is preferably in contact with the first barrier insulating film in the first device layer in a region where the second barrier insulating film in the n-th device layer does not overlap with the oxide semiconductor device in the first device layer to the n-th device layer.

In the above, the first barrier insulating film and the second barrier insulating film are preferably silicon nitride.

In the above, preferably, the second barrier insulating film includes a first layer and a second layer over the first layer, and the first layer has a lower hydrogen concentration than the second layer. In the above, the first layer is preferably an insulating film formed by a sputtering method. In the above, the second layer is preferably an insulating film formed by a PEALD method.

In the above, the first conductor is preferably placed so as to be embedded in an interlayer insulating film formed over the oxide semiconductor device.

In the above, the substrate is preferably a silicon substrate. Also in the above, a transistor may be formed on the substrate.

In the above, the oxide semiconductor film included in the oxide semiconductor device preferably includes one or more of In, Ga, and Zn.

### Effect of the Invention

According to one embodiment of the present invention, a semiconductor device with a small variation in transistor characteristics can be provided. According to another embodiment of the present invention, a semiconductor device having favorable electrical characteristics can be provided. According to another embodiment of the present invention, a semiconductor device with favorable reliability can be provided. According to another embodiment of the present invention, a semiconductor device with a high on-state current can be provided. According to another embodiment of the present invention, a semiconductor device with a high field-effect mobility can be provided. According to another embodiment of the present invention, a semiconductor device with favorable frequency characteristics can be provided. According to another embodiment of the present invention, a semiconductor device that can be miniaturized or highly integrated can be provided. According to another embodiment of the present invention, a semiconductor device that can be downsized can be provided. According to another embodiment of the present invention, a semiconductor device with low power consumption can be provided. According to another embodiment of the present invention, a semiconductor device with a novel structure can be provided. According to another embodiment of the present invention, a method for manufacturing any of the above semiconductor devices can be provided.

Note that the description of these effects does not preclude the existence of other effects. One embodiment of the present invention does not have to have all these effects. Other effects will be apparent from and can be derived from the description of the specification, the drawings, the claims, and the like.

### BRIEF DESCRIPTION OF THE DRAWINGS

FIG. 1A to FIG. 1C are schematic diagrams of a semiconductor device of one embodiment of the present invention.

FIG. 2A to FIG. 2C are schematic diagrams of a semiconductor device of one embodiment of the present invention.

FIG. 3 is a schematic diagram of a semiconductor device of one embodiment of the present invention.

FIG. 4 is a schematic diagram of a semiconductor device of one embodiment of the present invention.

FIG. 5 is a schematic diagram of a semiconductor device of one embodiment of the present invention.

FIG. 6A to FIG. 6C are schematic diagrams illustrating a manufacturing method of a semiconductor device of one embodiment of the present invention.

FIG. 7A to FIG. 7C are schematic diagrams illustrating a manufacturing method of a semiconductor device of one embodiment of the present invention.

FIG. 8A to FIG. 8E are schematic diagrams illustrating a manufacturing method of a semiconductor device of one embodiment of the present invention.

FIG. 9A to FIG. 9C are schematic diagrams illustrating a manufacturing method of a semiconductor device of one embodiment of the present invention.

FIG. 10A and FIG. 10B are schematic diagrams illustrating a manufacturing method of a semiconductor device of one embodiment of the present invention.

FIG. 11A to FIG. 11C are schematic diagrams illustrating a manufacturing method of a semiconductor device of one embodiment of the present invention.

FIG. 12A and FIG. 12B are schematic diagrams illustrating a manufacturing method of a semiconductor device of one embodiment of the present invention.

FIG. 13A is a top view of a semiconductor device of one embodiment of the present invention.

FIG. 13B is a cross-sectional view of the semiconductor device of one embodiment of the present invention.

FIG. 14A and FIG. 14B are cross-sectional views of semiconductor devices of one embodiment of the present invention.

FIG. 15A is a diagram showing the classification of crystal structures of IGZO. FIG. 15B is a graph showing an XRD spectrum of a CAAC-IGZO film. FIG. 15C is an image showing a nanobeam electron diffraction pattern of a CAAC-IGZO film.

FIG. 16A is a plan view of a semiconductor device of one embodiment of the present invention.

FIG. 16B and FIG. 16C are cross-sectional views of the semiconductor device of one embodiment of the present invention.

FIG. 17 is a cross-sectional view illustrating a structure of a storage device of one embodiment of the present invention.

FIG. 18 is a cross-sectional view illustrating a structure of a storage device of one embodiment of the present invention.

FIG. 19A is a block diagram illustrating a structure example of a storage device of one embodiment of the present invention. FIG. 19B is a perspective view illustrating a structure example of the storage device of one embodiment of the present invention.

FIG. 20A to FIG. 20H are circuit diagrams each illustrating a structure example of a storage device of one embodiment of the present invention.

FIG. 21A is a block diagram illustrating a structure example of a semiconductor device. FIG. 21B is a perspective schematic view of the semiconductor device.

FIG. 22 is a schematic diagram illustrating a structure example of a semiconductor device.

FIG. 23 is a circuit diagram illustrating a structure example of a semiconductor device.

FIG. 24 is a timing chart showing a structure example of a semiconductor device.

FIG. 25 is a cross-sectional view illustrating a structure example of a semiconductor device.

FIG. 26 is a cross-sectional view illustrating a structure example of a semiconductor device.

FIG. 27 is a cross-sectional view illustrating a structure example of a semiconductor device.

FIG. 28A and FIG. 28B are schematic diagrams of a semiconductor device of one embodiment of the present invention.

FIG. 29A and FIG. 29B are diagrams illustrating examples of electronic components.

FIG. 30 is a diagram illustrating a structure example of a CPU.

FIG. 31A and FIG. 31B are diagrams illustrating a structure example of a CPU.

FIG. 32 is a diagram illustrating an operation example of a CPU.

FIG. 33A and FIG. 33B are diagrams illustrating a structure example of an integrated circuit.

FIG. 34A to FIG. 34E are schematic views of storage devices of one embodiment of the present invention.

FIG. 35A to FIG. 35H are views illustrating electronic devices of one embodiment of the present invention.

### MODE FOR CARRYING OUT THE INVENTION

Hereinafter, embodiments are described with reference to the drawings. Note that the embodiments can be implemented with many different modes, and it is readily understood by those skilled in the art that modes and details thereof can be changed in various ways without departing from the spirit and scope thereof. Thus, the present invention should not be interpreted as being limited to the description of the embodiments below.

In the drawings, the size, the layer thickness, or the region is exaggerated for clarity in some cases. Therefore, they are not necessarily limited to the illustrated scale. Note that the drawings schematically illustrate ideal examples, and embodiments of the present invention are not limited to shapes, values, and the like shown in the drawings. For example, in the actual manufacturing process, a layer, a resist mask, or the like might be unintentionally reduced in size by treatment such as etching, which might not be reflected in the drawings for easy understanding. Furthermore, in the drawings, the same reference numerals are used in common for the same portions or portions having similar functions in different drawings, and repeated description thereof is omitted in some cases. Furthermore, the same hatch pattern is used for the portions having similar functions, and the portions are not especially denoted by reference numerals in some cases.

In the case where a plurality of components are denoted by the same reference numerals, and, particularly when they need to be distinguished from each other, an identification sign such as “_1”, “_2”, “[n]”, or “[m,n]” is sometimes added to the reference numerals. For example, a second wiring GL is referred to as a wiring GL_2 in some cases.

Furthermore, especially in a top view (also referred to as a “plan view”), a perspective view, or the like, the description of some components might be omitted for easy understanding of the invention. In addition, some hidden lines and the like might not be illustrated.

The ordinal numbers such as “first” and “second” in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like do not sometimes correspond to the ordinal numbers that are used to specify one embodiment of the present invention.

Moreover, in this specification and the like, terms for describing arrangement, such as “over” and “under”, are used for convenience for describing the positional relation between components with reference to drawings. The positional relationship between components is changed as appropriate in accordance with the direction in which the components are described. Thus, without limitation to terms described in this specification, the description can be changed appropriately depending on the situation.

When this specification and the like explicitly state that X and Y are connected, for example, the case where X and Y are electrically connected, the case where X and Y are functionally connected, and the case where X and Y are directly connected are regarded as being disclosed in this specification and the like. Accordingly, without being limited to a predetermined connection relationship, for example, a connection relationship shown in drawings or texts, a connection relationship other than one shown in drawings or texts is regarded as being disclosed in the drawings or the texts. Here, X and Y each denote an object (e.g., a device, an element, a circuit, a wiring, an electrode, a terminal, a conductive film, or a layer).

In this specification and the like, a transistor is an element having at least three terminals including a gate, a drain, and a source. In addition, the transistor includes a region where a channel is formed (hereinafter also referred to as a channel formation region) between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which a current mainly flows.

Furthermore, functions of a source and a drain are sometimes interchanged with each other when transistors having different polarities are used or when the direction of current is changed in circuit operation, for example. Therefore, the terms “source” and “drain” can sometimes be interchanged with each other in this specification and the like.

Note that a channel length refers to, for example, the distance between a source (a source region or a source electrode) and a drain (a drain region or a drain electrode) in a region where a semiconductor (or a portion where current flows in a semiconductor when a transistor is in an on state) and a gate electrode overlap each other or a channel formation region in a top view of the transistor. Note that in one transistor, channel lengths in all regions do not necessarily have the same value. In other words, the channel length of one transistor is not fixed to one value in some cases. Thus, in this specification, the channel length is any one of the values, the maximum value, the minimum value, or the average value in a channel formation region.

A channel width refers to, for example, the length of a channel formation region in a direction perpendicular to a channel length direction in a region where a semiconductor (or a portion where current flows in a semiconductor when a transistor is in an on state) and a gate electrode overlap each other, or a channel formation region in a top view of the transistor. Note that in one transistor, channel widths in all regions do not necessarily have the same value. In other words, the channel width of one transistor is not fixed to one value in some cases. Thus, in this specification, the channel width is any one of the values, the maximum value, the minimum value, or the average value in a channel formation region.

Note that in this specification and the like, depending on the transistor structure, a channel width in a region where a channel is actually formed (hereinafter also referred to as an “effective channel width”) is sometimes different from a channel width shown in a top view of a transistor (hereinafter also referred to as an “apparent channel width”). For example, in a transistor whose gate electrode covers a side surface of a semiconductor, the effective channel width is larger than the apparent channel width, and its influence cannot be ignored in some cases. For example, in a miniaturized transistor whose gate electrode covers a side surface of a semiconductor, the proportion of a channel formation region formed in the side surface of the semiconductor is increased in some cases. In that case, the effective channel width is larger than the apparent channel width.

In such a case, the effective channel width is sometimes difficult to estimate by actual measurement. For example, estimation of an effective channel width from a design value requires assumption that the shape of a semiconductor is known. Accordingly, in the case where the shape of a semiconductor is not known exactly, it is difficult to measure the effective channel width accurately.

In this specification, the simple term “channel width” refers to an apparent channel width in some cases. Alternatively, in this specification, the simple term “channel width” refers to an effective channel width in some cases. Note that values of a channel length, a channel width, an effective channel width, an apparent channel width, and the like can be determined, for example, by analyzing a cross-sectional TEM image and the like.

Note that impurities in a semiconductor refer to, for example, elements other than the main components of a semiconductor. For example, an element with a concentration lower than 0.1 atomic % can be regarded as an impurity. When an impurity is contained, for example, the density of defect states in a semiconductor increases or the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. Note that water also serves as an impurity in some cases. In addition, oxygen vacancies (also referred to as V_{O}) are formed in an oxide semiconductor in some cases by entry of impurities, for example.

Note that in this specification and the like, silicon oxynitride is a material that contains more oxygen than nitrogen in its composition. Moreover, silicon nitride oxide is a material that contains more nitrogen than oxygen in its composition.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 800 and less than or equal to 100°. Accordingly, the case where the angle is greater than or equal to 850 and less than or equal to 950 is also included. Furthermore, “substantially perpendicular” indicates a state where two straight lines are placed at an angle greater than or equal to 600 and less than or equal to 120°.

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be called a transistor including a metal oxide or an oxide semiconductor.

In this specification and the like, “normally off” means that a drain current per micrometer of channel width flowing through a transistor when no potential is applied to a gate or the gate is supplied with a ground potential is 1×10⁻²⁰ A or lower at room temperature, 1×10⁻¹⁸ A or lower at 85° C., or 1×10⁻¹⁶ A or lower at 125° C.

### Embodiment 1

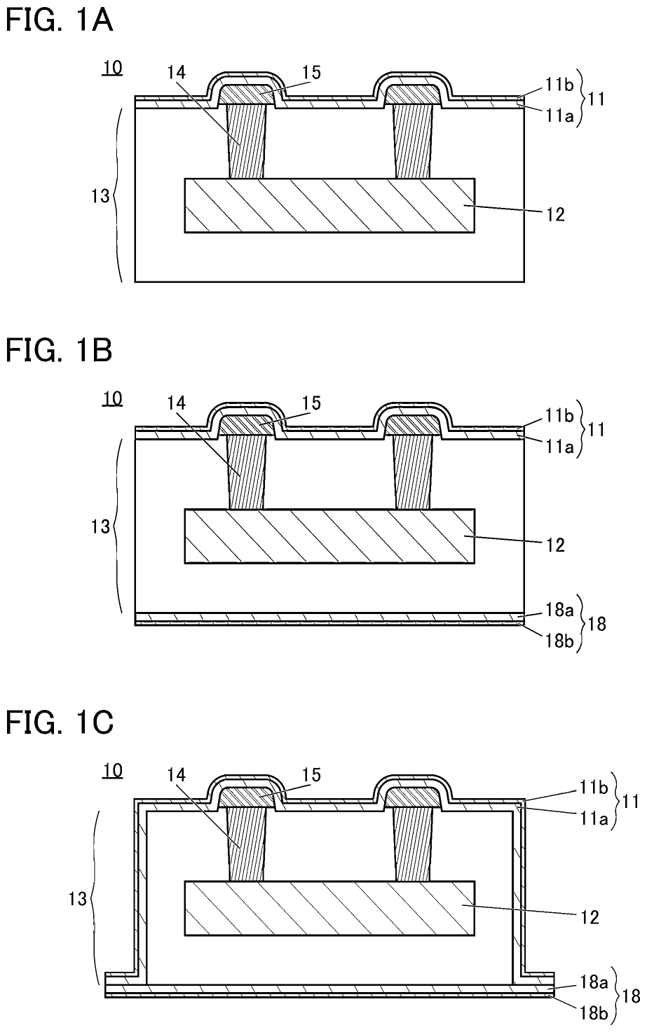

In this embodiment, an example of a semiconductor device of one embodiment of the present invention and a manufacturing method thereof will be described with reference to FIG. 1A to FIG. 12B.

### <Structure Example of Semiconductor Device>

FIG. 1A is a diagram schematically showing a semiconductor device 10 of one embodiment of the present invention. The semiconductor device 10 of one embodiment of the present invention includes a structure body 13 formed over a substrate (not illustrated), an oxide semiconductor element 12 included in the structure body 13, a conductor 14 positioned in an opening formed in the structure body 13, a conductor 15 positioned over the conductor 14, an insulator 11a positioned to cover the structure body 13, the conductor 14, and the conductor 15, and an insulator 11b over the insulator 11a. In this specification and the like, the oxide semiconductor element is referred to as an oxide semiconductor device in some cases.

The structure body 13 includes an interlayer insulating film stacked over and/or below the oxide semiconductor element 12. As the interlayer insulating film, for example, silicon oxide, silicon oxynitride, silicon oxide to which fluorine is added, silicon oxide to which carbon is added, silicon oxide to which carbon and nitrogen are added, porous silicon oxide, or the like can be used. Note that although FIG. 1A illustrates a state where the structure body 13 includes one oxide semiconductor element 12, the present invention is not limited thereto. The structure body 13 may include a plurality of oxide semiconductor elements 12.

The conductor 14 is positioned in the opening formed in the interlayer insulating film of the structure body 13. The opening reaches the oxide semiconductor element 12, so that the conductor 14 is electrically connected to the oxide semiconductor element 12. In other words, the conductor 14 serves as a plug electrically connecting the conductor 15 to the oxide semiconductor element 12. For example, as the conductor 14, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. Tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, and the like are preferable, for example, because they are conductive materials that are not easily oxidized or materials that maintain the conductivity even when absorbing oxygen.

The conductor 15 is provided in contact with the top surface of the conductor 14. A portion of the conductor 15 that does not overlap with the conductor 14 is in contact with an interlayer insulating film of the uppermost layer in the structure body 13. The conductor 15 functions as a wiring, an electrode, a terminal, or the like that is electrically connected to the oxide semiconductor element 12. The conductor 15 can be formed using a conductive material that can be used for the conductor 14. Note that although two conductors 14 and two conductors 15 are illustrated in FIG. 1A, the present invention is not limited to this structure. The numbers of the conductors 14 and the conductors 15 can be appropriately set depending on the structure of the oxide semiconductor element 12.

The oxide semiconductor element 12 includes at least one of circuit elements such as a switch, a transistor, a capacitor, an inductor, a resistor, and a diode. Furthermore, at least part of the circuit elements is provided with an oxide semiconductor film. For example, a transistor including a channel formation region in an oxide semiconductor film can be provided as the oxide semiconductor element 12. Note that specific examples of the oxide semiconductor element 12 and the like will be described in the following embodiment later.

As the oxide semiconductor film, it is preferable to use, for example, a metal oxide such as an In-M-Zn oxide containing indium, an element M, and zinc (the element M is one or more kinds selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, magnesium, and the like). An In—Ga oxide, an In—Zn oxide, or an indium oxide may be used as the oxide semiconductor film.

The above oxide semiconductor film has a band gap greater than or equal to 2 eV, preferably greater than or equal to 2.5 eV. The use of an oxide semiconductor film having such a wide band gap can reduce the leakage current flowing between the source and the drain of the transistor in an off state (hereinafter, the current is also referred to as “off-state current”).

The oxide semiconductor film preferably has crystallinity. It is particularly preferable to use a CAAC-OS (c-axis aligned crystalline oxide semiconductor) for the oxide semiconductor film.

The CAAC-OS is a metal oxide having a dense structure with high crystallinity and a small amount of impurities and defects (oxygen vacancy (V_{O}) or the like). In particular, after the formation of a metal oxide, heat treatment is performed at a temperature at which the metal oxide does not become a polycrystal (e.g., 400° C. to 600° C., inclusive), whereby a CAAC-OS having a dense structure with higher crystallinity can be obtained. When the density of the CAAC-OS is increased in such a manner, diffusion of impurities in the CAAC-OS can be further reduced.

On the other hand, a clear crystal grain boundary cannot be observed in the CAAC-OS; thus, it can be said that a reduction in electron mobility due to the crystal grain boundary is less likely to occur. Thus, an oxide semiconductor film including the CAAC-OS is physically stable. Therefore, the oxide semiconductor film including the CAAC-OS is resistant to heat and has high reliability.

An oxide semiconductor film with a low carrier concentration is preferably used for a channel formation region of the transistor. In the case where the carrier concentration of an oxide semiconductor film is lowered, the impurity concentration in the oxide semiconductor film is lowered to decrease the density of defect states. In this specification and the like, a state with a low impurity concentration and a low density of defect states is referred to as a highly purified intrinsic or substantially highly purified intrinsic state. Examples of impurities in the oxide semiconductor include hydrogen, nitrogen, an alkali metal, an alkaline earth metal, iron, nickel, and silicon.

In particular, hydrogen contained in the oxide semiconductor film reacts with oxygen bonded to a metal atom to be water, and thus sometimes causes formation of an oxygen vacancy (V_{O}) in the oxide semiconductor film. In some cases, a defect where hydrogen enters an oxygen vacancy (hereinafter, sometimes referred to as V_{O}H) functions as a donor and generates an electron serving as a carrier. In other cases, bonding of part of hydrogen to oxygen bonded to a metal atom generates electrons serving as carriers. Thus, a transistor using an oxide semiconductor film containing a large amount of hydrogen tends to have normally on characteristics (characteristics in which, even when no voltage is applied to the gate electrode, the channel exists and current flows through the transistor). Uneven in-plane distribution of hydrogen concentration may cause variation of electrical characteristics of transistors according to the distribution of hydrogen concentration. Moreover, hydrogen in an oxide semiconductor film is easily transferred by a stress such as heat or an electric field; thus, a large amount of hydrogen in an oxide semiconductor film might reduce the reliability of a transistor. Thus, impurities, oxygen vacancies, and V_{O}H are preferably reduced as much as possible in the region of the oxide semiconductor film where a channel is formed. In other words, it is preferable that the region of the oxide semiconductor film where a channel is formed have a reduced carrier concentration and be of an i-type (intrinsic) or substantially i-type.

However, even when an oxide semiconductor film in which the amount of hydrogen contained is reduced is formed, hydrogen is diffused into the oxide semiconductor film from the outside thereof in some cases. For example, in the case where an organic resin such as polyimide is provided over the oxide semiconductor element, hydrogen contained in the organic resin may be diffused.

In one embodiment of the present invention, the insulator 11a and the insulator 11b each of which functions as a barrier insulating film blocking impurities such as hydrogen are provided over the structure body 13 and the conductor 15. With the insulator 11a and the insulator 11b having such a function, the amount of impurities such as hydrogen diffusing into the oxide semiconductor film from above the structure body 13 can be reduced. Furthermore, the insulator 11a and the insulator 11b are provided to cover not only the structure body 13 but also the conductor 15 functioning as a wiring, whereby the amount of impurities such as hydrogen diffusing into the oxide semiconductor film through the conductor 15 and the conductor 14 can be reduced. Hereinafter, the insulator 11a and the insulator 11b are collectively referred to as an insulator 11, in some cases.

Note that in this specification, a barrier insulating film refers to an insulating film having a barrier property. A barrier property in this specification means a function of inhibiting diffusion of a targeted substance (also referred to as having low permeability). In addition, a barrier property in this specification means a function of trapping and fixing (also referred to as gettering) a targeted substance.

The insulator 11 is preferably an insulator having a function of inhibiting diffusion of hydrogen as described above, and preferably has lower permeability of hydrogen than at least one of interlayer insulating films included in the structure body 13. For the insulator 11, aluminum oxide, magnesium oxide, hafnium oxide, gallium oxide, indium gallium zinc oxide, silicon nitride, silicon nitride oxide, or the like can be used, for example. In particular, silicon nitride which has a high hydrogen barrier property is preferably used.

The insulator 11a is positioned in contact with the top surface of the uppermost interlayer insulating film of the structure body 13 and the top surface and side surface of the conductor 15. When the misaligned pattern of the conductor 15 or the like occurs, the insulator 11a is in contact with part of the conductor 14 in some cases. Thus, when the insulator 11a itself has a high hydrogen concentration, there is a risk of hydrogen diffusion into the oxide semiconductor element 12 through the interlayer insulating film, the conductor 14, or the conductor 15.

Thus, the hydrogen concentration in the insulator 11a is preferably low. The hydrogen concentration of the insulator 11a is preferably lower than that of at least one of the interlayer insulating films included in the structure body 13 and further preferably lower than that of the insulator 11b. Therefore, it is preferable to deposit the insulator 11a by a method without using a gas containing hydrogen as a deposition gas. For example, the insulator 11a may be formed by a sputtering method.

Since the insulator 11a is formed to cover the conductor 15, unevenness in the base of the insulator 11 is relatively significant, and there is a risk of forming a pinhole, disconnection, or the like in the insulator 11a. In such a case, the pinhole, the disconnection, or the like formed in the insulator 11a may serve as a path through which hydrogen diffuses into the structure body 13.

Thus, it is preferable that the coverage with the insulator 11b be better than that with the insulator 11a. With such a structure, even when a pinhole, disconnection, or the like is formed in the insulator 11a, the insulator 11b covers the pinhole or the disconnection and accordingly can prevent the entry of hydrogen.

The insulator 11b is preferably deposited by a method providing a film with good coverage, such as an atomic layer deposition (ALD: Atomic Layer Deposition) method. In particular, a PEALD (Plasma Enhanced ALD) method which enables a film to be formed at a relatively low temperature is preferably used. In the deposition by a PEALD method, a precursor not containing an organic substance is preferably used. With such a method, the hydrogen concentration of the insulator 11b can be reduced.

Providing such an insulator 11 enables a reduction in the amount of hydrogen diffusing into the structure body 13 from the above the insulator 11 and from the insulator 11 itself, whereby the hydrogen concentration in the channel formation region of the oxide semiconductor element 12 can be reduced. Accordingly, a semiconductor device with small variations in transistor characteristics can be provided. A semiconductor device with favorable reliability can also be provided. A semiconductor device having favorable electrical characteristics can be provided.

Although FIG. 1A illustrates a structure where the insulator 11 functioning as a barrier insulating film is provided over the structure body 13, the present invention is not limited thereto. As illustrated in FIG. 1B, an insulator 18 functioning as a barrier insulating film may be provided below the structure body 13.

The insulator 18 has a stacked structure including an insulator 18b and an insulator 18a over the insulator 18b. Here, a barrier insulating film that can be used for the insulator 11a is preferably used as the insulator 18a, and a barrier insulating film that can be used for the insulator 11b is preferably used as the insulator 18b. In other words, in the stacked structure of the insulator 18, insulators corresponding to those in the insulator 11 are preferably inverted vertically.

In such a stacked structure, the insulator 18a in contact with the interlayer insulating film at the lower part of the structure body 13 has a reduced hydrogen concentration like the insulator 11a, and thus, the amount of hydrogen diffusing from the insulator 18 itself into the interlayer insulating film can be reduced. Even when the insulator 18 has an uneven base and a pinhole or disconnection is formed in the insulator 18a, the insulator 18b blocks the pinhole or the disconnection, so that the entry of hydrogen from below the structure body 13 can be inhibited.

As illustrated in FIG. 1C, the insulator 11 may have a structure in which the insulator 11a is in contact with the side surface of the structure body 13. In addition, the insulator 11a may be in contact with the insulator 18a in a region where the insulator 11a does not overlap with the structure body 13. In this case, the region where the insulator 11a is in contact with the insulator 18a is preferably formed so as to surround the structure body 13. Such a structure in which the structure body 13 is sealed by the insulator 11 and the insulator 18 can reduce the amount of hydrogen diffusing into the structure body 13 from the outside not only through the top and bottom surfaces of the structure body 13 but also through the side surface thereof.

Note that in FIG. 1C, the insulator 11a is in direct contact with the insulator 18a in the region where the insulator 11a does not overlap with the structure body 13, but the present invention is not limited thereto. For example, in the region where the insulator 11a does not overlap with the structure body 13, the insulator 11a may overlap with the insulator 18a with an insulating film therebetween that has a function of trapping and fixing hydrogen. In that case, an aluminum oxide film or the like can be used as the insulating film that has a function of trapping and fixing hydrogen.

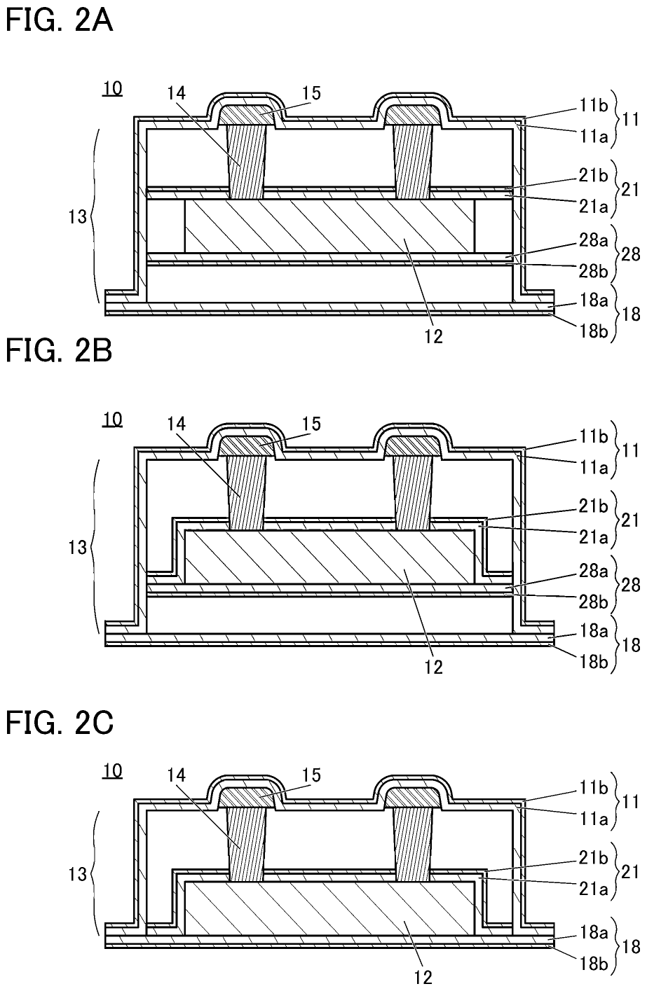

As illustrated in FIG. 2A, an insulator 21 and an insulator 28 that function as barrier insulating films against impurities such as hydrogen may be further provided in the structure body 13. Here, the insulator 21 is an insulating film having a structure similar to that of the insulator 11 and has a stacked structure including an insulator 21a and an insulator 21b over the insulator 21a. A barrier insulating film that can be used for the insulator 11a is preferably used as the insulator 21a, and a barrier insulating film that can be used for the insulator 11b is preferably used as the insulator 21b. The insulator 28 has a stacked structure including an insulator 28b and an insulator 28a over the insulator 28b. A barrier insulating film that can be used for the insulator 18a is preferably used as the insulator 28a, and a barrier insulating film that can be used for the insulator 18b is preferably used as the insulator 28b.

The insulator 21 is provided over the oxide semiconductor element 12. That is, the insulator 21 is provided between the oxide semiconductor element 12 and the insulator 11. The thus provided insulator 21 can reduce the amount of hydrogen diffusing into the oxide semiconductor element 12 more effectively. Note that the insulator 21 includes openings and the conductors 14 are provided so as to be embedded in the openings.

The insulator 28 is provided under the oxide semiconductor element 12. That is, the insulator 28 is provided between the oxide semiconductor element 12 and the insulator 18. The thus provided insulator 28 can reduce the amount of hydrogen diffusing into the oxide semiconductor element 12 more effectively.

Note that FIG. 2A as well as FIG. 1C illustrates the structure in which the structure body 13 is sealed by the insulator 11 and the insulator 18; however, the structure is not limited thereto, and the insulator 11 and the insulator 18 may be provided as illustrated in FIG. 1A or FIG. 1B.

As illustrated in FIG. 2B, the insulator 21 may have a structure in which the insulator 21a is in contact with the side surface of the oxide semiconductor element 12. In addition, the insulator 21a may be in contact with the insulator 28a in a region where the insulator 21a does not overlap with the oxide semiconductor element 12. In this case, the region where the insulator 21a is in contact with the insulator 28a is preferably formed to surround the oxide semiconductor element 12. Such a structure can reduce the amount of hydrogen diffusing into the oxide semiconductor element 12 from the outside not only through the top and bottom surfaces of the oxide semiconductor element 12 but also through the side surface thereof. In addition, in the region where the insulator 21a does not overlap with the oxide semiconductor element 12, the insulator 21a may overlap with the insulator 28a with an insulating film therebetween that has a function of trapping and fixing hydrogen.

As illustrated in FIG. 2C, without the insulator 28, the structure body 13 may be sealed by the insulator 11 and the insulator 18, and the oxide semiconductor element 12 may be sealed by the insulator 21 and the insulator 18. In other words, the insulator 18 also has a function of the insulator 28 in the semiconductor device 10 illustrated in FIG. 2B. Note that in the region where the insulator 21a does not overlap with the oxide semiconductor element 12, the insulator 21a may overlap with the insulator 18a with an insulating film therebetween that has a function of trapping and fixing hydrogen.

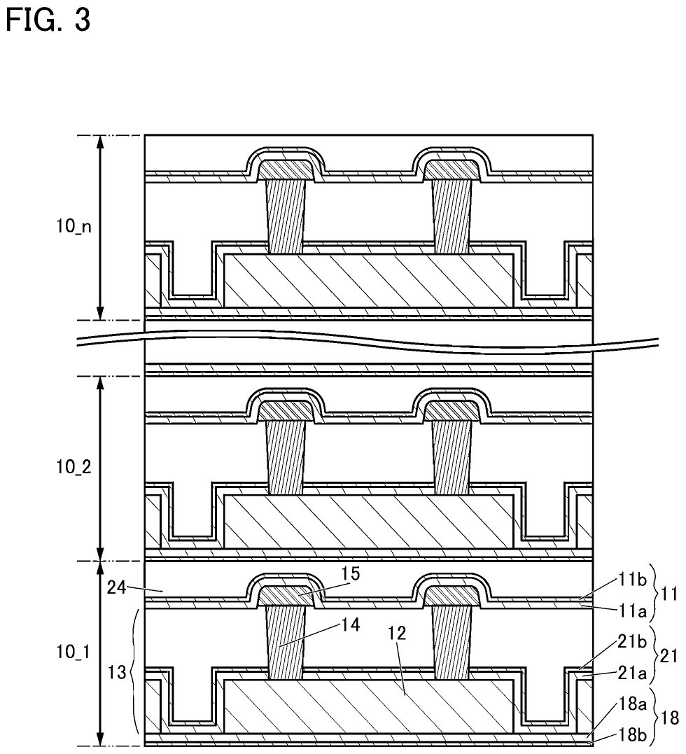

As illustrated in FIG. 3, a plurality of semiconductor devices 10 may be stacked to form a stacked semiconductor device. In the stacked semiconductor device illustrated in FIG. 3, n (n is a natural number of 2 or more) layers (hereinafter, also referred to as an element layer 10_1 to an element layer 10_n with identification signs) each including the semiconductor device 10 are stacked. In this specification and the like, the element layer is referred to as a device layer in some cases.

As illustrated in FIG. 3, all of the element layer 10_1 to the element layer 10_n have the same structure, which is similar to the structure of the semiconductor device 10 illustrated in FIG. 2C. Note that sealing with the insulator 11 is not performed, and the insulator 11 and the insulator 18 are not in contact with each other. An insulator 24 is provided over the insulator 11. As the insulator 24, an interlayer insulating film or the like that can be used as the structure body 13 described above may be used. The top surface of the insulator 24 is preferably planarized by CMP treatment or the like. This enables the structure body 13 to be provided over the insulator 24 with favorable adhesion.

Each of the element layers illustrated in FIG. 3 has a structure similar to that of the semiconductor device 10 illustrated in FIG. 2C; however, the structure of the element layer is not limited thereto and may be similar to that of the semiconductor device 10 illustrated in FIG. 2A or FIG. 2B.

As illustrated in FIG. 3, the oxide semiconductor element 12 in each element layer is sealed by the insulator 21 and the insulator 18, which can reduce the amount of hydrogen diffusing into the oxide semiconductor element 12. In particular, sealing of the oxide semiconductor element 12 in each element layer can prevent hydrogen from diffusing into a lower-layer oxide semiconductor element 12 while an upper-layer element layer is manufactured.

In such a semiconductor device including the stacked element layer 10_1 to the element layer 10_n, the number of elements per area can be increased to achieve higher integration of the semiconductor device.

Note that the stacked semiconductor device illustrated in FIG. 3 has the structure in which the oxide semiconductor element 12 is sealed by the insulator 18 and the insulator 11 in each element layer; however, the present invention is not limited thereto.

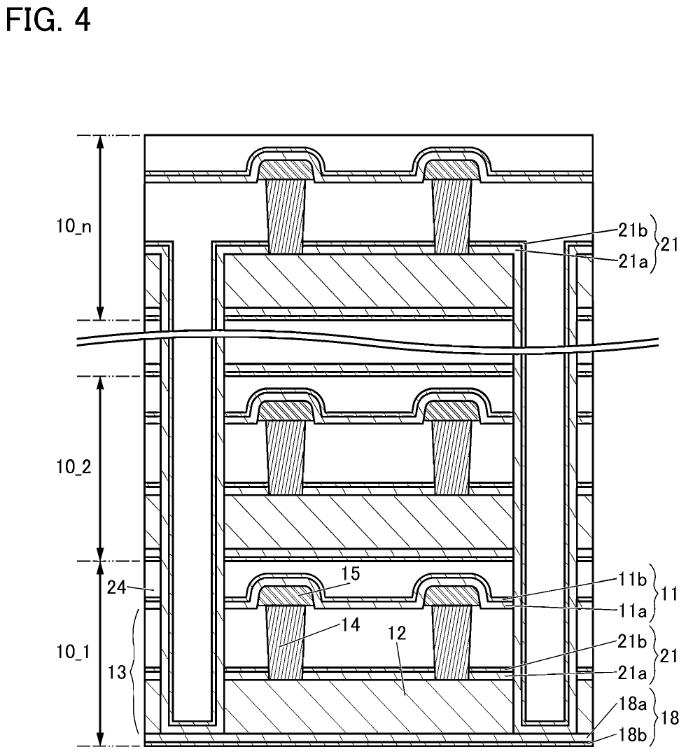

As illustrated in FIG. 4, all of the oxide semiconductor elements 12 included in the element layer 10_1 to the element layer 10_n may be collectively sealed by the insulator 18 in the element layer 10_1 and the insulator 21 in the element layer 10_n.

In a semiconductor device illustrated in FIG. 4, an opening is formed to reach the insulator 18 in the element layer 10_1 from the oxide semiconductor element 12 in the element layer 10_n, and the oxide semiconductor element 12 in each layer is surrounded by the opening. The insulator 21 is provided in contact with the bottom surface and inner wall of the opening and the top surface of the oxide semiconductor element 12. The insulator 21 touches the top surface of the insulator 18 in the element layer 10_1 at the bottom surface of the opening. Note that in the region where the insulator 21 does not overlap with the oxide semiconductor element 12, the insulator 21 may overlap with the insulator 18 with an insulating film therebetween that has a function of trapping and fixing hydrogen.

In a region sealed by the insulator 18 in the element layer 101 and the insulator 21 in the element layer 10_n, the insulator 18 and the insulator 21 are provided under and over the oxide semiconductor element 12 in each element layer, respectively. Also in this sealed region, the insulator 11 is provided to cover the conductor 15 in each of the element layer 10_1 to the element layer 10_n−1. Thus, the insulator 21 in the element layer 10_n is in contact with the side surfaces of the insulator 21, the insulator 11, and the insulator 24 in each element layer.

Such a structure in which all of the oxide semiconductor elements 12 included in the element layer 10_1 to the element layer 10_n are collectively sealed can reduce the number of steps of sealing the oxide semiconductor elements 12.

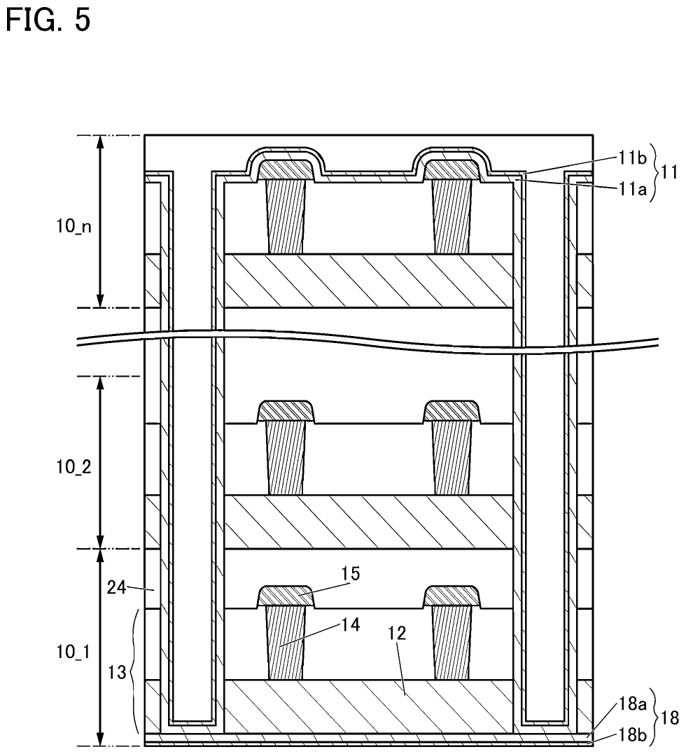

In the semiconductor device illustrated in FIG. 4, the oxide semiconductor elements 12 in all of the element layers are collectively sealed by the insulator 18 in the element layer 10_1 and the insulator 21 in the element layer 10_n; however, the present invention is not limited thereto. As illustrated in FIG. 5, the oxide semiconductor elements 12 in all of the element layers may be collectively sealed by the insulator 18 in the element layer 10_1 and the insulator 11 in the element layer 10_n.

In that case, an opening is formed to reach the insulator 18 in the element layer 10_1 from an interlayer insulating film of the structure body 13 in the element layer 10_n, and the oxide semiconductor element 12 in each layer is surrounded by the opening. The insulator 11 is provided in contact with the bottom surface and inner wall of the opening, and the conductor 15 and the interlayer insulating film of the structure body 13 in the element layer 10_n. The insulator 11 touches the top surface of the insulator 18 in the element layer 10_1 at the bottom surface of the opening. Note that in the region where the insulator 11 does not overlap with the oxide semiconductor element 12, the insulator 11 may overlap with the insulator 18 with an insulating film therebetween that has a function of trapping and fixing hydrogen.

Note that the semiconductor device illustrated in FIG. 5 has a structure in which a barrier insulating film against hydrogen is not provided in the region sealed by the insulator 18 in the element layer 10_1 and the insulator 11 in the element layer 10_n. This can further reduce the number of steps of manufacturing a stacked semiconductor device.

The stacked semiconductor devices illustrated in FIG. 3 to FIG. 5 each have a structure in which the insulator 28 illustrated in FIG. 2A or FIG. 2B is not provided; however, the present invention is not limited thereto. The stacked semiconductor devices illustrated in FIG. 3 to FIG. may each have a structure in which the insulator 28 is provided between the oxide semiconductor element 12 and the insulator 18.

### <Manufacturing Method of Semiconductor Device>

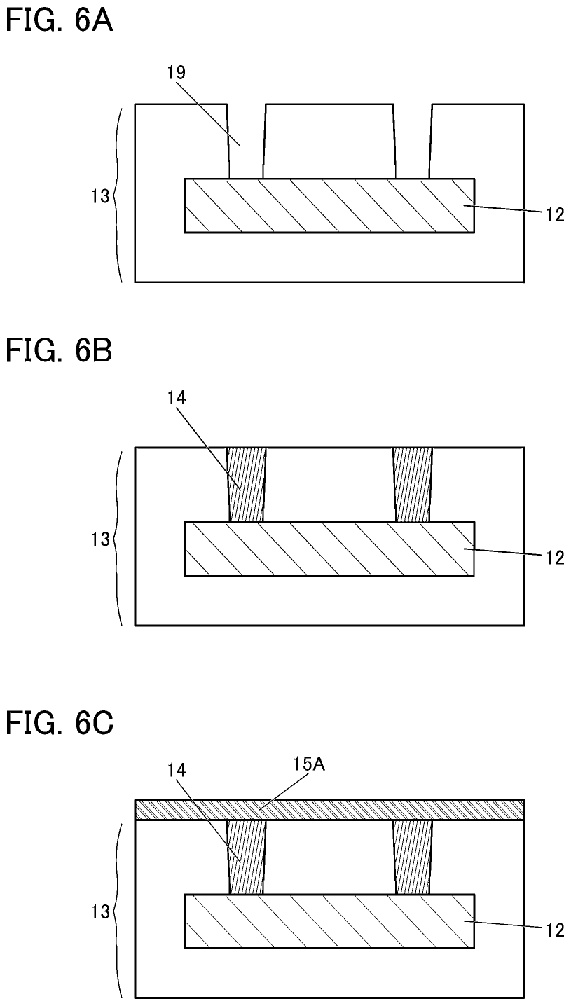

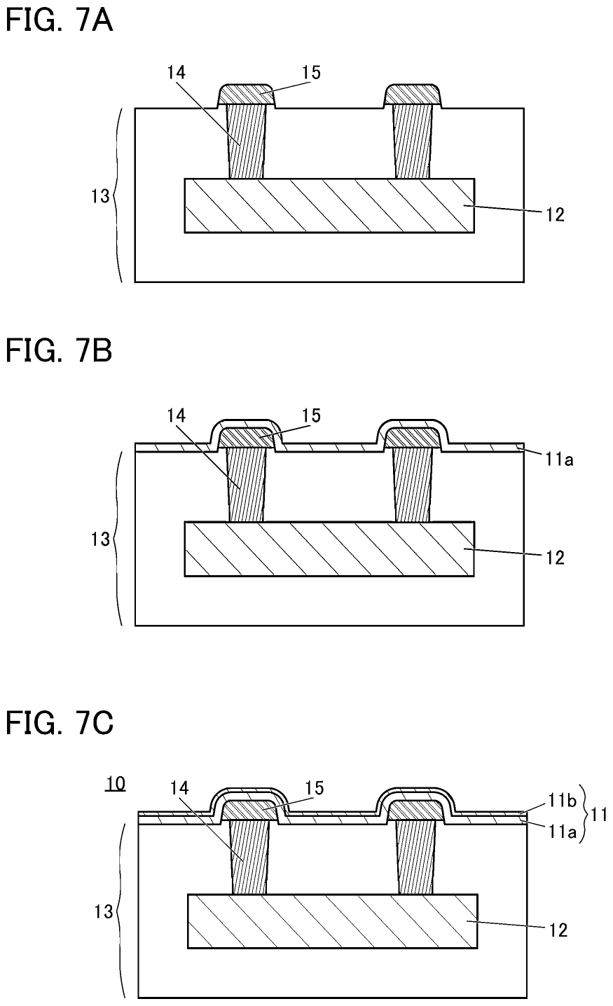

Next, a method for manufacturing the semiconductor device 10 of one embodiment of the present invention illustrated in FIG. 1A is described with reference to FIG. 6A to FIG. 7C.

Note that in this specification and the like, an insulating material for forming an insulator, a conductive material for forming a conductor, or a semiconductor material for forming a semiconductor can be formed as appropriate by a sputtering method, a chemical vapor deposition (CVD) method, a molecular beam epitaxy (MBE) method, a pulsed laser deposition (PLD) method, an ALD method, or the like.

Examples of the sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. An RF sputtering method is mainly used in the case where an insulating film is deposited, and a DC sputtering method is mainly used in the case where a metal conductive film is deposited. The pulsed DC sputtering method is mainly used in the case where a compound such as an oxide, a nitride, or a carbide is deposited by a reactive sputtering method.

Note that the CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by a plasma CVD method. Furthermore, a thermal CVD method is a deposition method that does not use plasma and thus enables less plasma damage to an object to be processed. For example, a wiring, an electrode, an element (a transistor, a capacitor, or the like), or the like included in a semiconductor device might be charged up by receiving electric charge from plasma. In that case, accumulated electric charge might break the wiring, the electrode, the element, or the like included in the semiconductor device. In contrast, such plasma damage does not occur in the case of a thermal CVD method, which does not use plasma, and thus the yield of the semiconductor device can be increased. In addition, a thermal CVD method does not cause plasma damage during deposition, so that a film with few defects can be obtained.

As an ALD method, a thermal ALD method, in which a precursor and a reactant react with each other only by a thermal energy, a PEALD method, in which a reactant excited by plasma is used, and the like can be used.

A CVD method and an ALD method are different from a sputtering method in which particles ejected from a target or the like are deposited. Thus, a CVD method and an ALD method are deposition methods that enable favorable step coverage almost regardless of the shape of an object to be processed. In particular, an ALD method has excellent step coverage and excellent thickness uniformity and thus is suitable for covering a surface of an opening portion with a high aspect ratio, for example. On the other hand, an ALD method has a relatively low deposition rate, and thus is preferably used in combination with another deposition method with a high deposition rate, such as a CVD method, in some cases.

By a CVD method, a film with a certain composition can be deposited depending on the flow rate ratio of the source gases. For example, by a CVD method, by changing the flow rate ratio of the source gases during the deposition, a film in which the composition is continuously changed can be deposited. In the case where the film is deposited while the flow rate ratio of the source gases is changed, as compared to the case where the film is deposited using a plurality of deposition chambers, the time taken for the deposition can be shortened because the time taken for transfer and pressure adjustment is omitted. Thus, the productivity of the semiconductor device can be increased in some cases.

By an ALD method, a film with a certain composition can be deposited by concurrently introducing a plurality kinds of different precursors or controlling the cycle number of each of the plurality kinds of different precursors.

First, a substrate (not illustrated) is prepared, and the structure body 13 including the oxide semiconductor element 12 is formed over the substrate. The interlayer insulating film of the structure body 13 can be deposited by a sputtering method, a CVD method, an MBE method, a PLD method, an ALD method, or the like. A silicon oxide film may be deposited by a sputtering method as the insulating film, for example.

Next, openings 19 reaching the oxide semiconductor element 12 are formed in the interlayer insulating film of the structure body 13 (see FIG. 6A). The openings can be formed by a lithography method. Wet etching can be used for the formation of the openings; however, dry etching is preferably used for microfabrication.

Next, the conductor 14 is embedded in the openings 19 (see FIG. 6B). A conductive film that can be used for the conductor 14 is formed to fill the openings 19, and chemical mechanical polishing (CMP) is performed on the conductive film, so that the conductor 14 is formed. The conductive film can be formed by a sputtering method, a CVD method, an MBE method, a PLD method, an ALD method, or the like.

CMP treatment is performed on the conductive film until the top surface of the uppermost interlayer insulating film of the structure body 13 is exposed, whereby the conductive film remains only in the openings 19, and the conductor 14 with a flat top surface can be formed. Note that the top surface of the interlayer insulating film is partly removed by the CMP treatment in some cases.

Next, a conductive film 15A is formed to cover the structure body 13 and the conductor 14 (see FIG. 6C). For the conductive film 15A, a conductive film that can be used for the above conductor 14 can be used. The conductive film 15A can be deposited by a sputtering method, a CVD method, an MBE method, a PLD method, an ALD method, or the like.

Next, the conductive film 15A is processed by a lithography method, so that the conductor 15 in contact with the top surface of the conductor 14 is formed (see FIG. 7A). At this time, in a region where an interlayer insulating film of the structure body 13 does not overlap with the conductor 15, part of the interlayer insulating film is removed in some cases. Thus, on the uppermost surface of the structure body 13, the level of a region overlapping with the conductor 14 is higher than that of the other region in some cases.

Next, the insulator 11a is formed to cover the structure body 13, the conductor 14, and the conductor 15 (see FIG. 7B). For the insulator 11a, the above-described insulating material having a hydrogen barrier property may be used, and a nitride containing silicon such as silicon nitride is preferably used. The insulator 11a is preferably formed by a sputtering method. A gas mainly containing hydrogen is not necessarily used as a deposition gas. By using a sputtering method, the hydrogen concentration in insulator 11a can be reduced.

Next, the insulator 11b is formed over the insulator 11a (see FIG. 7C). For the insulator 11b, the above-described insulating material having a hydrogen barrier property may be used, and a nitride containing silicon such as silicon nitride is preferably used. The insulator 11b is preferably formed by an ALD method providing a film with good coverage and further preferably formed by a PEALD method.

When the insulator 11b is formed by a PEALD method, a precursor not containing an organic substance such as hydrocarbon (hereinafter, referred to as an inorganic precursor) is preferably used. With use of an inorganic precursor for film formation, the hydrogen concentration in the insulator 11b can be reduced. As the inorganic precursor, a substance containing silicon is preferably used, and furthermore a halogen element can be contained. In the case where the inorganic precursor contains a halogen element, the halogen element is to be contained in the insulator 11b as an impurity in some cases. Note that impurities can be quantified by secondary ion mass spectrometry (SIMS) or X-ray photoelectron spectroscopy (XPS).

Note that an ALD method in the present invention is not limited to the case of using an inorganic precursor, but a precursor containing an organic substance can be used in some cases.

In the case where silicon nitride is deposited by a PEALD method, nitrogen radicals are used as a reactant. Nitrogen radicals can be obtained by making a nitrogen gas into a plasma state. Note that in nitrogen plasma, nitrogen is contained in a state of molecules, radicals, ions, or the like. For example, by applying a high-frequency wave such as RF or a microwave to a nitrogen gas, nitrogen plasma containing nitrogen radicals can be generated. It is preferable that the reactant do not contain hydrogen. In this case, the hydrogen concentration in the insulator 11b can be reduced.

Through the above steps, the semiconductor device 10 illustrated in FIG. 1A can be manufactured.

In the case where the semiconductor device 10 illustrated in FIG. 1B is manufactured, before the structure body 13 illustrated in FIG. 6A is formed, the insulator 18b may be formed and the insulator 18a may be formed over the insulator 18b. Then, the structure body 13 may be formed over the insulator 18a. The insulator 18a can be deposited in a manner similar to that of the insulator 11a. The insulator 18b can be deposited in a manner similar to that of the insulator 11b.

In the case where the semiconductor device 10 illustrated in FIG. 1(C) is manufactured, in the manufacturing method of the semiconductor device 10 illustrated in FIG. 1(B), the structure body 13 may be etched before the insulator 11a is deposited, so that the insulator 11a is provided to cover the side surface of the structure body 13. The top surface of the insulator 18a is exposed by the etching, whereby a region where the insulator 11a and the insulator 18a are in contact with each other can be provided outside the structure body 13. Thus, the structure body 13 can be sealed by the insulator 11 and the insulator 18.

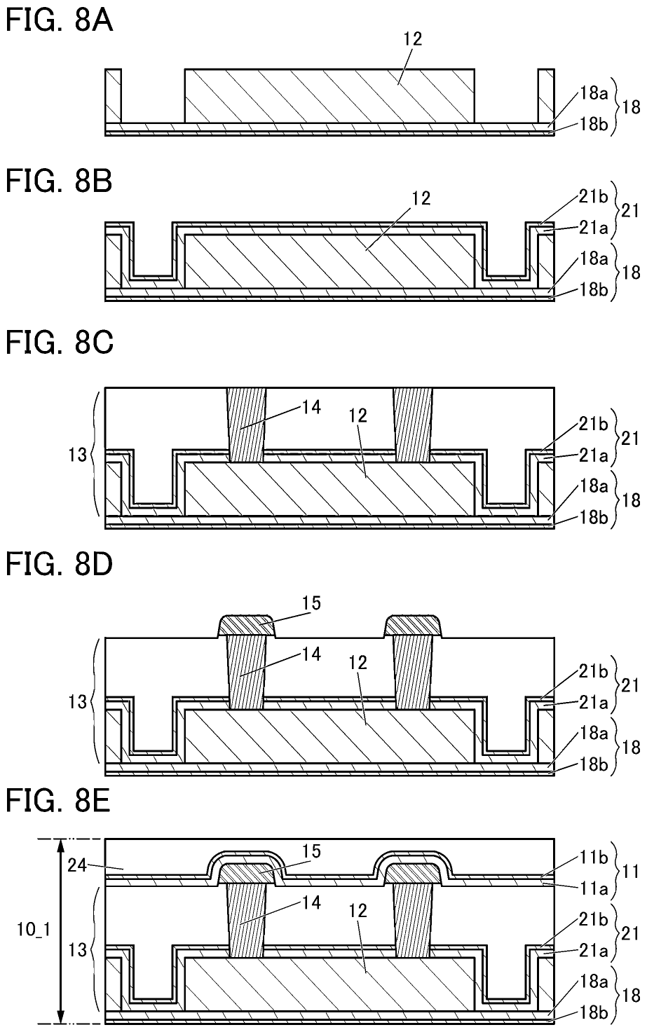

Next, a method for manufacturing the stacked semiconductor device of one embodiment of the present invention illustrated in FIG. 3 is described with reference to FIG. 8A to FIG. 8E.

First, a substrate (not illustrated) is prepared, and the insulator 18 is formed over the substrate. The insulator 18 may be formed by depositing the insulator 18b and then depositing the insulator 18a over the insulator 18b. Furthermore, the oxide semiconductor element 12 patterned into an island shape is formed over the insulator 18 (see FIG. 8A). The patterning into an island shape means that, for example, the oxide semiconductor element 12 is surrounded by a trench-like opening.

Next, the insulator 21 is formed to cover the oxide semiconductor element 12 (see FIG. 8B). The insulator 21 may be formed by depositing the insulator 21a and then depositing the insulator 21b over the insulator 21a. The insulator 21a can be deposited in a manner similar to that of the insulator 11a. The insulator 21b can be deposited in a manner similar to that of the insulator 11b.

Next, the structure body 13 is formed so as to include the oxide semiconductor element 12 and the insulator 21. Furthermore, the conductor 14 is formed so as to be embedded in the structure body 13 and the insulator 21 (see FIG. 8C). For the steps up to the formation of the conductor 14, the above description relating to the steps in FIG. 6A and FIG. 6B can be referred to.

Next, the conductor 15 is formed in contact with the top surface of the conductor 14 (see FIG. 8D). For the steps up to the formation of the conductor 15, the above description relating to the steps in FIG. 6C and FIG. 7A can be referred to.

Next, the insulator 11 is formed to cover the structure body 13, the conductor 14, and the conductor 15. The insulator 11 may be formed by depositing the insulator 11a and then depositing the insulator 11b over the insulator 11a. For the deposition of the insulator 11a and the insulator 11b, the above description relating to the steps in FIG. 7B and FIG. 7C can be referred to.

Next, the insulator 24 is formed over the insulator 11 (see FIG. 8E). The insulator 24 can be deposited by a sputtering method, a CVD method, an MBE method, a PLD method, an ALD method, or the like. A silicon oxide film may be deposited by a sputtering method as the insulator 24, for example. The top surface of the insulator 24 is preferably planarized by CMP treatment or the like. In this manner, the element layer 10_1 illustrated in FIG. 3 can be formed.

After that, the steps illustrated in FIG. 8A to FIG. 8E are repeated n−1 times, so that the semiconductor device illustrated in FIG. 3, in which the element layer 101 to the element layer 10_n are stacked, can be manufactured. In this manufacturing method of the semiconductor device, the oxide semiconductor element 12 is sealed by the insulator 21 and the insulator 18 in the manufacturing process of each element layer (see FIG. 8B). This can prevent hydrogen from diffusing into a lower-layer oxide semiconductor element 12 while an upper-layer element layer is manufactured.

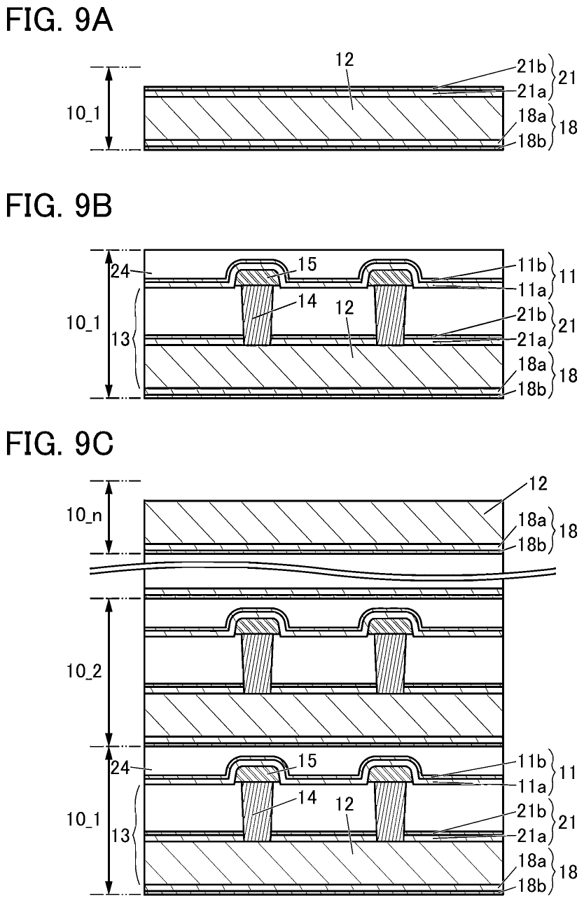

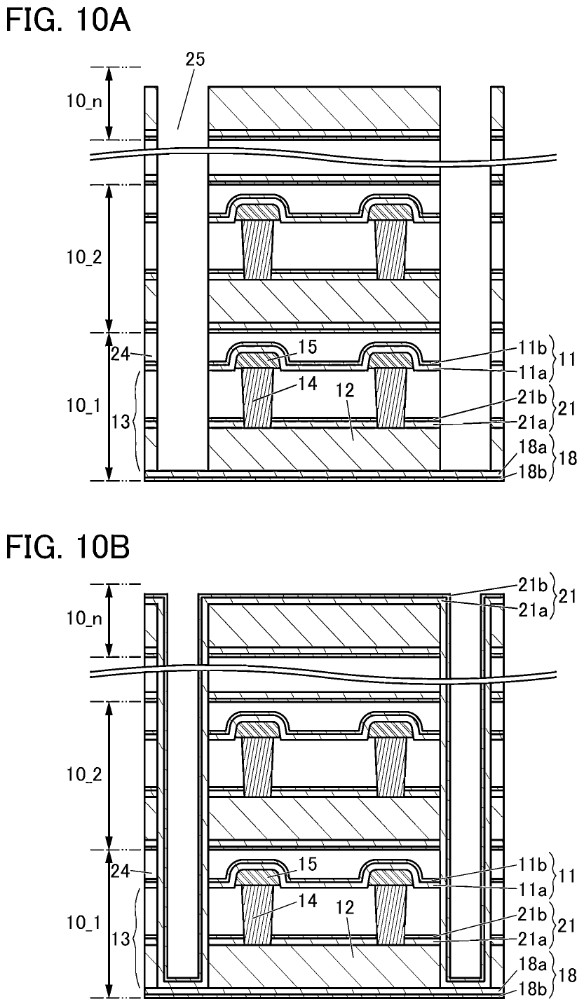

Next, a method for manufacturing the stacked semiconductor device of one embodiment of the present invention illustrated in FIG. 4 is described with reference to FIG. 9A to FIG. 10B.

First, a substrate (not illustrated) is prepared, and the insulator 18 is formed over the substrate. Furthermore, the oxide semiconductor element 12 is formed over the insulator 18 and the insulator 21 is formed thereover (see FIG. 9A). For the steps up to the formation of the insulator 21, the above description relating to the steps in FIG. 8A and FIG. 8B can be referred to. Note that in this step, the oxide semiconductor element 12 is not patterned into an island shape and the insulator 21 is formed over the layer-like oxide semiconductor element 12. Thus, the insulator 21 does not cover the side surfaces of the oxide semiconductor element 12.

Next, the structure body 13 is formed so as to include the oxide semiconductor element 12 and the insulator 21. Furthermore, the conductor 14 is formed so as to be embedded in the structure body 13 and the insulator 21. In addition, the conductor 15 is formed in contact with the top surface of the conductor 14. Then, the insulator 11 and the insulator 24 are formed to cover the structure body 13, the conductor 14, and the conductor 15 (see FIG. 9B). For the steps up to the formation of the insulator 11 and the insulator 24, the above description relating to the steps in FIG. 8C to FIG. 8E can be referred to. In this manner, the element layer 10_1 in which the oxide semiconductor element 12 is not patterned into an island shape can be formed.

Repeating the steps illustrated in FIG. 9A and FIG. 9B n−1 times allows manufacturing of the semiconductor device including the stacked element layer 10_1 to element layer 10_n, in each of which the oxide semiconductor element 12 is not patterned into an island shape (see FIG. 9C). Note that as illustrated in FIG. 9C, the element layer 10_n includes only the insulator 18 and the oxide semiconductor element 12.

Next, openings 25 reaching the insulator 18a in the element layer 10_1 are formed in the aforementioned semiconductor device (see FIG. 10A). The openings 25 can be formed by a lithography method, for example, dry etching. The openings 25 are preferably formed so as to surround the oxide semiconductor element 12 in each layer.

Next, the insulator 21 is deposited in contact with the bottom surface and inner wall of the opening 25 and the top surface of the oxide semiconductor element 12 in the element layer 10_n (see FIG. 10B). The insulator 21 touches the top surface of the insulator 18a in the element layer 10_1 at the bottom surface of the opening 25. The insulator 21 can be deposited in a manner similar to the step in FIG. 8B. Here, when the insulator 21b is deposited by an ALD method providing a film with good coverage, especially a PEALD method as described above, a pinhole, disconnection, or the like that might be formed in the insulator 21a can be covered with the insulator 21b to prevent entry of hydrogen.

After that, the structure body 13, the conductor 14, the conductor 15, the insulator 11, and the insulator 24 in the element layer 10_n may be formed in a manner similar to the steps in FIG. 8C to FIG. 8E. As a result, the semiconductor device illustrated in FIG. 4, in which the element layer 10_1 to the element layer 10_n are stacked, can be manufactured. In this manufacturing method of the semiconductor device, all the oxide semiconductor elements 12 included in the element layer 10_1 to the element layer 10_n can be collectively sealed (see FIG. 10B). It is thus possible to reduce the number of steps for sealing the oxide semiconductor element 12. This leads to an improvement in the productivity and a reduction in the production costs of the semiconductor device.

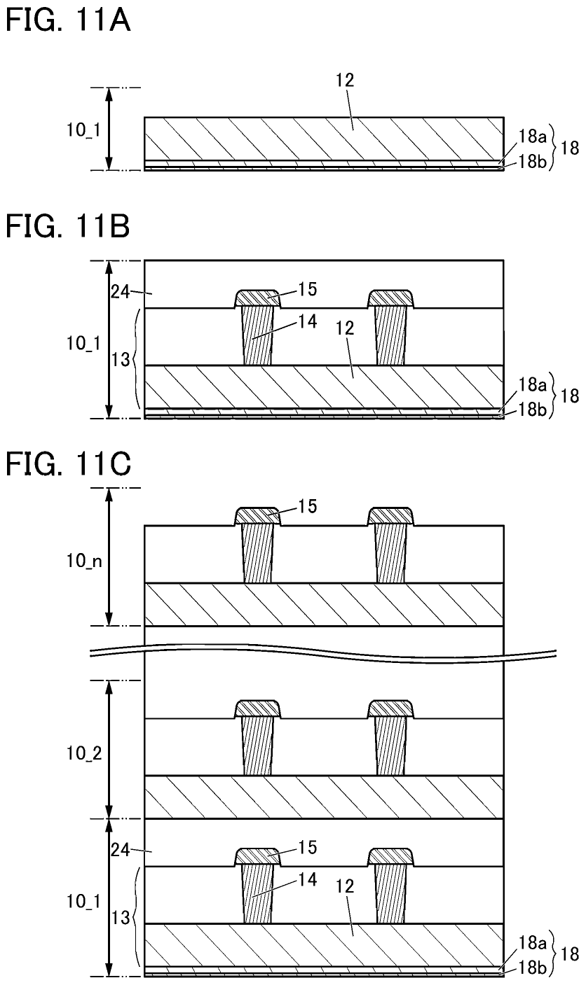

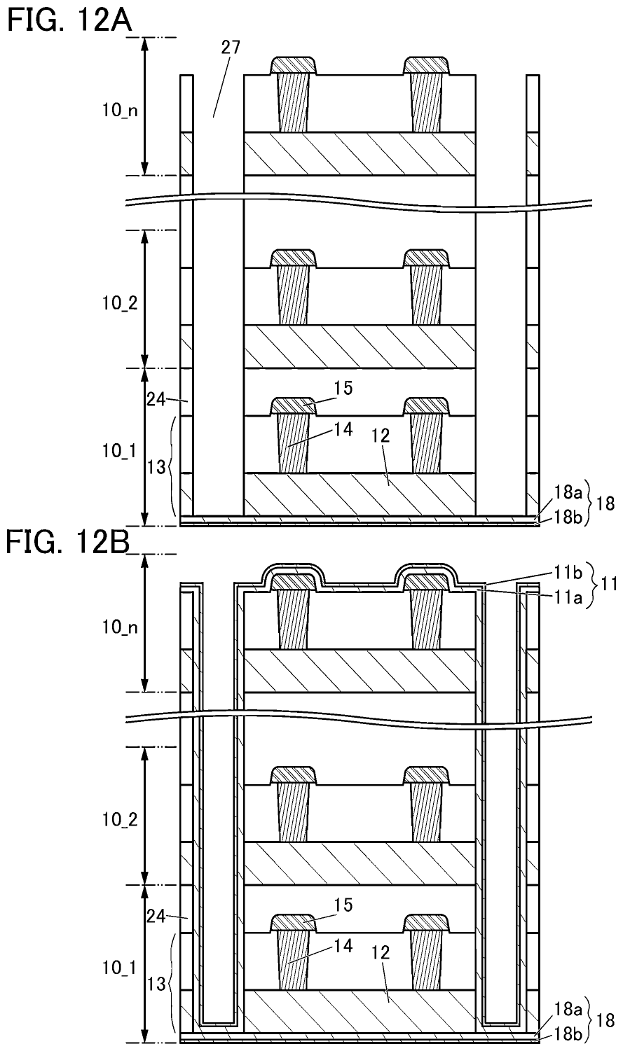

Next, a method for manufacturing the stacked semiconductor device of one embodiment of the present invention illustrated in FIG. 5 is described with reference to FIG. 11A to FIG. 12B.

First, a substrate (not illustrated) is prepared, and the insulator 18 is formed over the substrate. Furthermore, the oxide semiconductor element 12 is formed over the insulator 18 (see FIG. 11A). For the steps up to the formation of the oxide semiconductor element 12, the above description relating to the step in FIG. 9A can be referred to. Note that in this step, the insulator 21 is not formed over the oxide semiconductor element 12.

Next, the structure body 13 is formed so as to include the oxide semiconductor element 12. Furthermore, the conductor 14 is formed so as to be embedded in the structure body 13. In addition, the conductor 15 is formed in contact with the top surface of the conductor 14. Then, the insulator 24 is formed to cover the structure body 13, the conductor 14, and the conductor 15 (see FIG. 11B). For the steps up to the formation of the insulator 11, the above description relating to the step in FIG. 9B can be referred to. Note that in this step, the insulator 11 is not formed over the structure body 13 and the conductor 15. In this manner, the element layer 10_1 in which the insulator 21 and the insulator 11 are not formed can be formed.

Next, the steps illustrated in FIG. 11A and FIG. 11B are repeated n−1 times without formation of the insulator 18. As a result, the semiconductor device in which the element layer 10_1 to the element layer 10_n are stacked can be manufactured (see FIG. 11C). Here, the stacked semiconductor device illustrated in FIG. 11C does not include a barrier insulating film against hydrogen other than the insulator 18 in the element layer 10_1. Also as illustrated in FIG. 11C, the element layer 10_n does not include the insulator 24.

Next, openings 27 reaching the insulator 18a in the element layer 10_1 are formed in the aforementioned semiconductor device (see FIG. 12A). For the formation of the openings 27, the above description relating to the step of forming the openings 27 in FIG. 10A can be referred to. The openings 27 are preferably formed so as to surround the oxide semiconductor element 12 in each layer.

Next, the insulator 11 is deposited in contact with the bottom surface and inner wall of the opening 27 and the conductor 15 and an interlayer insulating film of the structure body 13 in the element layer 10_n (see FIG. 12B). The insulator 11 touches the top surface of the insulator 18a in the element layer 10_1 at the bottom surface of the opening 27. The insulator 11 can be deposited in a manner similar to the step in FIG. 8E. Here, when the insulator 11b is deposited by an ALD method providing a film with good coverage, especially a PEALD method as described above, a pinhole, disconnection, or the like that might be formed in the insulator 11a can be covered with the insulator 11b to prevent entry of hydrogen.

After that, the insulator 24 in the element layer 10_n may be formed in a manner similar to the step in FIG. 8E. As a result, the semiconductor device illustrated in FIG. 5, in which the element layer 10_1 to the element layer 10_n are stacked, can be manufactured. In this manufacturing method of the semiconductor device, all the oxide semiconductor elements 12 included in the element layer 10_1 to the element layer 10_n can be collectively sealed (see FIG. 12B). It is thus possible to reduce the number of steps for sealing the oxide semiconductor element 12. Also in this manufacturing method of the semiconductor device, a barrier insulating film against hydrogen is not provided in the region sealed by the insulator 18 in the element layer 10_1 and the insulator 11 in the element layer 10_n (see FIG. 12B). This can further reduce the number of steps of manufacturing the stacked semiconductor device. This leads to an improvement in the productivity and a reduction in the production costs of the stacked semiconductor device.

Although the insulator 11 is described as having a stacked structure of the insulator 11a and the insulator 11b in the above, the present invention is not necessarily limited to this structure. For example, when the coverage with the insulator 11a is sufficiently good so that a pinhole, disconnection, or the like is not formed, a structure where the insulator 11b is not provided but only the insulator 11a is provided may be employed. For example, when the hydrogen concentration in the insulator 11b is sufficiently low, a structure where the insulator 11a is not provided but only the insulator 11b is provided may be employed. As for the insulator 18, similarly, a structure where only the insulator 18a is provided or a structure where only the insulator 18b is provided may be employed. As for the insulator 21, similarly, a structure where only the insulator 21a is provided or a structure where only the insulator 21b is provided may be employed. As for the insulator 28, similarly, a structure where only the insulator 28a is provided or a structure where only the insulator 28b is provided may be employed.

According to one embodiment of the present invention, a novel semiconductor device can be provided. According to another embodiment of the present invention, a method for manufacturing a novel semiconductor device can be provided. According to another embodiment of the present invention, a semiconductor device with a small variation in transistor characteristics can be provided. According to another embodiment of the present invention, a semiconductor device having favorable electrical characteristics can be provided. According to another embodiment of the present invention, a semiconductor device with favorable reliability can be provided.

At least part of the structure, method, and the like described in this embodiment can be implemented in appropriate combination with any of those in the other embodiments and the like described in this specification.

### Embodiment 2

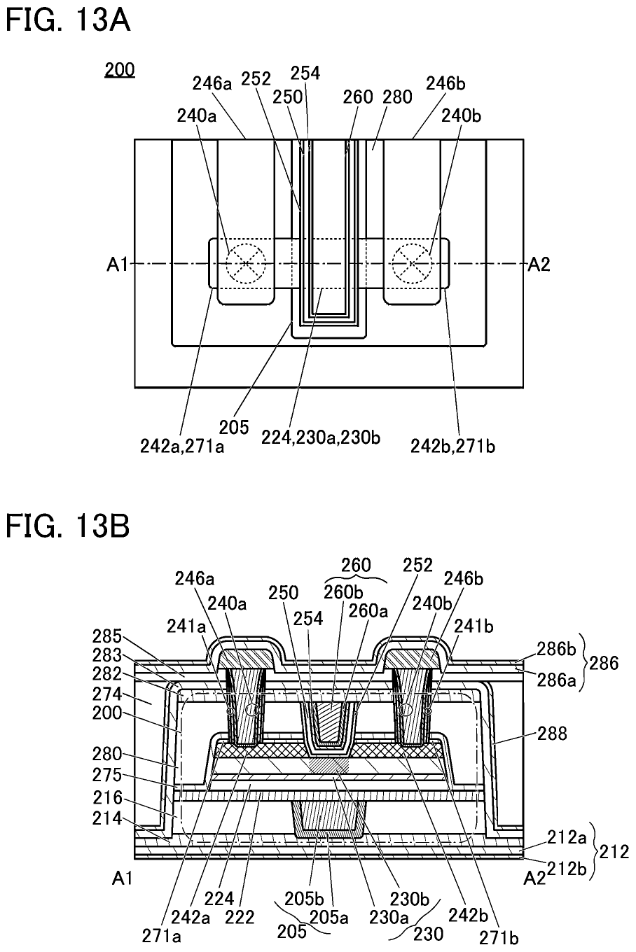

In this embodiment, a semiconductor device including a transistor 200 will be described as a specific example of the semiconductor device 10 shown in Embodiment 1 with reference to FIG. 13A to FIG. 16C.

### <Structure Example of Semiconductor Device>

A structure of a semiconductor device corresponding to the semiconductor device 10 in illustrated FIG. 1B is described with reference to FIG. 13A and FIG. 13B. FIG. 13A and FIG. 13B are a top view and a cross-sectional view of the semiconductor device including the transistor 200. FIG. 13A is a top view of the semiconductor device. FIG. 13B is a cross-sectional view of a portion indicated by the dashed-dotted line A1-A2 in FIG. 13A, i.e., a cross-sectional view of the transistor 200 in the channel length direction. For clarity of the drawing, some components are not illustrated in the top view of FIG. 13A.

The semiconductor device of one embodiment of the present invention includes an insulator 212 over a substrate (not illustrated), an insulator 214 over the insulator 212, the transistor 200 over the insulator 214, an insulator 280 over the transistor 200, an insulator 282 over the insulator 280, an insulator 283 over the insulator 282, an insulator 288 over the insulator 283, an insulator 274 over the insulator 288, and an insulator 285 over the insulator 283 and the insulator 274. Here, the insulator 212 preferably has a stacked structure including an insulator 212b and an insulator 212a over the insulator 212b. An insulator 286 preferably has a stacked structure including an insulator 286a and an insulator 286b over the insulator 286a.

The insulator 212, the insulator 214, the insulator 280, the insulator 282, the insulator 283, the insulator 285, and the insulator 274 each function as an interlayer insulating film of the semiconductor device illustrated in FIG. 13A and FIG. 13B. The insulator 283 is in contact with part of the top surface of the insulator 214, a side surface of an insulator 216, a side surface of the insulator 222, a side surface of an insulator 275, a side surface of the insulator 280, and a side surface and the top surface of the insulator 282. In addition, the uppermost portion of the insulator 283, the uppermost portion of the insulator 288, and the uppermost portion of the insulator 274 are substantially level with each other.

In addition, the semiconductor device also includes a conductor 240 (a conductor 240a and a conductor 240b) that is electrically connected to the transistor 200 and functions as a plug. Note that an insulator 241 (an insulator 241a and an insulator 241b) is provided in contact with a side surface of the conductor 240 functioning as a plug. A conductor 246 (a conductor 246a and a conductor 246b) electrically connected to the conductor 240 and functioning as a wiring is provided over the insulator 285 and the conductor 240. The insulator 286 is provided to cover the conductor 246 and the insulator 285.

Here, the transistor 200 corresponds to the oxide semiconductor element 12 described in Embodiment 1. The insulator 212 (the insulator 212a and the insulator 212b) corresponds to the insulator 18 (the insulator 18a and the insulator 18b) described in Embodiment 1. The insulator 283 corresponds to the insulator 21a described in Embodiment 1. The insulator 288 corresponds to the insulator 21b described in Embodiment 1. The conductor 240 corresponds to the conductor 14 described in Embodiment 1. The conductor 246 corresponds to the conductor 15 described in Embodiment 1. The insulator 286 (the insulator 286a and the insulator 286b) corresponds to the insulator 11 (the insulator 11a and the insulator 11b) described in Embodiment 1. Therefore, in addition to the description in this embodiment, the description in Embodiment 1 can be referred to.

The insulator 241a is provided in contact with an inner wall of an opening formed in the insulator 275, the insulator 280, the insulator 282, the insulator 283, and the insulator 285, and the conductor 240a is provided in contact with a side surface of the insulator 241a. The insulator 241b is provided in contact with an inner wall of an opening formed in the insulator 275, the insulator 280, the insulator 282, the insulator 283, and the insulator 285, and the conductor 240b is provided in contact with a side surface of the insulator 241b. The insulator 241 has a structure in which a first insulator is provided in contact with the inner wall of the opening and a second insulator is provided on the inner side of the first insulator. The conductor 240 has a structure in which a first conductor is provided in contact with the side surface of the insulator 241 and a second conductor is provided on the inner side of the first conductor. The top surface of the conductor 240 can be substantially level with the top surface of the insulator 285 in a region overlapping with the conductor 246.

Although the first insulator of the insulator 241 and the second insulator of the insulator 241 are stacked in the transistor 200, the present invention is not limited thereto. For example, the insulator 241 may have a single-layer structure or a stacked-layer structure of three or more layers. Although the first conductor of the conductor 240 and the second conductor of the conductor 240 are stacked in the transistor 200, the present invention is not limited thereto. For example, the conductor 240 may have a single-layer structure or a stacked-layer structure of three or more layers. In the case where a component has a stacked-layer structure, layers may be distinguished by ordinal numbers corresponding to the formation order.

### [Transistor 200]

As illustrated in FIG. 13A and FIG. 13B, the transistor 200 includes the insulator 216 over the insulator 214, a conductor 205 (a conductor 205a and a conductor 205b) provided to be embedded in the insulator 214 or the insulator 216, an insulator 222 over the insulator 216 and the conductor 205, an insulator 224 over the insulator 222, an oxide 230a over the insulator 224, an oxide 230b over the oxide 230a, a conductor 242a over the oxide 230b, an insulator 271a over the conductor 242a, a conductor 242b over the oxide 230b, an insulator 271b over the conductor 242b, an insulator 252 over the oxide 230b, an insulator 250 over the insulator 252, an insulator 254 over the insulator 250, a conductor 260 (a conductor 260a and a conductor 260b) over the insulator 254 and overlapping with part of the oxide 230b, and the insulator 275 placed over the insulator 222, the insulator 224, the oxide 230a, the oxide 230b, the conductor 242a, the conductor 242b, the insulator 271a, and the insulator 271b. Here, the insulator 252 is in contact with the top surface of the insulator 222, a side surface of the insulator 224, a side surface of the oxide 230a, a side surface and the top surface of the oxide 230b, a side surface of a conductor 242, a side surface of an insulator 271, a side surface of the insulator 275, a side surface of the insulator 280, and the bottom surface of the insulator 250. The top surface of the conductor 260 is placed to be substantially level with the uppermost portion of the insulator 254, the uppermost portion of the insulator 250, the uppermost portion of the insulator 252, and the top surface of the insulator 280. The insulator 282 is in contact with at least parts of the top surfaces of the conductor 260, the insulator 252, the insulator 250, the insulator 254, and the insulator 280.

Hereinafter, the oxide 230a and the oxide 230b are collectively referred to as an oxide 230 in some cases. The conductor 242a and the conductor 242b are collectively referred to as the conductor 242 in some cases. The insulator 271a and the insulator 271b are collectively referred to as the insulator 271 in some cases.

An opening reaching the oxide 230b is provided in the insulator 280 and the insulator 275. The insulator 252, the insulator 250, the insulator 254, and the conductor 260 are positioned in the opening. The conductor 260, the insulator 252, the insulator 250, and the insulator 254 are provided between the conductor 242a and the conductor 242b and between the insulator 271a and the insulator 271b in the channel length direction of the transistor 200. The insulator 254 includes a region in contact with a side surface of the conductor 260 and a region in contact with the bottom surface of the conductor 260.

The oxide 230 preferably includes the oxide 230a placed over the insulator 224 and the oxide 230b placed over the oxide 230a. Including the oxide 230a under the oxide 230b makes it possible to inhibit diffusion of impurities into the oxide 230b from components formed below the oxide 230a.

Although a structure in which two layers, the oxide 230a and the oxide 230b, are stacked as the oxide 230 in the transistor 200 is described, the present invention is not limited thereto. For example, the oxide 230 may be provided as a single layer of the oxide 230b or to have a stacked-layer structure of three or more layers, or the oxide 230a and the oxide 230b may each have a stacked-layer structure.

The conductor 260 functions as a first gate (also referred to as a top gate) electrode, and the conductor 205 functions as a second gate (also referred to as a back gate) electrode. The insulator 252, the insulator 250, and the insulator 254 function as a first gate insulator, and the insulator 222 and the insulator 224 function as a second gate insulator. Note that the gate insulator is also referred to as a gate insulating layer or a gate insulating film in some cases. The conductor 242a functions as one of a source and a drain, and the conductor 242b functions as the other of the source and the drain. At least part of a region of the oxide 230 overlapping with the conductor 260 functions as a channel formation region.

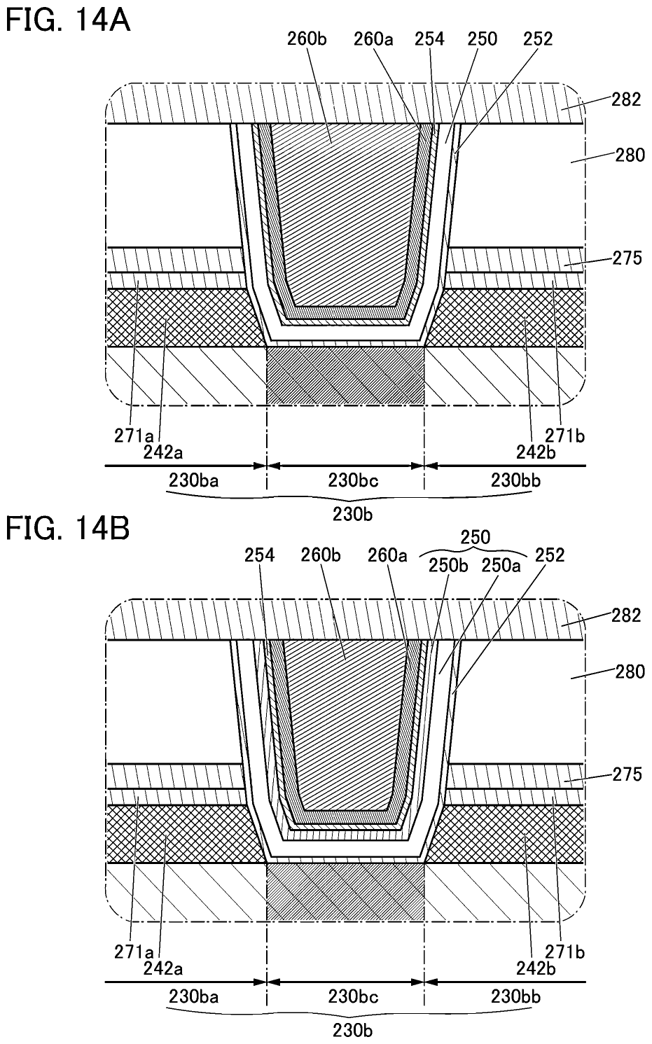

Here, FIG. 14A shows an enlarged view of the vicinity of the channel formation region in FIG. 13B. Supply of oxygen to the oxide 230b forms the channel formation region in a region between the conductor 242a and the conductor 242b. Thus, as illustrated in FIG. 14A, the oxide 230b includes a region 230bc functioning as the channel formation region of the transistor 200 and a region 230ba and a region 230bb that are provided to sandwich the region 230bc and function as a source region and a drain region. At least part of the region 230bc overlaps with the conductor 260. In other words, the region 230bc is provided between the conductor 242a and the conductor 242b. The region 230ba is provided to overlap with the conductor 242a, and the region 230bb is provided to overlap with the conductor 242b.

The region 230bc functioning as the channel formation region has a smaller amount of oxygen vacancies or a lower impurity concentration than the regions 230ba and 230bb, in other words, the region 230bc is a high-resistance region with a low carrier concentration. Thus, the region 230bc can be regarded as being i-type (intrinsic) or substantially i-type. Performing microwave treatment in an atmosphere containing oxygen facilitates formation of the region 230bc, for example. Here, the microwave treatment refers to, for example, treatment using an apparatus including a power source that generates high-density plasma with use of a microwave. Note that in this specification and the like, a microwave refers to an electromagnetic wave having a frequency of 300 MHz to 300 GHz inclusive.

The region 230ba and the region 230bb functioning as the source region and the drain region are each a low-resistance region with an increased carrier concentration because they include a large amount of oxygen vacancies or have a high concentration of an impurity such as hydrogen, nitrogen, and a metal element. In other words, the region 230ba and the region 230bb are each an n-type region having a higher carrier concentration and a lower resistance than the region 230bc.

The carrier concentration in the region 230bc functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10⁻¹³ cm⁻³, and yet still further preferably lower than 1×10¹² cm⁻³. Note that the lower limit of the carrier concentration in the region 230bc functioning as the channel formation region is not particularly limited and can be, for example, 1×10⁻⁹ cm⁻³.

Between the region 230bc and the region 230ba or the region 230bb, a region having a carrier concentration that is lower than or substantially equal to the carrier concentrations in the region 230ba and the region 230bb and higher than or substantially equal to the carrier concentration in the region 230bc may be formed. That is, the region functions as a junction region between the region 230bc and the region 230ba or the region 230bb. The hydrogen concentration in the junction region is lower than or substantially equal to the hydrogen concentrations in the region 230ba and the region 230bb and higher than or substantially equal to the hydrogen concentration in the region 230bc in some cases. The amount of oxygen vacancies in the junction region is smaller than or substantially equal to the amounts of oxygen vacancies in the region 230ba and the region 230bb and larger than or substantially equal to the amount of oxygen vacancies in the region 230bc in some cases.

Although FIG. 14A illustrates an example in which the region 230ba, the region 230bb, and the region 230bc are formed in the oxide 230b, the present invention is not limited thereto. For example, the above regions may be formed not only in the oxide 230b but also in the oxide 230a.

In the oxide 230, the boundaries between the regions are difficult to detect clearly in some cases. The concentration of a metal element and an impurity element such as hydrogen or nitrogen, which is detected in each region, may be gradually changed not only between the regions but also in each region. That is, the region closer to the channel formation region preferably has lower concentrations of a metal element and an impurity element such as hydrogen or nitrogen.

In the transistor 200, a metal oxide functioning as a semiconductor (such a metal oxide is hereinafter also referred to as an oxide semiconductor) is preferably used for the oxide 230 (the oxide 230a and the oxide 230b) including the channel formation region.

The metal oxide functioning as a semiconductor preferably has a band gap of 2 eV or more, further preferably 2.5 eV or more. With use of a metal oxide having such a large bandgap, the off-state current of the transistor can be reduced.

As the oxide 230, it is preferable to use, for example, a metal oxide such as an In-M-Zn oxide containing indium, an element M, and zinc (the element M is one or more kinds selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, magnesium, and the like). Alternatively, an In—Ga oxide, an In—Zn oxide, or an indium oxide may be used as the oxide 230.

The atomic ratio of In to the element M in the metal oxide used as the oxide 230b is preferably greater than the atomic ratio of In to the element M in the metal oxide used as the oxide 230a.

The oxide 230a is placed under the oxide 230b, whereby impurities and oxygen can be inhibited from diffusing into the oxide 230b from components formed below the oxide 230a.

When the oxide 230a and the oxide 230b contain a common element (as the main component) besides oxygen, the density of defect states at an interface between the oxide 230a and the oxide 230b can be made low. Since the density of defect states at the interface between the oxide 230a and the oxide 230b can be made low, the influence of interface scattering on carrier conduction is small, and a high on-state current can be obtained.

The oxide 230b preferably has crystallinity. It is particularly preferable to use CAAC-OS as the oxide 230b.

The CAAC-OS is a metal oxide having a dense structure with high crystallinity and a small amount of impurities or defects (e.g., oxygen vacancies (V_{O})). In particular, after the formation of a metal oxide, heat treatment is performed at a temperature at which the metal oxide does not become a polycrystal (e.g., 400° C. to 600° C. inclusive), whereby a CAAC-OS having a dense structure with higher crystallinity can be obtained. When the density of the CAAC-OS is increased in such a manner, diffusion of impurities or oxygen in the CAAC-OS can be further reduced.

On the other hand, a clear crystal grain boundary cannot be observed in the CAAC-OS; thus, it can be said that a reduction in electron mobility due to the crystal grain boundary is less likely to occur. Thus, a metal oxide including a CAAC-OS is physically stable. Therefore, the metal oxide including a CAAC-OS is resistant to heat and has high reliability.

Furthermore, a curved surface may be provided between a side surface of the oxide 230b and the top surface of the oxide 230b in a cross-sectional view of the transistor 200 in the channel width direction. In other words, an end portion of the side surface and an end portion of the top surface may be curved (hereinafter referred to as rounded).

The radius of curvature of the curved surface is preferably greater than 0 nm and less than the thickness of the oxide 230b in a region overlapping with the conductor 242, or less than half of the length of a region that does not have the curved surface. Specifically, the radius of curvature of the curved surface is greater than 0 nm and less than or equal to 20 nm, preferably greater than or equal to 1 nm and less than or equal to 15 nm, and further preferably greater than or equal to 2 nm and less than or equal to 10 nm. Such a shape can improve the coverage of the oxide 230b with the insulator 252, the insulator 250, the insulator 254, and the conductor 260.

The oxide 230 preferably has a stacked-layer structure of a plurality of oxide layers with different chemical compositions. Specifically, the atomic ratio of the element M to a metal element that is a main component of the metal oxide used as the oxide 230a is preferably greater than the atomic ratio of the element M to a metal element that is a main component of the metal oxide used as the oxide 230b. Moreover, the atomic ratio of the element M to In in the metal oxide used as the oxide 230a is preferably greater than the atomic ratio of the element M to In in the metal oxide used as the oxide 230b. Furthermore, the atomic ratio of In to the element M in the metal oxide used as the oxide 230b is preferably greater than the atomic ratio of In to the element M in the metal oxide used as the oxide 230a.

The oxide 230b is preferably an oxide having crystallinity, such as a CAAC-OS. An oxide having crystallinity, such as a CAAC-OS, has a dense structure with small amounts of impurities and defects (e.g., oxygen vacancies) and high crystallinity. This can inhibit oxygen extraction from the oxide 230b by the source electrode or the drain electrode. This can reduce oxygen extraction from the oxide 230b even when heat treatment is performed; thus, the transistor 200 is stable with respect to high temperatures in a manufacturing process (what is called thermal budget).

Here, the conduction band minimum gradually changes at a junction portion of the oxide 230a and the oxide 230b. In other words, the conduction band minimum at the junction portion of the oxide 230a and the oxide 230b continuously changes or is continuously connected. To achieve this, the density of defect states in a mixed layer formed at the interface between the oxide 230a and the oxide 230b is preferably made low.

Specifically, when the oxide 230a and the oxide 230b contain a common element as a main component besides oxygen, a mixed layer with a low density of defect states can be formed. For example, in the case where the oxide 230b is an In-M-Zn oxide, an In-M-Zn oxide, an M-Zn oxide, an oxide of the element M, an In—Zn oxide, indium oxide, or the like may be used as the oxide 230a.

Specifically, as the oxide 230a, a metal oxide with a composition of In:M:Zn=1:3:4 [atomic ratio] or in the neighborhood thereof, or a composition of In:M:Zn=1:1:0.5 [atomic ratio] or in the neighborhood thereof is used. As the oxide 230b, a metal oxide with In:M:Zn=1:1:1 [atomic ratio] or a composition in the neighborhood thereof, In:M:Zn=1:1:2 [atomic ratio] or a composition in the neighborhood thereof, or In:M:Zn=4:2:3 [atomic ratio] or a composition in the neighborhood thereof is used. Note that a composition in the neighborhood includes the range of ±30% of an intended atomic ratio. Gallium is preferably used as the element M.

Here, the oxide 230a and the oxide 230b are preferably formed using a sputtering method. Oxygen or a mixed gas of oxygen and a rare gas is used as the sputtering gas. Increasing the proportion of oxygen contained in the sputtering gas can increase the amount of oxygen in the deposited films. The deposition method of the oxide 230a and the oxide 230b is not limited to a sputtering method, and a CVD method, an MBE method, a PLD method, an ALD method, or the like can be used as appropriate.

When the metal oxide is deposited by a sputtering method, the above atomic ratio is not limited to the atomic ratio of the deposited metal oxide and may be the atomic ratio of a sputtering target used for depositing the metal oxide.

When the oxide 230a and the oxide 230b have the above structure, the density of defect states at the interface between the oxide 230a and the oxide 230b can be made low. Thus, the influence of interface scattering on carrier conduction is small, and the transistor 200 can have a high on-state current and excellent frequency characteristics.

At least one of the insulator 212, the insulator 214, the insulator 271, the insulator 275, the insulator 282, the insulator 283, the insulator 288, and the insulator 286 preferably functions as a barrier insulating film, which inhibits diffusion of impurities such as water and hydrogen from the substrate side or above the transistor 200 into the transistor 200. Thus, for at least one of the insulator 212, the insulator 214, the insulator 271, the insulator 275, the insulator 282, the insulator 283, the insulator 288, and the insulator 286, it is preferable to use an insulating material that has a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (through which the impurities are less likely to pass). Alternatively, it is preferable to use an insulating material having a function of inhibiting diffusion of oxygen (e.g., at least one of oxygen atoms, oxygen molecules, and the like)(an insulating material through which the oxygen is less likely to pass).

An insulator having a function of inhibiting diffusion of oxygen and impurities such as water and hydrogen is preferably used as the insulator 212, the insulator 214, the insulator 271, the insulator 275, the insulator 282, the insulator 283, the insulator 288, and the insulator 286; for example, aluminum oxide, magnesium oxide, hafnium oxide, gallium oxide, indium gallium zinc oxide, silicon nitride, or silicon nitride oxide can be used. For example, silicon nitride, which has a higher hydrogen barrier property, is preferably used for the insulator 212, the insulator 275, the insulator 283, the insulator 288, and the insulator 286. For example, aluminum oxide or magnesium oxide, which has a high-performance function of trapping and fixing hydrogen, is preferably used for the insulator 214, the insulator 271, and the insulator 282. In this case, impurities such as water and hydrogen can be inhibited from diffusing into the transistor 200 side from the substrate side through the insulator 212 and the insulator 214. Impurities such as water and hydrogen can be inhibited from diffusing into the transistor 200 side from an interlayer insulating film and the like which are provided outside the insulator 285. Alternatively, oxygen contained in the insulator 224 and the like can be inhibited from diffusing into the substrate side through the insulator 212 and the insulator 214. Alternatively, oxygen contained in the insulator 280 and the like can be inhibited from diffusing into above the transistor 200 through the insulator 282 and the like. In this manner, it is preferable that the transistor 200 be surrounded by the insulator 212, the insulator 214, the insulator 271, the insulator 275, the insulator 282, the insulator 283, the insulator 288, and the insulator 286, which have a function of inhibiting diffusion of oxygen and impurities such as water and hydrogen.

As illustrated in FIG. 13B, the semiconductor device including the transistor 200 has a structure sandwiched between the insulator 286 and the insulator 212 each of which has a hydrogen barrier property, and thus hydrogen is less likely to diffuse into the transistor 200. The insulator 286 is provided to cover the insulator 285 and the conductor 246, whereby the amount of hydrogen diffusing into the transistor 200 through the conductor 246 can be reduced. On the inner side thereof, the transistor 200 is sealed by the insulator 212 and the insulator 283 and the insulator 288 each of which has a hydrogen barrier property. Thus, hydrogen diffusing into the transistor 200 can be further inhibited. On the further inner side, the insulator 214, the insulator 271, and the insulator 282, each of which has a high-performance function of trapping and fixing hydrogen, are provided, whereby low-concentration hydrogen in the vicinity of the transistor 200 is prevented from diffusing into the oxide 230.

An oxide having an amorphous structure is preferably used for the insulator 214, the insulator 271, the insulator 275, and the insulator 282. For example, a metal oxide such as AlO, (x is a given number greater than 0) or MgO_{y} (y is a given number greater than 0) is preferably used. In such a metal oxide having an amorphous structure, an oxygen atom has a dangling bond and sometimes has a property of trapping or fixing hydrogen with the dangling bond. When such a metal oxide having an amorphous structure is used as the component of the transistor 200 or provided around the transistor 200, hydrogen contained in the transistor 200 or hydrogen present around the transistor 200 can be trapped or fixed. In particular, hydrogen contained in the channel formation region of the transistor 200 is preferably trapped or fixed. The metal oxide having an amorphous structure is used as the component of the transistor 200 or provided around the transistor 200, whereby the transistor 200 and a semiconductor device which have favorable characteristics and high reliability can be manufactured.

Although the insulator 214, the insulator 271, the insulator 275, and the insulator 282 preferably have an amorphous structure, they may partly include a region with a polycrystalline structure. The insulator 214, the insulator 271, the insulator 275, and the insulator 282 may have a multilayer structure in which a layer with an amorphous structure and a layer with a polycrystalline structure are stacked. For example, a stacked-layer structure in which a layer having a polycrystalline structure is formed over a layer having an amorphous structure may be employed.

The insulator 212a, the insulator 214, the insulator 271, the insulator 275, the insulator 282, the insulator 283, and the insulator 286a can be deposited by a sputtering method, for example. Since a sputtering method does not need to use a molecule containing hydrogen as a deposition gas, the hydrogen concentrations in the insulator 212a, the insulator 214, the insulator 271, the insulator 275, the insulator 282, the insulator 283, and the insulator 286a can be reduced. The insulator 212b, the insulator 288, and the insulator 286b are preferably deposited by an ALD method, particularly a PEALD method. By the method, the insulator 212b, the insulator 288, and the insulator 286b can be formed to have a good coverage; accordingly, the hydrogen barrier property of the insulator 212, the insulator 286, the insulator 283, and the insulator 288 can be improved.

Note that the film deposition method is not limited to a sputtering method and an ALD method, and a CVD method, an MBE method, a PLD method, or the like can be used as appropriate.

The resistivities of the insulator 212, the insulator 275, the insulator 283, and the insulator 286 are preferably low in some cases. For example, by setting the resistivities of the insulator 212, the insulator 275, the insulator 283, and the insulator 286 to approximately 1×10¹³ Ωcm, the insulator 212, the insulator 275, the insulator 283, and the insulator 286 can sometimes reduce charge up of the conductor 205, the conductor 242, the conductor 260, or the conductor 246 in treatment using plasma or the like in the manufacturing process of a semiconductor device. The resistivities of the insulator 212, the insulator 275, the insulator 283, and the insulator 286 are preferably higher than or equal to 1×10¹⁰ Ωcm and lower than or equal to 1×10¹⁵ Ωcm.

The insulator 216, the insulator 274, the insulator 280, and the insulator 285 each preferably have a lower permittivity than the insulator 214. When a material with a low permittivity is used for an interlayer film, parasitic capacitance generated between wirings can be reduced. For the insulator 216, the insulator 274, the insulator 280, and the insulator 285, silicon oxide, silicon oxynitride, silicon oxide to which fluorine is added, silicon oxide to which carbon is added, silicon oxide to which carbon and nitrogen are added, porous silicon oxide, or the like is used as appropriate, for example.

The conductor 205 is placed to overlap with the oxide 230 and the conductor 260. Here, the conductor 205 is preferably provided to be embedded in an opening formed in the insulator 216. Part of the conductor 205 is embedded in the insulator 214 in some cases.

The conductor 205 includes the conductor 205a and the conductor 205b. The conductor 205a is provided in contact with the bottom surface and the sidewall of the opening. The conductor 205b is provided to be embedded in a recessed portion formed in the conductor 205a. Here, the top surface of the conductor 205b is substantially level with the top surface of the conductor 205a and the top surface of the insulator 216.

Here, for the conductor 205a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material that has a function of inhibiting diffusion of oxygen (e.g., at least one of an oxygen atom, an oxygen molecule, and the like).

When the conductor 205a is formed using a conductive material having a function of inhibiting diffusion of hydrogen, impurities such as hydrogen contained in the conductor 205b can be prevented from diffusing into the oxide 230 through the insulator 224 and the like. When the conductor 205a is formed using a conductive material having a function of inhibiting diffusion of oxygen, the conductivity of the conductor 205b can be inhibited from being lowered because of oxidation. As the conductive material having a function of inhibiting diffusion of oxygen, for example, titanium, titanium nitride, tantalum, tantalum nitride, ruthenium, or ruthenium oxide is preferably used. Thus, a single layer or a stacked layer of the above conductive material is used as the conductor 205a. For example, titanium nitride is used for the conductor 205a.

Moreover, the conductor 205b is preferably formed using a conductive material containing tungsten, copper, or aluminum as its main component. For example, tungsten is used for the conductor 205b.

The conductor 205 sometimes functions as a second gate electrode. In that case, by changing a potential applied to the conductor 205 not in conjunction with but independently of a potential applied to the conductor 260, the threshold voltage (Vth) of the transistor 200 can be controlled. In particular, Vth of the transistor 200 can be higher in the case where a negative potential is applied to the conductor 205, and the off-state current can be reduced. Thus, a drain current at the time when a potential applied to the conductor 260 is 0 V can be lower in the case where a negative potential is applied to the conductor 205 than in the case where the negative potential is not applied to the conductor 205.

The electric resistivity of the conductor 205 is designed in consideration of the potential applied to the conductor 205, and the thickness of the conductor 205 is determined in accordance with the electric resistivity. The thickness of the insulator 216 is substantially equal to that of the conductor 205. The conductor 205 and the insulator 216 are preferably as thin as possible in the allowable range of the design of the conductor 205. When the thickness of the insulator 216 is reduced, the absolute amount of impurities such as hydrogen contained in the insulator 216 can be reduced, reducing the amount of the impurities to be diffused into the oxide 230.

As illustrated in FIG. 13A, the conductor 205 is preferably provided so as to be larger than a region of the oxide 230 that does not overlap with the conductor 242a or the conductor 242b. It is preferable that the conductor 205 extend also to a region beyond end portions of the oxide 230a and the oxide 230b in the channel width direction. That is, the conductor 205 and the conductor 260 preferably overlap with each other with the insulators therebetween on the outer side of the side surface of the oxide 230 in the channel width direction. With this structure, the channel formation region of the oxide 230 can be electrically surrounded by the electric field of the conductor 260 functioning as a first gate electrode and the electric field of the conductor 205 functioning as the second gate electrode. In this specification, a transistor structure in which a channel formation region is electrically surrounded by the electric fields of the first gate and the second gate is referred to as a surrounded channel (S-channel) structure.

In this specification and the like, a transistor having the S-channel structure refers to a transistor having a structure in which a channel formation region is electrically surrounded by the electric fields of a pair of gate electrodes. The S-channel structure disclosed in this specification and the like is different from a Fin-type structure and a planar structure. With the S-channel structure, resistance to a short-channel effect can be enhanced, that is, a transistor in which a short-channel effect is less likely to occur can be provided.

Furthermore, the conductor 205 is extended to function as a wiring as well. However, without limitation to this structure, a structure in which a conductor functioning as a wiring is provided below the conductor 205 may be employed. In addition, the conductor 205 is not necessarily provided in each transistor. For example, the conductor 205 may be shared by a plurality of transistors.

Although the transistor 200 having a structure in which the conductor 205 is a stack of the conductor 205a and the conductor 205b is illustrated, the present invention is not limited thereto. For example, the conductor 205 may be provided to have a single-layer structure or a stacked-layer structure of three or more layers.

The insulator 222 and the insulator 224 function as a gate insulator.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of inhibiting diffusion of one or both of hydrogen and oxygen more than the insulator 224.

As the insulator 222, an insulator containing an oxide of one or both of aluminum and hafnium, which is an insulating material, is preferably used. For the insulator, aluminum oxide, hafnium oxide, an oxide containing aluminum and hafnium (hafnium aluminate), or the like is preferably used. In the case where the insulator 222 is formed using such a material, the insulator 222 functions as a layer that inhibits release of oxygen from the oxide 230 to the substrate side and diffusion of impurities such as hydrogen from the periphery of the transistor 200 into the oxide 230. Thus, providing the insulator 222 can inhibit diffusion of impurities such as hydrogen into the transistor 200 and inhibit generation of oxygen vacancies in the oxide 230. Moreover, the conductor 205 can be inhibited from reacting with oxygen contained in the insulator 224 or the oxide 230.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, the insulator may be subjected to nitriding treatment. A stack of silicon oxide, silicon oxynitride, or silicon nitride over these insulators may be used for the insulator 222.

For example, a single layer or stacked layers of an insulator(s) containing what is called a high-k material such as aluminum oxide, hafnium oxide, tantalum oxide, or zirconium oxide may be used for the insulator 222. As miniaturization and high integration of transistors progress, a problem such as a leakage current may arise because of a thinner gate insulator. When a high-k material is used for an insulator functioning as the gate insulator, a gate potential at the time when the transistor operates can be reduced while the physical thickness is maintained. Furthermore, a substance with a high permittivity such as lead zirconate titanate (PZT), strontium titanate (SrTiO₃), or (Ba,Sr)TiO₃ (BST) may be used for the insulator 222.

Silicon oxide or silicon oxynitride, for example, can be used as appropriate for the insulator 224 that is in contact with the oxide 230.

In a manufacturing process of the transistor 200, heat treatment is preferably performed with a surface of the oxide 230 exposed. For example, the heat treatment is performed at a temperature higher than or equal to 100° C. and lower than or equal to 600° C., preferably higher than or equal to 350° C. and lower than or equal to 550° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. This can supply oxygen to the oxide 230 to reduce oxygen vacancies (V_{O}). The heat treatment may be performed under reduced pressure. Alternatively, heat treatment may be performed in an atmosphere containing an oxidizing gas at 10 ppm or more, 1% or more, or 10% or more in order to compensate for released oxygen after heat treatment in a nitrogen gas or inert gas atmosphere. Alternatively, heat treatment may be performed in a nitrogen gas or inert gas atmosphere successively after heat treatment in an atmosphere containing an oxidizing gas at 10 ppm or more, 1% or more, or 10% or more.

Note that oxygen adding treatment performed on the oxide 230 can promote a reaction in which oxygen vacancies in the oxide 230 are repaired with supplied oxygen, i.e., a reaction of “V_{O}+O→null”. Furthermore, hydrogen remaining in the oxide 230 reacts with supplied oxygen, so that the hydrogen can be removed as H₂O (dehydration). This can inhibit recombination of hydrogen remaining in the oxide 230 with oxygen vacancies and formation of V_{O}H.

Such heat treatment can make the oxide 230 having a dense structure with higher crystallinity. The density of the oxide 230 is improved in this manner, which further reduces the diffusion of impurities or oxygen in the oxide 230.

Note that the insulator 222 and the insulator 224 may each have a stacked-layer structure of two or more layers. In that case, without limitation to a stacked-layer structure formed of the same material, a stacked-layer structure formed of different materials may be employed. The insulator 224 may be formed into an island shape so as to overlap with the oxide 230a. In this case, the insulator 275 is in contact with the side surface of the insulator 224 and the top surface of the insulator 222.

The conductor 242a and the conductor 242b are provided in contact with the top surface of the oxide 230b. Each of the conductor 242a and the conductor 242b functions as a source electrode or a drain electrode of the transistor 200.

For the conductor 242 (the conductor 242a and the conductor 242b), for example, a nitride containing tantalum, a nitride containing titanium, a nitride containing molybdenum, a nitride containing tungsten, a nitride containing tantalum and aluminum, a nitride containing titanium and aluminum, or the like is preferably used. In one embodiment of the present invention, a nitride containing tantalum is particularly preferable. As another example, ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

Note that hydrogen contained in the oxide 230b or the like diffuses into the conductor 242a or the conductor 242b in some cases. In particular, when a nitride containing tantalum is used for the conductor 242a and the conductor 242b, hydrogen contained in the oxide 230b or the like is likely to diffuse into the conductor 242a or the conductor 242b, and the diffused hydrogen is bonded to nitrogen contained in the conductor 242a or the conductor 242b in some cases. That is, hydrogen contained in the oxide 230b or the like is absorbed by the conductor 242a or the conductor 242b in some cases.

No curved surface is preferably formed between the side surface of the conductor 242 and the top surface of the conductor 242. When no curved surface is formed in the conductor 242, the conductor 242 can have a large cross-sectional area in the channel width direction. Accordingly, the conductivity of the conductor 242 is increased, so that the on-state current of the transistor 200 can be increased.

The insulator 271a is provided in contact with the top surface of the conductor 242a, and the insulator 271b is provided in contact with the top surface of the conductor 242b. The insulator 271 preferably functions as at least a barrier insulating film against oxygen. Thus, the insulator 271 preferably has a function of inhibiting oxygen diffusion. For example, the insulator 271 preferably has a function of inhibiting diffusion of oxygen more than the insulator 280. For example, a nitride containing silicon such as silicon nitride may be used for the insulator 271. The insulator 271 preferably has a function of trapping impurities such as hydrogen. In that case, for the insulator 271, a metal oxide having an amorphous structure, for example, an insulator such as aluminum oxide or magnesium oxide, may be used. It is particularly preferable to use aluminum oxide having an amorphous structure or amorphous aluminum oxide for the insulator 271 because hydrogen can be trapped or fixed more effectively in some cases. Accordingly, the transistor 200 and a semiconductor device which have favorable characteristics and high reliability can be manufactured.

The insulator 275 is provided to cover the insulator 224, the oxide 230a, the oxide 230b, the conductor 242, and the insulator 271. The insulator 275 preferably has a function of trapping and fixing hydrogen. In that case, the insulator 275 preferably includes silicon nitride, or a metal oxide having an amorphous structure, for example, an insulator such as aluminum oxide or magnesium oxide. Alternatively, for example, a stacked-layer film of aluminum oxide and silicon nitride over the aluminum oxide may be used as the insulator 275. For example, aluminum oxide may be deposited by a sputtering method, and silicon nitride may be deposited by a PEALD method.

When the above insulator 271 and the insulator 275 are provided, the conductor 242 can be surrounded by the insulators having a barrier property against oxygen. That is, oxygen contained in the insulator 224 and the insulator 280 can be prevented from diffusing into the conductor 242. As a result, the conductor 242 can be inhibited from being directly oxidized by oxygen contained in the insulator 224 and the insulator 280, so that an increase in resistivity and a reduction in on-state current can be inhibited.

The insulator 252 functions as part of the gate insulator. As the insulator 252, a barrier insulating film against oxygen is preferably used. As the insulator 252, an insulator that can be used as the insulator 282 described above may be used. An insulator containing an oxide of one or both of aluminum and hafnium may be used as the insulator 252. As the insulator, aluminum oxide, hafnium oxide, an oxide containing aluminum and hafnium (hafnium aluminate), an oxide containing hafnium and silicon (hafnium silicate), or the like can be used. In this embodiment, aluminum oxide is used for the insulator 252. In this case, the insulator 252 is an insulator containing at least oxygen and aluminum.

The insulator 252 is preferably provided in contact with the top surface and side surface of the oxide 230b, the side surface of the oxide 230a, the side surface of the insulator 224, and the top surface of the insulator 222, also in the channel width direction. That is, the regions of the oxide 230a, the oxide 230b, and the insulator 224 that overlap with the conductor 260 are covered with the insulator 252 in the cross section in the channel width direction. With this structure, the insulator 252 having a barrier property against oxygen can prevent release of oxygen from the oxide 230a and the oxide 230b at the time of heat treatment or the like. This can inhibit formation of oxygen vacancies (V_{O}) in the oxide 230a and the oxide 230b. Therefore, oxygen vacancies (V_{O}) and V_{O}H formed in the region 230bc can be reduced. Thus, the transistor 200 can have favorable electrical characteristics and higher reliability.

Even when an excess amount of oxygen is contained in the insulator 280, the insulator 250, and the like, oxygen can be inhibited from being excessively supplied to the oxide 230a and the oxide 230b. Thus, the region 230ba and the region 230bb are prevented from being excessively oxidized by oxygen through the region 230bc; a reduction in on-state current or field-effect mobility of the transistor 200 can be inhibited.

As illustrated in FIG. 13B, the insulator 252 is provided in contact with the side surfaces of the conductor 242, the insulator 271, the insulator 275, and the insulator 280. This can inhibit formation of an oxide film on the side surface of the conductor 242 by oxidization of the side surface. Accordingly, a reduction in on-state current or field-effect mobility of the transistor 200 can be inhibited.

Furthermore, the insulator 252 needs to be provided in an opening formed in the insulator 280 and the like, together with the insulator 254, the insulator 250, and the conductor 260. The thickness of the insulator 252 is preferably thin for miniaturization of the transistor 200. The thickness of the insulator 252 is greater than or equal to 0.1 nm and less than or equal to 5.0 nm, preferably greater than or equal to 0.5 nm and less than or equal to 3.0 nm, and further preferably greater than or equal to 1.0 nm and less than or equal to 3.0 nm. In that case, at least part of the insulator 252 preferably includes a region having the above-described thickness. The thickness of the insulator 252 is preferably smaller than that of the insulator 250. In that case, at least part of the insulator 252 preferably includes a region having a thickness smaller than that of the insulator 250.

To form the insulator 252 having a small thickness like the above-described thickness, an ALD method is preferably used for deposition. The ALD method includes a thermal ALD method, in which a precursor and a reactant react with each other only by a thermal energy, a PEALD method, in which a reactant excited by plasma is used, for example. The use of plasma in a PEALD method is sometimes preferable because deposition at a lower temperature is possible.

The insulator 250 functions as part of the gate insulator. The insulator 250 is preferably in contact with a top surface of the insulator 252. The insulator 250 can be formed using silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like. In particular, silicon oxide and silicon oxynitride are preferable because they are thermally stable. The insulator 250 in this case is an insulator containing at least oxygen and silicon.

As in the insulator 224, the concentration of impurities such as water and hydrogen in the insulator 250 is preferably reduced. The thickness of the insulator 250 is preferably greater than or equal to 1 nm and less than or equal to 20 nm, further preferably greater than or equal to 0.5 nm and less than or equal to 15.0 nm. In this case, it is acceptable that at least part of the insulator 250 has a region with a thickness like the above-described thickness.

Although FIG. 13A and FIG. 13B illustrate a single-layer structure of the insulator 250, the present invention is not limited to this structure, and a stacked-layer structure of two or more layers may be employed. For example, as illustrated in FIG. 14B, the insulator 250 may have a stacked-layer structure including two layers of an insulator 250a and an insulator 250b over the insulator 250a.

In the case where the insulator 250 has a stacked-layer structure of two layers as illustrated in FIG. 14B, it is preferable that the insulator 250a in a lower layer be formed using an insulator that is likely to transmit oxygen and the insulator 250b in an upper layer be formed using an insulator having a function of inhibiting oxygen diffusion. With such a structure, oxygen contained in the insulator 250a can be inhibited from diffusing into the conductor 260. That is, a reduction in the amount of oxygen supplied to the oxide 230 can be inhibited. In addition, oxidation of the conductor 260 due to oxygen contained in the insulator 250a can be inhibited. For example, it is preferable that the insulator 250a be provided using any of the above-described materials that can be used for the insulator 250 and the insulator 250b be provided using an insulator containing an oxide of one or both of aluminum and hafnium. As the insulator, aluminum oxide, hafnium oxide, an oxide containing aluminum and hafnium (hafnium aluminate), an oxide containing hafnium and silicon (hafnium silicate), or the like can be used. In this embodiment, hafnium oxide is used as the insulator 250b. In this case, the insulator 250b is an insulator containing at least oxygen and hafnium. The thickness of the insulator 250b is greater than or equal to 0.5 nm and less than or equal to 5.0 nm, preferably greater than or equal to 1.0 nm and less than or equal to 5.0 nm, further preferably greater than or equal to 1.0 nm and less than or equal to 3.0 nm. In that case, at least part of the insulator 250b may include a region having a thickness like the above-described thickness.

In the case where silicon oxide, silicon oxynitride, or the like is used for the insulator 250a, the insulator 250b may be formed using an insulating material that is a high-k material having a high dielectric constant. The gate insulator having a stacked-layer structure of the insulator 250a and the insulator 250b can be thermally stable and can have a high dielectric constant. Thus, a gate potential that is applied during operation of the transistor can be reduced while the physical thickness of the gate insulator is maintained. In addition, the equivalent oxide thickness (EOT) of the insulator functioning as the gate insulator can be reduced. Therefore, the withstand voltage of the insulator 250 can be increased.

The insulator 254 functions as part of a gate insulator. As the insulator 254, a barrier insulating film against hydrogen is preferably used. This can prevent diffusion of impurities such as hydrogen contained in the conductor 260 into the insulator 250 and the oxide 230b. As the insulator 254, an insulator that can be used as the insulator 283 described above may be used. For example, silicon nitride deposited by a PEALD method may be used as the insulator 254. In this case, the insulator 254 is an insulator containing at least nitrogen and silicon.

Furthermore, the insulator 254 may have a barrier property against oxygen. Thus, diffusion of oxygen contained in the insulator 250 into the conductor 260 can be inhibited.

Furthermore, the insulator 254 needs to be provided in an opening formed in the insulator 280 and the like, together with the insulator 252, the insulator 250, and the conductor 260. The thickness of the insulator 254 is preferably thin for miniaturization of the transistor 200. The thickness of the insulator 254 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In that case, at least part of the insulator 254 preferably includes a region having the above-described thickness. The thickness of the insulator 254 is preferably smaller than that of the insulator 250. In that case, at least part of the insulator 254 may include a region having a thickness that is smaller than that of the insulator 250.

The conductor 260 functions as the first gate electrode of the transistor 200. The conductor 260 preferably includes the conductor 260a and the conductor 260b placed over the conductor 260a. For example, the conductor 260a is preferably placed to cover the bottom surface and the side surface of the conductor 260b. Moreover, as illustrated in FIG. 13B, the top surface of the conductor 260 is substantially level with the uppermost portion of the insulator 250. Although the conductor 260 has a two-layer structure of the conductor 260a and the conductor 260b in FIG. 13B, the conductor 260 can have a single-layer structure or a stacked-layer structure of three or more layers.

For the conductor 260a, a conductive material having a function of inhibiting diffusion of impurities such as a hydrogen atom, a hydrogen molecule, a water molecule, a nitrogen atom, a nitrogen molecule, a nitrogen oxide molecule, and a copper atom is preferably used. Alternatively, it is preferable to use a conductive material that has a function of inhibiting diffusion of oxygen (e.g., at least one of an oxygen atom, an oxygen molecule, and the like).

When the conductor 260a has a function of inhibiting diffusion of oxygen, the conductivity of the conductor 260b can be inhibited from being lowered because of oxidation due to oxygen contained in the insulator 250. As the conductive material having a function of inhibiting diffusion of oxygen, for example, titanium, titanium nitride, tantalum, tantalum nitride, ruthenium, or ruthenium oxide is preferably used.

The conductor 260 also functions as a wiring and thus is preferably formed using a conductor having high conductivity. For example, a conductive material containing tungsten, copper, or aluminum as its main component can be used for the conductor 260b. The conductor 260b may have a stacked-layer structure; for example, a stacked-layer structure of the conductive material and titanium or titanium nitride may be employed.

In the transistor 200, the conductor 260 is formed in a self-aligned manner to fill the opening formed in the insulator 280 and the like. The formation of the conductor 260 in this manner allows the conductor 260 to be placed properly in a region between the conductor 242a and the conductor 242b without alignment.

In the channel width direction of the transistor 200, assuming the bottom surface of the insulator 222 is as a benchmark, the level of the bottom surface of the conductor 260 in a region where the conductor 260 and the oxide 230b do not overlap is preferably lower than the level of the bottom surface of the oxide 230b. When the conductor 260 functioning as the gate electrode covers the side surface and top surface of the channel formation region of the oxide 230b with the insulator 250 and the like therebetween, the electric field of the conductor 260 can easily act on the entire channel formation region of the oxide 230b. Thus, the on-state current of the transistor 200 can be increased and the frequency characteristics of the transistor 200 can be improved. With the bottom surface of the insulator 222 as a benchmark, the difference between the level of the bottom surface of the conductor 260 in a region where the conductor 260 does not overlap with the oxide 230a or the oxide 230b and the level of the bottom surface of the oxide 230b is greater than or equal to 0 nm and less than or equal to 100 nm, preferably greater than or equal to 3 nm and less than or equal to 50 nm, further preferably greater than or equal to 5 nm and less than or equal to 20 nm.

The insulator 280 is provided over the insulator 275, and the opening is formed in a region where the insulator 250 and the conductor 260 are to be provided. In addition, the top surface of the insulator 280 may be planarized.

The insulator 280 functioning as an interlayer film preferably has a low permittivity. When a material with a low permittivity is used for an interlayer film, parasitic capacitance generated between wirings can be reduced. The insulator 280 is preferably provided using a material similar to that for the insulator 216, for example. In particular, silicon oxide and silicon oxynitride, which have thermal stability, are preferable. Materials such as silicon oxide, silicon oxynitride, and porous silicon oxide are particularly preferable because a region containing oxygen to be released by heating can be easily formed.

The insulator 280 preferably includes an excess-oxygen region or excess oxygen. The concentration of impurities such as water and hydrogen in the insulator 280 is preferably reduced. Silicon oxide, silicon oxynitride, or the like may be used as appropriate for the insulator 280, for example. When an insulator containing excess oxygen is provided in contact with the oxide 230, oxygen vacancies in the oxide 230 can be reduced and the reliability of the transistor 200 can be improved. When the insulator 280 is deposited by a sputtering method in an oxygen-containing atmosphere, the insulator 280 containing excess oxygen can be formed. By a sputtering method that does not need to use hydrogen as a deposition gas, the concentration of hydrogen in the insulator 280 can be reduced. The insulator 282 in contact with the top surface of the insulator 280 may be deposited by a sputtering method in an atmosphere containing oxygen so that oxygen can be supplied to the insulator 280. When oxygen is supplied to the insulator 280 by the deposition of the insulator 282, the deposition method of the insulator 280 is not limited to a sputtering method, and a CVD method, an MBE method, a PLD method, an ALD method, or the like may be employed. For example, the insulator 280 may have a stacked-layer structure of silicon oxide deposited by a sputtering method and silicon oxynitride deposited thereover by a CVD method. Furthermore, silicon nitride may be stacked thereover.

The insulator 282 preferably functions as a barrier insulating film that inhibits impurities such as water and hydrogen from diffusing into the insulator 280 from above and preferably has a function of trapping impurities such as hydrogen. The insulator 282 preferably functions as a barrier insulating film that inhibits passage of oxygen. For the insulator 282, a metal oxide having an amorphous structure, for example, an insulator such as aluminum oxide can be used. In this case, the insulator 282 is an insulator containing at least oxygen and aluminum. The insulator 282, which has a function of trapping impurities such as hydrogen, is provided in contact with the insulator 280 in a region sandwiched between the insulator 212 and the insulator 283, whereby impurities such as hydrogen contained in the insulator 280 and the like can be trapped and the amount of hydrogen in the region can be constant. In particular, aluminum oxide having an amorphous structure is preferably used for the insulator 282, because hydrogen can be trapped and fixed more effectively in some cases. Accordingly, the transistor 200 and a semiconductor device which have favorable characteristics and high reliability can be manufactured.

The insulator 282 is preferably deposited by a sputtering method. When the insulator 282 is deposited by a sputtering method, oxygen can be added to the insulator 280. The deposition method of the insulator 282 is not limited to a sputtering method; a CVD method, an MBE method, a PLD method, an ALD method, or the like may be used as appropriate.

The insulator 283 functions as a barrier insulating film that inhibits impurities such as water and hydrogen from diffusing into the insulator 280 from above. The insulator 283 is placed over the insulator 282. The insulator 283 is preferably formed using a nitride containing silicon such as silicon nitride or silicon nitride oxide. For example, silicon nitride deposited by a sputtering method may be used for the insulator 283. When the insulator 283 is deposited by a sputtering method, a high-density silicon nitride film can be formed. By a sputtering method that does not need to use a molecule containing hydrogen as a deposition gas, the concentration of hydrogen in the insulator 283 can be reduced.

The insulator 288 is preferably formed using a nitride containing silicon such as silicon nitride. For example, silicon nitride deposited by a PEALD method may be used as the insulator 288. When the coverage with the insulator 288 is made better, the hydrogen barrier property of the stacked structure of the insulator 283 and the insulator 288 can be improved. Here, the CMP treatment is performed on the insulator 283, the insulator 288, and the insulator 274 until the uppermost portion of the insulator 283 is exposed. Thus, the uppermost portions of the insulator 283, the insulator 288, and the insulator 274 are substantially aligned with each other in some cases. FIG. 13B illustrates a structure in which part of the insulator 288 is removed so that part of the insulator 283 is in contact with the insulator 285; however, the present invention is not limited thereto. It is possible to employ, for example, a structure in which the insulator 283 is entirely covered with the insulator 288, and the insulator 288 is in contact with the insulator 285 in a region where the insulator 288 overlaps with the insulator 282.

For the conductor 240a and the conductor 240b, a conductive material containing tungsten, copper, or aluminum as its main component is preferably used. The conductor 240a and the conductor 240b may each have a stacked-layer structure.

In the case where the conductor 240 has a stacked-layer structure, a conductive material having a function of inhibiting passage of impurities such as water and hydrogen is preferably used for a first conductor placed in the vicinity of the insulator 285, the insulator 283, the insulator 282, the insulator 280, the insulator 275, and the insulator 271. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. Moreover, impurities such as water and hydrogen contained in a layer above the insulator 283 can be inhibited from entering the oxide 230 through the conductor 240a and the conductor 240b.

For the insulator 241a and the insulator 241b, a barrier insulating film that can be used for the insulator 275 or the like may be used. For the insulator 241a and the insulator 241b, for example, an insulator such as silicon nitride, aluminum oxide, or silicon nitride oxide may be used. Since the insulator 241a and the insulator 241b are provided in contact with the insulator 283, the insulator 282, and the insulator 271, impurities such as water and hydrogen contained in the insulator 280 or the like can be inhibited from entering the oxide 230 through the conductor 240a and the conductor 240b. In particular, silicon nitride is suitable because of its high blocking property against hydrogen. Furthermore, oxygen contained in the insulator 280 can be prevented from being absorbed by the conductor 240a and the conductor 240b.

When the insulator 241a and the insulator 241b each have a stacked-layer structure as illustrated in FIG. 13B, a first insulator in contact with an inner wall of the opening formed in the insulator 280 and the like and a second insulator on the inner side of the first insulator are preferably formed using a combination of a barrier insulating film against oxygen and a barrier insulating film against hydrogen.

For example, aluminum oxide deposited by an ALD method may be used as the first insulator and silicon nitride deposited by a PEALD method may be used as the second insulator. With this structure, oxidation of the conductor 240 can be inhibited, and hydrogen can be prevented from entering the conductor 240.

The conductor 246 (the conductor 246a and the conductor 246b) functioning as a wiring may be placed in contact with the top surface of the conductor 240a and the top surface of the conductor 240b. The conductor 246 is preferably formed using a conductive material containing tungsten, copper, or aluminum as its main component. Furthermore, the conductor may have a stacked-layer structure and may be a stack of titanium or titanium nitride and the conductive material, for example. Note that the conductor may be formed to be embedded in an opening provided in an insulator.

Although the transistor 200 described in this embodiment includes the conductor 260 that functions as a first gate electrode and the conductor 205 that functions as a second gate electrode as illustrated in FIG. 13A, the present invention is not limited thereto. Any structure may be used for a transistor as long as the transistor includes an oxide semiconductor film, and the transistor may be designed as appropriate in consideration of characteristics required for a semiconductor device. For example, the transistor may have a top-gate structure or a bottom-gate structure.

### <Component Material for Semiconductor Device>

Component materials that can be used for the semiconductor device are described below.

### <<Substrate>>

As a substrate where the transistor 200 is formed, an insulator substrate, a semiconductor substrate, or a conductor substrate may be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a storage element.

### <<Insulator>>

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage during operation of the transistor can be lowered while the physical thickness of the gate insulator is maintained. In contrast, when a material with a low dielectric constant is used for the insulator functioning as an interlayer film, parasitic capacitance generated between wirings can be reduced. Thus, a material is preferably selected depending on the function of an insulator.

Examples of the insulator with a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator with a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor using a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

The insulator functioning as the gate insulator is preferably an insulator including a region containing oxygen to be released by heating. For example, when the oxide 230 is in contact with silicon oxide or silicon oxynitride including a region containing oxygen to be released by heating, oxygen vacancies included in the oxide 230 can be compensated for.

### <<Conductor>>

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are conductive materials that are not easily oxidized or materials that retain their conductivity even after absorbing oxygen. Alternatively, a semiconductor having high electrical conductivity, typified by polycrystalline silicon containing an impurity element such as phosphorus, or silicide such as nickel silicide may be used.

A stack of a plurality of conductive layers formed of the above materials may be used. For example, a stacked-layer structure combining a material containing the above metal element and a conductive material containing oxygen may be employed. Alternatively, a stacked-layer structure combining a material containing the above metal element and a conductive material containing nitrogen may be employed. Alternatively, a stacked-layer structure combining a material containing the above metal element, a conductive material containing oxygen, and a conductive material containing nitrogen may be employed.

In the case where an oxide is used for the channel formation region of the transistor, the conductor functioning as the gate electrode preferably employs a stacked-layer structure combining a material containing the above metal element and a conductive material containing oxygen. In this case, the conductive material containing oxygen is preferably provided on the channel formation region side. When the conductive material containing oxygen is provided on the channel formation region side, oxygen released from the conductive material is easily supplied to the channel formation region.

For the conductor functioning as the gate electrode, it is preferable to use, in particular, a conductive material containing oxygen and a metal element contained in the metal oxide where the channel is formed. Alternatively, a conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With use of such a material, hydrogen contained in the metal oxide where the channel is formed can be trapped in some cases. Alternatively, hydrogen entering from an external insulator or the like can be trapped in some cases.

### <<Metal Oxide>>

The oxide 230 is preferably formed using a metal oxide functioning as a semiconductor (an oxide semiconductor). A metal oxide that can be used as the oxide 230 of the present invention is described below.

The metal oxide preferably contains at least indium or zinc. In particular, indium and zinc are preferably contained. Furthermore, aluminum, gallium, yttrium, tin, or the like is preferably contained in addition to them. Furthermore, one kind or a plurality of kinds selected from boron, titanium, iron, nickel, germanium, zirconium, molybdenum, lanthanum, cerium, neodymium, hafnium, tantalum, tungsten, magnesium, cobalt, and the like may be contained.

Here, the case where the metal oxide is an In-M-Zn oxide containing indium, the element M, and zinc is considered. The element M is aluminum, gallium, yttrium, or tin. Examples of other elements that can be used as the element M include boron, titanium, iron, nickel, germanium, zirconium, molybdenum, lanthanum, cerium, neodymium, hafnium, tantalum, tungsten, magnesium, and cobalt. Note that two or more of the above elements may be used in combination as the element M.

Note that in this specification and the like, a metal oxide containing nitrogen is also referred to as a metal oxide in some cases. A metal oxide containing nitrogen may be referred to as a metal oxynitride.

### <Classification of Crystal Structure>

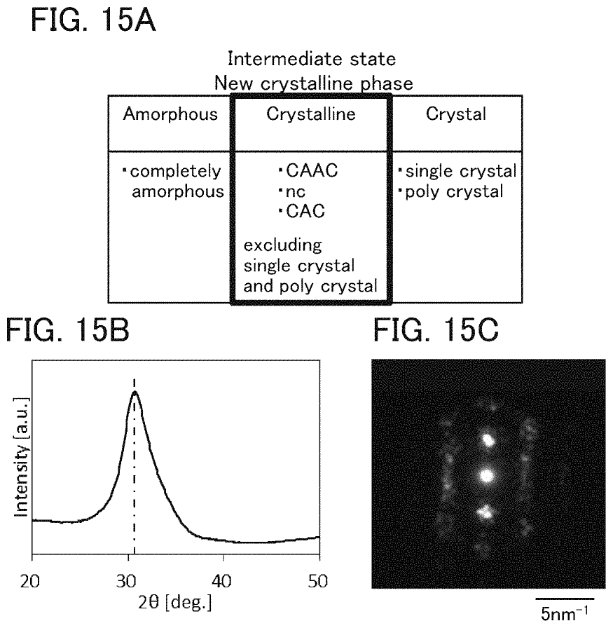

First, the classification of the crystal structures of an oxide semiconductor is explained with reference to FIG. 15A. FIG. 15A is a diagram showing the classification of crystal structures of an oxide semiconductor, typically IGZO (a metal oxide containing In, Ga, and Zn).

As shown in FIG. 15A, an oxide semiconductor is roughly classified into “Amorphous”, “Crystalline”, and “Crystal”. The term “Amorphous” includes completely amorphous. The term “Crystalline” includes CAAC (c-axis-aligned crystalline), nc (nanocrystalline), and CAC (cloud-aligned composite). Note that the term “Crystalline” excludes single crystal, poly crystal, and completely amorphous. The term “Crystal” includes single crystal and poly crystal.

Note that the structures in the thick frame in FIG. 15A are in an intermediate state between “Amorphous” and “Crystal,” and belong to a new crystalline phase. That is, these structures are completely different from “Amorphous”, which is energetically unstable, and “Crystal”.

A crystal structure of a film or a substrate can be analyzed with an X-ray diffraction (XRD) spectrum. FIG. 15B shows an XRD spectrum, which is obtained by GIXD (Grazing-Incidence XRD) measurement, of a CAAC-IGZO film classified into “Crystalline”. Note that a GIXD method is also referred to as a thin film method or a Seemann-Bohlin method. The XRD spectrum that is shown in FIG. 15B and obtained by GIXD measurement is hereinafter simply referred to as an XRD spectrum. The CAAC-IGZO film in FIG. 15B has a composition in the vicinity of In:Ga:Zn=4:2:3 [atomic ratio]. The CAAC-IGZO film in FIG. 15B has a thickness of 500 nm.

In FIG. 15B, the horizontal axis represents 26 [deg.], and the vertical axis represents intensity [a.u.]. As shown in FIG. 15B, a clear peak indicating crystallinity is detected in the XRD spectrum of the CAAC-IGZO film. Specifically, a peak indicating c-axis alignment is detected at 2θ of around 31° in the XRD spectrum of the CAAC-IGZO film. As shown in FIG. 15B, the peak at 2θ of around 31° is asymmetric with respect to the axis of the angle at which the peak intensity is detected.

A crystal structure of a film or a substrate can also be evaluated with a diffraction pattern observed by a nanobeam electron diffraction (NBED) method (such a pattern is also referred to as a nanobeam electron diffraction pattern). FIG. 15C shows a diffraction pattern of the CAAC-IGZO film. FIG. 15C shows a diffraction pattern obtained by the NBED method in which an electron beam is incident in the direction parallel to the substrate. The CAAC-IGZO film in FIG. 15C has a composition in the neighborhood of In:Ga:Zn=4:2:3 [atomic ratio]. In the nanobeam electron diffraction method, electron diffraction is performed with a probe diameter of 1 nm.

As shown in FIG. 15C, a plurality of spots indicating c-axis alignment are observed in the diffraction pattern of the CAAC-IGZO film.

### <<Structure of Oxide Semiconductor>>

Oxide semiconductors might be classified in a manner different from that in FIG. 15A when classified in terms of the crystal structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter an In layer) and a layer containing the element M, zinc (Zn), and oxygen (hereinafter an (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM image, for example.

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, a lattice arrangement in the crystal region is basically a hexagonal lattice arrangement; however, a unit lattice is not always a regular hexagon and is a non-regular hexagon in some cases. Furthermore, a pentagonal or heptagonal lattice arrangement, for example, is included in the distortion in some cases. Note that a clear crystal grain boundary (grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, or the like.

A crystal structure in which a clear crystal grain boundary is observed is what is called polycrystal. It is highly probable that the grain boundary becomes a recombination center and traps carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is less likely to occur. Moreover, since the crystallinity of an oxide semiconductor might be decreased by entry of impurities, formation of defects, and the like, the CAAC-OS can be regarded as an oxide semiconductor that has small amounts of impurities, defects, and the like (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., larger than or equal to 1 nm and smaller than or equal to 30 nm).

[a-Like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has higher hydrogen concentration in the film than the nc-OS and the CAAC-OS.

### <<Composition of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted with [In], [Ga], and [Zn], respectively. For example, the first region in the CAC-OS in the In—Ga—Zn oxide has [In] higher than that in the composition of the CAC-OS film. Moreover, the second region has [Ga] higher than that in the composition of the CAC-OS film. For example, the first region has higher [In] and lower [Ga] than the second region. Moreover, the second region has higher [Ga] and lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

In the case where the CAC-OS is used for a transistor, a switching function (on/off switching function) can be given to the CAC-OS owing to the complementary action of the conductivity derived from the first region and the insulating property derived from the second region. A CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Ion), high field-effect mobility (μ), and excellent switching operation can be achieved.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor with a low carrier concentration is preferably used for a channel formation region of the transistor. For example, the carrier concentration in an oxide semiconductor in the channel formation region is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor with a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Electric charge trapped by the trap states in the oxide semiconductor takes a long time to disappear and might behave like fixed electric charge. Thus, a transistor whose channel formation region is formed in an oxide semiconductor with a high density of trap states has unstable electrical characteristics in some cases.

Accordingly, in order to obtain stable electrical characteristics of a transistor, reducing impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the channel formation region in the oxide semiconductor and the concentration of silicon or carbon in the vicinity of an interface with the channel formation region in the oxide semiconductor (the concentrations obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the channel formation region in the oxide semiconductor, which is obtained by SIMS, is lower than or equal to 1×10¹⁸ atoms/cm³, preferably lower than or equal to 2×10¹⁶ atoms/cm³.

When the oxide semiconductor contains nitrogen, the oxide semiconductor easily becomes n-type by generation of electrons serving as carriers and an increase in carrier concentration. Thus, a transistor using an oxide semiconductor containing nitrogen as the semiconductor tends to have normally-on characteristics. When nitrogen is contained in the oxide semiconductor, a trap state is sometimes formed. This might make the electrical characteristics of the transistor unstable. Therefore, the concentration of nitrogen in the channel formation region in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the channel formation region in the oxide semiconductor is preferably reduced as much as possible. Specifically, the hydrogen concentration in the channel formation region in the oxide semiconductor, which is obtained by SIMS, is set lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, and yet still further preferably lower than 1×10¹⁸ atoms/cm³.

When an oxide semiconductor with sufficiently reduced impurities is used for the channel formation region of the transistor, stable electrical characteristics can be given.

### <<Other Semiconductor Materials>>

A semiconductor material that can be used for the oxide 230 is not limited to the above metal oxides. A semiconductor material that has a band gap (a semiconductor material that is not a zero-gap semiconductor) may be used for the oxide 230. For example, a single element semiconductor such as silicon, a compound semiconductor such as gallium arsenide, or a layered material functioning as a semiconductor (also referred to as an atomic layer material or a two-dimensional material) is preferably used as a semiconductor material. In particular, a layered material functioning as a semiconductor is preferably used as a semiconductor material.

Here, in this specification and the like, the layered material generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered material has high electrical conductivity in a monolayer, that is, high two-dimensional electrical conductivity. When a material that functions as a semiconductor and has high two-dimensional electrical conductivity is used for a channel formation region, a transistor having a high on-state current can be provided.

Examples of the layered material include graphene, silicene, and chalcogenide. Chalcogenide is a compound containing chalcogen. Chalcogen is a general term of elements belonging to Group 16, which includes oxygen, sulfur, selenium, tellurium, polonium, and livermorium. Examples of chalcogenide include transition metal chalcogenide and chalcogenide of Group 13 elements.

For the oxide 230, a transition metal chalcogenide functioning as a semiconductor is preferably used, for example. Specific examples of the transition metal chalcogenide which can be used for the oxide 230 include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfO₂), hafnium selenide (typically HfSe₂), zirconium sulfide (typically ZrS₂), and zirconium selenide (typically ZrSe₂).

### <Application Example of Semiconductor Device>

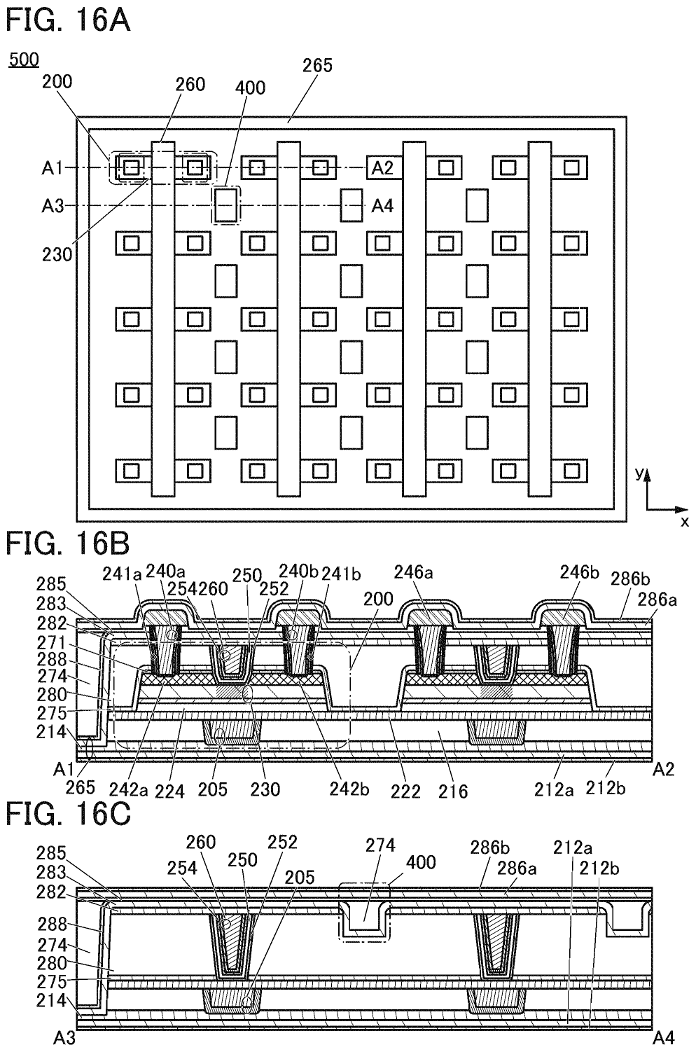

An example of the semiconductor device of one embodiment of the present invention will be described below with reference to FIG. 16.

FIG. 16A is a top view of a semiconductor device 500. In FIG. 16A, the x-axis is parallel to the channel length direction of the transistor 200, and the y-axis is perpendicular to the x-axis. FIG. 16B is a cross-sectional view corresponding to a portion indicated by the dashed-dotted line A1-A2 in FIG. 16A, and is also a cross-sectional view of the transistor 200 in the channel length direction. FIG. 16C is a cross-sectional view corresponding to a portion indicated by the dashed-dotted line A3-A4 in FIG. 16A, and is also a cross-sectional view of an opening region 400 and its vicinity. Note that for clarity of the drawing, some components are not illustrated in the top view of FIG. 16A.

Note that in the semiconductor device illustrated in FIG. 16A to FIG. 16C, components having the same functions as the components included in the semiconductor device described in <Structure example of semiconductor device> are denoted by the same reference numerals. Note that the materials described in detail in <Structure example of semiconductor device> can also be used as component materials of the semiconductor devices in this section.

The semiconductor device 500 illustrated in FIG. 16A to FIG. 16C is a modification example of the semiconductor device illustrated in FIG. 13A and FIG. 13B. The semiconductor device 500 illustrated in FIG. 16A to FIG. 16C is different from the semiconductor device illustrated in FIG. 13A and FIG. 13B in that the opening region 400 is formed in the insulator 282 and the insulator 280. Moreover, a sealing portion 265 is formed to surround a plurality of transistors 200, which is a different point from the semiconductor device illustrated in FIG. 13A and FIG. 13B.

The semiconductor device 500 includes a plurality of transistors 200 and a plurality of opening regions 400 arranged in a matrix. In addition, a plurality of conductors 260 functioning as gate electrodes of the transistors 200 are provided to extend in the y-axis direction. The opening regions 400 are provided in regions not overlapping with the oxide 230 or the conductor 260. The sealing portion 265 is formed so as to surround the plurality of transistors 200, the plurality of conductors 260, and the plurality of opening regions 400. Note that the number, the position, and the size of the transistors 200, the conductors 260, and the opening regions 400 are not limited to those illustrated in FIG. 16 and may be set as appropriate in accordance with the design of the semiconductor device 500.

As illustrated in FIG. 16B and FIG. 16C, the sealing portion 265 is provided to surround the plurality of transistors 200, the insulator 216, the insulator 222, the insulator 275, the insulator 280, and the insulator 282. In other words, the insulator 283 is provided to cover the insulator 216, the insulator 222, the insulator 275, the insulator 280, and the insulator 282. In the sealing portion 265, the insulator 283 is in contact with the top surface of the insulator 214. In the sealing portion 265, the insulator 288 and the insulator 274 are provided between the insulator 283 and the insulator 285. The uppermost portions of the insulator 288 and the insulator 274 are substantially level with the uppermost portion of the insulator 283. As the insulator 274, an insulator similar to the insulator 280 can be used.

Such a structure enables the plurality of transistors 200 to be surrounded by the insulator 283, the insulator 214, and the insulator 212. One or more of the insulator 283, the insulator 214, and the insulator 212 preferably function as a barrier insulating film against hydrogen. Accordingly, entry of hydrogen contained in the region outside the sealing portion 265 into a region in the sealing portion 265 can be inhibited.

The sealing portion may have such a structure that an opening is formed in the insulator 283, the insulator 288, the insulator 274, and the insulator 285 outside of the sealing portion 265 so that the insulator 286 and the insulator 214 are in contact with each other. Alternatively, the sealing portion may have a structure such that an opening is formed in the insulator 214, the insulator 283, the insulator 288, the insulator 274, and the insulator 285 outside the sealing portion 265 so that the insulator 286a and the insulator 212a are in contact with each other. In other words, the structure illustrated in FIG. 1C may be employed.

As illustrated in FIG. 16C, the insulator 282 has an opening portion in the opening region 400. In the opening region 400, the insulator 280 may have a groove to overlap with the opening portion in the insulator 282. The depth of the groove portion of the insulator 280 is less than or equal to the depth at which the top surface of the insulator 275 is exposed and is, for example, approximately greater than or equal to ¼ and less than or equal to ½ of the maximum thickness of the insulator 280.

As illustrated in FIG. 16C, the insulator 283 is in contact with the side surface of the insulator 282, the side surface of the insulator 280, and the top surface of the insulator 280 inside the opening region 400. Part of the insulator 274 is formed in the opening region 400 to fill the depression portion formed in the insulator 283, in some cases. At this time, the top surface of the insulator 274 formed in the opening region 400 is substantially level with the uppermost surface of the insulator 283, in some cases.

When heat treatment is performed in such a state that the opening region 400 is formed and the insulator 280 is exposed in the opening portion of the insulator 282, part of oxygen contained in the insulator 280 can be made to diffuse outwardly from the opening region 400 while oxygen is supplied to the oxide 230. This enables oxygen to be sufficiently supplied to the region functioning as the channel formation region and its vicinity in the oxide semiconductor from the insulator 280 containing oxygen to be released by heating, and also prevents an excess amount of oxygen from being supplied thereto.

At this time, hydrogen contained in the insulator 280 can be bonded to oxygen and released to the outside through the opening region 400. The hydrogen bonded to oxygen is released as water. Thus, the amount of hydrogen contained in the insulator 280 can be reduced, and hydrogen contained in the insulator 280 can be prevented from entering the oxide 230.

In FIG. 16A, the shape of the opening region 400 in the top view is substantially rectangular; however, the present invention is not limited to the shape. For example, the shape of the opening region 400 in the top view can be a rectangular shape, an elliptical shape, a circular shape, a rhombus shape, or a shape obtained by combining any of the above shapes. The area and arrangement interval of the opening regions 400 can be set as appropriate in accordance with the design of the semiconductor device including the transistor 200. For example, in the region where the density of the transistors 200 is low, the area of the opening region 400 may be increased or the arrangement interval of the opening regions 400 may be narrowed. For example, in the region where the density of the transistors 200 is high, the area of the opening region 400 may be decreased, or the arrangement interval of the opening regions 400 may be increased.

According to one embodiment of the present invention, a novel semiconductor device can be provided. According to another embodiment of the present invention, a method for manufacturing a novel semiconductor device can be provided. According to another embodiment of the present invention, a semiconductor device with a small variation in transistor characteristics can be provided. According to another embodiment of the present invention, a semiconductor device having favorable electrical characteristics can be provided. According to another embodiment of the present invention, a semiconductor device with favorable reliability can be provided. According to another embodiment of the present invention, a semiconductor device with a high on-state current can be provided. According to another embodiment of the present invention, a semiconductor device with a high field-effect mobility can be provided. According to another embodiment of the present invention, a semiconductor device with favorable frequency characteristics can be provided. According to another embodiment of the present invention, a semiconductor device that can be miniaturized or highly integrated can be provided. According to another embodiment of the present invention, a semiconductor device with low power consumption can be provided.

At least part of the structure, method, and the like described in this embodiment can be implemented in appropriate combination with any of those in the other embodiments and the like described in this specification.

### Embodiment 3

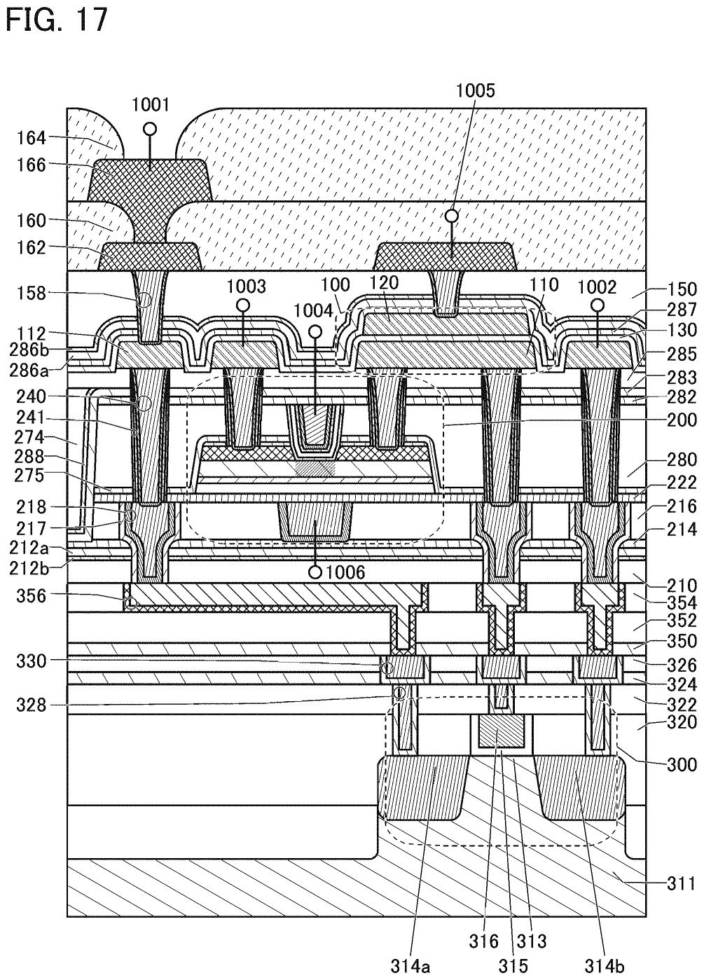

In this embodiment, one mode of a semiconductor device will be described with reference to FIG. 17.

### [Storage Device 1]

FIG. 17 illustrates an example of a semiconductor device (a storage device) of one embodiment of the present invention. In the semiconductor device of one embodiment of the present invention, the transistor 200 is provided above a transistor 300, and a capacitor 100 is provided above the transistor 300 and the transistor 200. The transistor 200 described in the above embodiment can be used as the transistor 200.

The transistor 200 is a transistor in which a channel is formed in a semiconductor layer including an oxide semiconductor. Since the transistor 200 has a low off-state current, a storage device that uses the transistor 200 can retain stored data for a long time. In other words, such a storage device does not require refresh operation or has extremely low frequency of the refresh operation, which leads to a sufficient reduction in power consumption of the storage device.

In the semiconductor device illustrated in FIG. 17, a wiring 1001 is electrically connected to a source of the transistor 300, and a wiring 1002 is electrically connected to a drain of the transistor 300. In addition, a wiring 1003 is electrically connected to one of the source and the drain of the transistor 200, a wiring 1004 is electrically connected to the first gate of the transistor 200, and a wiring 1006 is electrically connected to the second gate of the transistor 200. A gate of the transistor 300 and the other of the source and the drain of the transistor 200 are electrically connected to one electrode of the capacitor 100, and a wiring 1005 is electrically connected to the other electrode of the capacitor 100.

The storage device illustrated in FIG. 17 can form a memory cell array when arranged in a matrix.

### <Transistor 300>

The transistor 300 is provided on a substrate 311 and includes a conductor 316 functioning as a gate, an insulator 315 functioning as a gate insulator, a semiconductor region 313 formed of part of the substrate 311, and a low-resistance region 314a and a low-resistance region 314b functioning as a source region and a drain region. The transistor 300 may be a p-channel transistor or an n-channel transistor.

Here, in the transistor 300 illustrated in FIG. 17, the semiconductor region 313 (part of the substrate 311) in which a channel is formed has a convex shape. In addition, the conductor 316 is provided to cover the side surface and the top surface of the semiconductor region 313 with the insulator 315 therebetween. Note that a material adjusting the work function may be used for the conductor 316. Such a transistor 300 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI substrate.

Note that the transistor 300 illustrated in FIG. 17 is an example and the structure is not limited thereto; an appropriate transistor is used in accordance with a circuit structure or a driving method.

### <Capacitor 100>

The capacitor 100 is provided above the transistor 200. The capacitor 100 includes a conductor 110 functioning as a first electrode, a conductor 120 functioning as a second electrode, and an insulator 130 functioning as a dielectric. An insulator 287 is preferably provided to cover the insulator 130 and a conductor 112.

For example, the conductor 112 and the conductor 110 over the conductor 240 can be formed at the same time. Note that the conductor 112 functions as a plug or a wiring that is electrically connected to the capacitor 100, the transistor 200, or the transistor 300. The conductor 112 corresponds to the conductor 246 in the above embodiment, and the description of the conductor 246 can be referred to for the details of the conductor 112.

Although the conductor 112 and the conductor 110 having a single-layer structure are illustrated in FIG. 17, the structure is not limited thereto; a stacked-layer structure of two or more layers may be employed. For example, between a conductor having a barrier property and a conductor having high conductivity, a conductor that is highly adhesive to the conductor having a barrier property and the conductor having high conductivity may be formed.

The insulator 130 can be provided as stacked layers or a single layer using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, or hafnium nitride.

For example, for the insulator 130, a stacked-layer structure of a material with high dielectric strength such as silicon oxynitride and a high permittivity (high-k) material is preferably used. In the capacitor 100 having such a structure, a sufficient capacitance can be ensured owing to the high permittivity (high-k) insulator, and the dielectric strength can be increased owing to the insulator with high dielectric strength, so that the electrostatic breakdown of the capacitor 100 can be inhibited.

Examples of the insulator of a high permittivity (high-k) material (high dielectric constant material) include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Alternatively, a material having ferroelectricity may be used for the insulator 130.

Examples of a material used for the insulator 130 include a mixed crystal of hafnium oxide and zirconium oxide (also referred to as “HZO”), and a material in which an element X (the element X is silicon (Si), aluminum (Al), gadolinium (Gd), yttrium (Y), lanthanum (La), strontium (Sr), or the like) is added to hafnium oxide. Alternatively, a piezoelectric ceramic having a perovskite structure may be used for the insulator 130. For example, lead zirconate titanate (PZT), strontium bismuth tantalate (SBT), bismuth ferrite (BFO), or barium titanate may be used.

As the insulator 287, an insulator having a function of trapping and fixing hydrogen, which can be used as the insulator 214, the insulator 282, or the like, is preferably used. For example, aluminum oxide or the like is preferably used. Being provided on and in contact with the insulator 130, such an insulator 287 can trap and fix hydrogen contained in the insulator 130, so that the hydrogen concentration in the insulator 130 can be reduced. Thus, the leakage current between the conductor 110 and the conductor 120 can be reduced.

Although the capacitor 100 of the storage device illustrated in FIG. 17 has a planar shape, the storage device described in this embodiment is not limited thereto. For example, the capacitor 100 may have a cylindrical shape.

Examples of a material with high dielectric strength (a material having a low dielectric constant) include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

### <Wiring Layer>

Wiring layers provided with an interlayer film, a wiring, a plug, and the like may be provided between the components. A plurality of wiring layers can be provided in accordance with design. Here, a plurality of conductors functioning as plugs or wirings are collectively denoted by the same reference numeral in some cases. Furthermore, in this specification and the like, a wiring and a plug electrically connected to the wiring may be a single component. That is, part of a conductor functions as a wiring in some cases and part of a conductor functions as a plug in other cases.

For example, an insulator 320, an insulator 322, an insulator 324, and an insulator 326 are sequentially stacked over the transistor 300 as interlayer films. A conductor 328, a conductor 330, and the like that are electrically connected to the capacitor 100 or the transistor 200 are embedded in the insulator 320, the insulator 322, the insulator 324, and the insulator 326. Note that the conductor 328 and the conductor 330 function as a plug or a wiring.

The insulators functioning as interlayer films may also function as planarization films that cover uneven shapes therebelow. For example, the top surface of the insulator 322 may be planarized by planarization treatment using a chemical mechanical polishing (CMP) method or the like to improve planarity.

A wiring layer may be provided over the insulator 326 and the conductor 330. For example, in FIG. 17, an insulator 350, an insulator 352, and an insulator 354 are stacked in this order. Furthermore, a conductor 356 is formed in the insulator 350, the insulator 352, and the insulator 354. The conductor 356 functions as a plug or a wiring.

Similarly, a conductor 218, a conductor (the conductor 205) included in the transistor 200, and the like are embedded in an insulator 210, the insulator 212 (the insulator 212a and the insulator 212b), the insulator 214, and the insulator 216. Note that the conductor 218 has a function of a plug or a wiring that is electrically connected to the capacitor 100 or the transistor 300.

Here, like the insulator 241 described in the above embodiment, an insulator 217 is provided in contact with a side surface of the conductor 218 functioning as a plug. The insulator 217 is provided in contact with an inner wall of an opening formed in the insulator 210, the insulator 212, the insulator 214, and the insulator 216. That is, the insulator 217 is provided between the conductor 218 and each of the insulator 210, the insulator 212, the insulator 214, and the insulator 216. Note that the conductor 205 and the conductor 218 can be formed in parallel; thus, the insulator 217 is sometimes formed in contact with the side surface of the conductor 205.

As the insulator 217, an insulator such as silicon nitride, aluminum oxide, or silicon nitride oxide may be used, for example. Since the insulator 217 is provided in contact with the insulator 210, the insulator 212, the insulator 214, and the insulator 222, entry of impurities such as water or hydrogen into the oxide 230 through the conductor 218 from the insulator 210, the insulator 216, or the like can be inhibited. In particular, silicon nitride is suitable because of its high blocking property against hydrogen. Moreover, oxygen contained in the insulator 210 or the insulator 216 can be prevented from being absorbed by the conductor 218.

The insulator 217 can be formed in a manner similar to that of the insulator 241. For example, silicon nitride can be deposited by a PEALD method and an opening reaching the conductor 356 can be formed by anisotropic etching.

As in the above embodiment, the insulator 286 (the insulator 286a and the insulator 286b) functioning as a barrier insulating film is provided over the conductor 112 and the conductor 110 corresponding to the conductor 246. The insulator 286 is provided to cover the insulator 287. An insulator 150 is provided over the insulator 286. A conductor 158 is formed to be embedded in the insulator 150.

A conductor 162 is provided over the insulator 150, and an insulator 160 is provided to cover the conductor 162. A conductor 166 is provided over the insulator 160, and an insulator 164 is provided over the conductor 166. The insulator 160 and the insulator 164 can be formed using an organic resin such as polyimide. The conductor 162 and the conductor 166 can be formed using a low-resistance conductive film such as an aluminum film.

Here, part of the conductor 166 is electrically connected to the wiring 1001 and electrically connected to the transistor 300 through the conductor 162, the conductor 158, the conductor 112, and the like. Part of the conductor 162 is electrically connected to the wiring 1005 and electrically connected to a second electrode of the capacitor 100 through the conductor 158.

As described above, many interlayer insulating films, wirings, and the like, which contain impurities such as hydrogen affecting the oxide semiconductor film, are provided over the transistor 200. In particular, the insulator 160 and the insulator 164 formed using an organic resin are likely to diffuse hydrogen. However, the insulator 287 is covered with the insulator 286 that is an insulating film having a barrier property against hydrogen, which can reduce the amount of hydrogen diffusing into the transistor 200 and the like. Furthermore, when most of the conductor 120 is covered with the insulator 286, the amount of hydrogen diffusing into the transistor 200 through the conductor 112 functioning as a wiring can be significantly reduced.

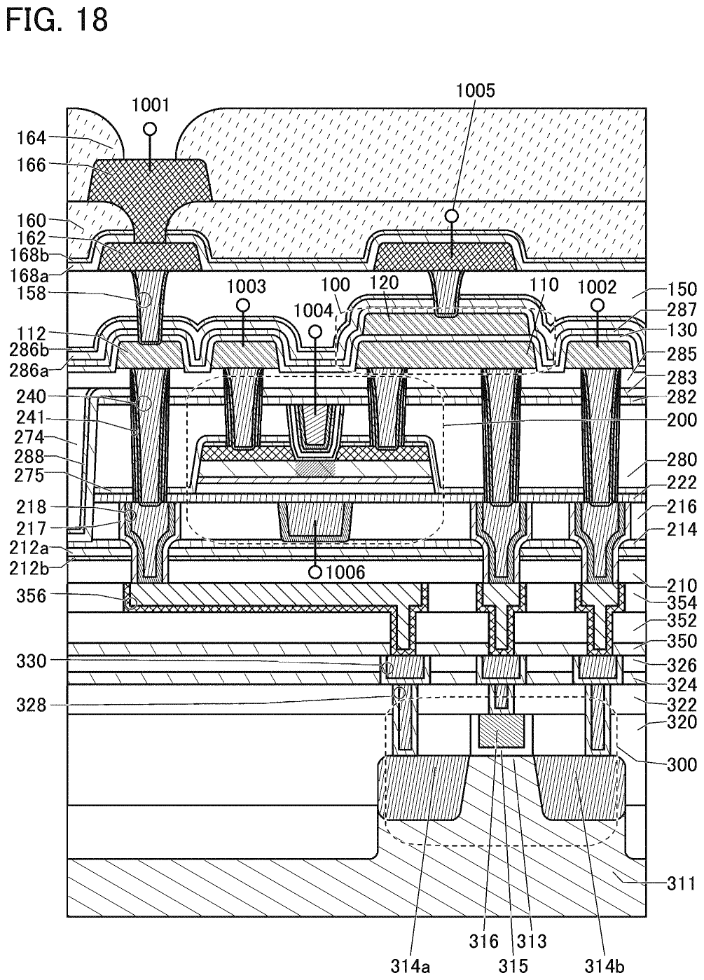

As illustrated in FIG. 18, an insulator 168a and an insulator 168b each of which functions as a barrier insulating film against hydrogen may be provided to cover the insulator 150 and the conductor 162. The insulator 168a has a structure similar to that of the insulator 286a, and accordingly the description of the insulator 286a can be referred to for the details. The insulator 168b over the insulator 168a has a structure similar to that of the insulator 286b, and accordingly the description of the insulator 286b can be referred to for the details. Hereinafter, the insulator 168a and the insulator 168b are collectively referred to as an insulator 168, in some cases.

In this manner, the insulator 168 is provided in contact with the bottom surface of the insulator 160 formed using an organic resin, whereby the amount of hydrogen diffusing below from the insulator 160 can be further reduced.

Examples of an insulator that can be used as an interlayer film include an insulating oxide, an insulating nitride, an insulating oxynitride, an insulating nitride oxide, an insulating metal oxide, an insulating metal oxynitride, and an insulating metal nitride oxide.

For example, when a material having a low dielectric constant is used for the insulator functioning as an interlayer film, parasitic capacitance generated between wirings can be reduced. Thus, a material is preferably selected depending on the function of an insulator.

For example, as the insulator 150, the insulator 210, the insulator 352, the insulator 354, and the like, an insulator having a low dielectric constant is preferably included. For example, the insulator preferably includes silicon oxide to which fluorine is added, silicon oxide to which carbon is added, silicon oxide to which carbon and nitrogen are added, porous silicon oxide, a resin, or the like. Alternatively, the insulator preferably has a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with a resin, the stacked-layer structure can have thermal stability and a low dielectric constant. Examples of the resin include polyester, polyolefin, polyamide (e.g., nylon and aramid), polyimide, polycarbonate, and acrylic. Note that these resins may be used for the insulator 160 and the insulator 164.

When a transistor using an oxide semiconductor is surrounded by an insulator having a function of inhibiting passage of oxygen and impurities such as hydrogen, the electrical characteristics of the transistor can be stable. Thus, the insulator having a function of inhibiting passage of oxygen and impurities such as hydrogen can be used for the insulator 350, the insulator 212, the insulator 214, the insulator 282, the insulator 283, the insulator 288, the insulator 286, and the like.

As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

As the conductor that can be used for a wiring or a plug, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Alternatively, a semiconductor having high electrical conductivity, typified by polycrystalline silicon containing an impurity element such as phosphorus, or silicide such as nickel silicide may be used.

For example, for the conductor 328, the conductor 330, the conductor 356, the conductor 218, the conductor 112, the conductor 110, the conductor 120, the conductor 158, and the like, a single layer or a stacked layer of a conductive material such as a metal material, an alloy material, a metal nitride material, or a metal oxide material that is formed using the above materials can be used. It is preferable to use a high-melting-point material that has both heat resistance and conductivity, such as tungsten or molybdenum, and it is preferable to use tungsten. Alternatively, it is preferable to use a low-resistance conductive material such as aluminum or copper. The use of a low-resistance conductive material can reduce wiring resistance. The conductor 162 and the conductor 166 are preferably formed using a low-resistance conductive material.

### <Wiring or Plug in Layer Including Oxide Semiconductor>

In the case where an oxide semiconductor is used in the transistor 200, an insulator including an excess-oxygen region is provided in the vicinity of the oxide semiconductor in some cases. In that case, an insulator having a barrier property is preferably provided between the insulator including the excess-oxygen region and a conductor provided in the insulator including the excess-oxygen region.

For example, in FIG. 17, the insulator 241 is preferably provided between the conductor 240, and the insulator 224 and the insulator 280 that contain excess oxygen. Since the insulator 241 is provided in contact with the insulator 222, the insulator 282, and the insulator 283, the insulator 224 and the transistor 200 can be sealed by the insulators having a barrier property.

That is, the insulator 241 can inhibit excess oxygen contained in the insulator 224 and the insulator 280 from being absorbed by the conductor 240. In addition, providing the insulator 241 can inhibit diffusion of hydrogen, which is an impurity, into the transistor 200 through the conductor 240.

The insulator 241 is preferably formed using an insulating material having a function of inhibiting diffusion of oxygen and impurities such as water or hydrogen. For example, silicon nitride, silicon nitride oxide, aluminum oxide, hafnium oxide, or the like is preferably used. In particular, silicon nitride is preferable because of its high blocking property against hydrogen. Other than that, a metal oxide such as magnesium oxide, gallium oxide, germanium oxide, yttrium oxide, zirconium oxide, lanthanum oxide, neodymium oxide, or tantalum oxide can be used, for example.

As described in the above embodiment, the transistor 200 may be sealed by the insulator 212, the insulator 214, the insulator 282, the insulator 283, the insulator 288, and the insulator 286. Such a structure can inhibit entry of hydrogen contained in the insulator 274, the insulator 150, or the like into the insulator 280 or the like.

Here, the conductor 240 penetrates the insulator 283 and the insulator 282, and the conductor 218 penetrates the insulator 214 and the insulator 212; however, as described above, the insulator 241 is provided in contact with the conductor 240, and the insulator 217 is provided in contact with the conductor 218. This can reduce the amount of hydrogen entering the inside of the insulator 212, the insulator 214, the insulator 282, and the insulator 283 through the conductor 240 and the conductor 218. In this manner, the transistor 200 is sealed by the insulator 212, the insulator 214, the insulator 282, the insulator 283, the insulator 241, and the insulator 217, so that impurities such as hydrogen contained in the insulator 274 or the like can be inhibited from entering from the outside.

### <Dicing Line>

A dicing line (sometimes referred to as a scribe line, a dividing line, or a cutting line) which is provided when a large-sized substrate is divided into semiconductor elements so that a plurality of semiconductor devices are each taken as a chip is described below. Examples of a dividing method include the case where a groove (a dicing line) for dividing the semiconductor elements is formed on the substrate, and then the substrate is cut along the dicing line to divide (split) it into a plurality of semiconductor devices.

Here, for example, as illustrated in FIG. 17, a region in which the insulator 283 and the insulator 214 are in contact with each other is preferably designed to overlap with the dicing line. That is, an opening is provided in the insulator 282, the insulator 280, the insulator 275, the insulator 222, and the insulator 216 in the vicinity of a region to be the dicing line that is provided on an outer edge of the memory cell including the plurality of transistors 200.

That is, in the opening provided in the insulator 282, the insulator 280, the insulator 275, the insulator 222, and the insulator 216, the insulator 214 is in contact with the insulator 283.

For example, an opening may be provided in the insulator 282, the insulator 280, the insulator 275, the insulator 222, the insulator 216, and the insulator 214. With such a structure, in the opening provided in the insulator 282, the insulator 280, the insulator 275, the insulator 224, the insulator 222, the insulator 216, and the insulator 214, the insulator 212 is in contact with the insulator 283. Here, the insulator 212 and the insulator 283 may be formed using the same material and the same method. When the insulator 212 and the insulator 283 are formed using the same material and the same method, the adhesion therebetween can be increased. For example, silicon nitride is preferably used.

With the structure, the transistors 200 can be surrounded by the insulator 212, the insulator 214, the insulator 282, and the insulator 283. Since at least one of the insulator 212, the insulator 214, the insulator 282, and the insulator 283 has a function of inhibiting diffusion of oxygen, hydrogen, and water, even when the substrate is divided into circuit regions each of which is provided with the semiconductor elements described in this embodiment to be processed into a plurality of chips, entry and diffusion of impurities such as hydrogen and water from the direction of the side surface of the divided substrate into the transistor 200 can be prevented.

With the structure, excess oxygen in the insulator 280 and the insulator 224 can be prevented from diffusing to the outside. Accordingly, excess oxygen in the insulator 280 and the insulator 224 is efficiently supplied to the oxide where the channel is formed in the transistor 200. The oxygen can reduce oxygen vacancies in the oxide where the channel is formed in the transistor 200. Thus, the oxide where the channel is formed in the transistor 200 can be an oxide semiconductor with a low density of defect states and stable characteristics. That is, the transistor 200 can have a small variation in the electrical characteristics and higher reliability.

Although an example in which the transistor 200 is sealed by the insulator 283 and the insulator 214 or the insulator 212 and a dicing line is formed in a region where the insulators are in contact with each other, the present invention is not limited thereto. For example, the transistor 200 may be sealed by the insulator 286 and the insulator 214 or the insulator 212, and a dicing line may be formed in a region where the insulators are in contact with each other.

### Embodiment 4

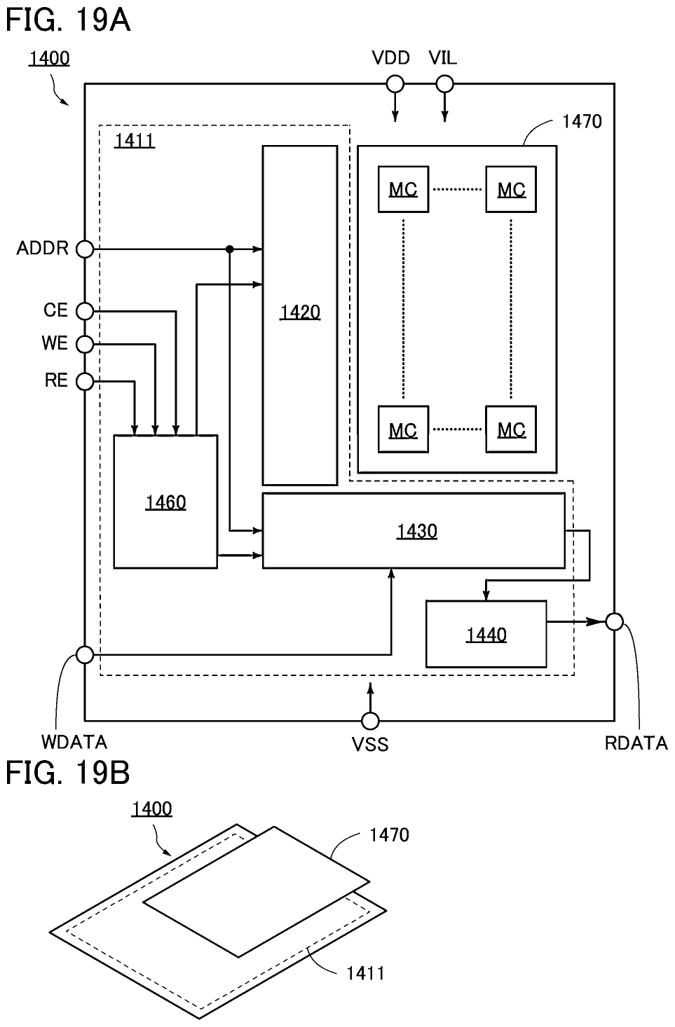

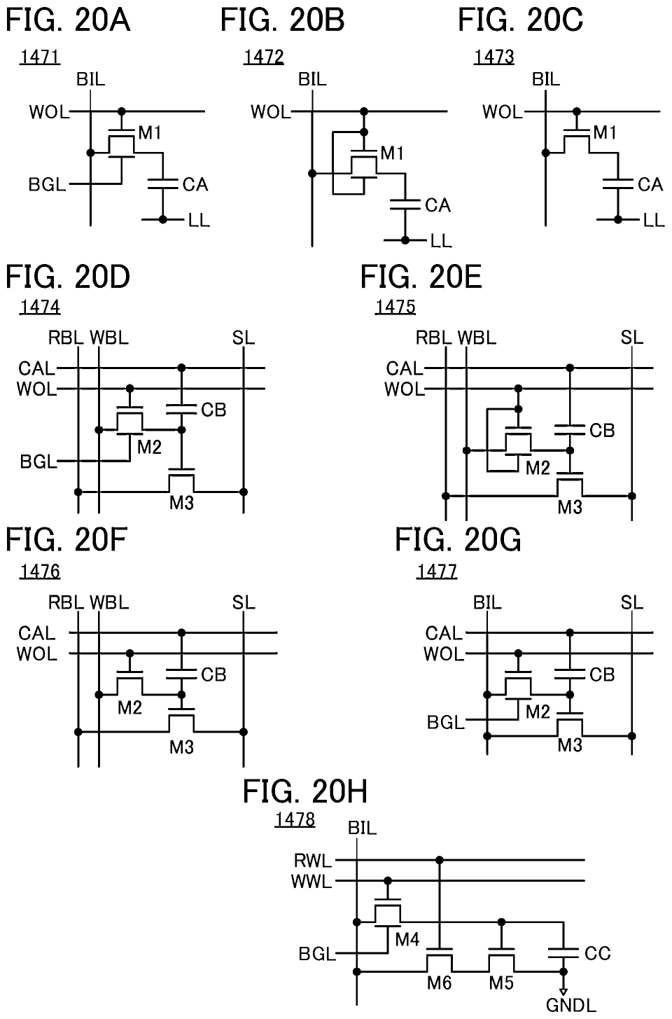

In this embodiment, a storage device of one embodiment of the present invention including a transistor in which an oxide is used as a semiconductor (hereinafter referred to as an OS transistor in some cases) and a capacitor (hereinafter referred to as an OS memory device in some cases), is described with reference to FIG. 19A, FIG. 19B, and FIG. 20A to FIG. 20H. The OS memory device is a storage device that includes at least a capacitor and an OS transistor that controls the charging and discharging of the capacitor. Since the OS transistor has an extremely low off-state current, the OS memory device has excellent retention characteristics and thus can function as a nonvolatile memory.

### <Structure Example of Storage Device>

FIG. 19A illustrates a structure example of the OS memory device. A storage device 1400 includes a peripheral circuit 1411 and a memory cell array 1470. The peripheral circuit 1411 includes a row circuit 1420, a column circuit 1430, an output circuit 1440, and a control logic circuit 1460.

The column circuit 1430 includes, for example, a column decoder, a precharge circuit, a sense amplifier, a write circuit, and the like. The precharge circuit has a function of precharging wirings. The sense amplifier has a function of amplifying a data signal read from a memory cell. Note that the wirings are connected to the memory cell included in the memory cell array 1470, and are described later in detail. The amplified data signal is output as a data signal RDATA to the outside of the storage device 1400 through the output circuit 1440. The row circuit 1420 includes, for example, a row decoder and a word line driver circuit, and can select a row to be accessed.

As power supply voltages from the outside, a low power supply voltage (VSS), a high power supply voltage (VDD) for the peripheral circuit 1411, and a high power supply voltage (VIL) for the memory cell array 1470 are supplied to the storage device 1400. Control signals (CE, WE, and RE), an address signal ADDR, and a data signal WDATA are also input to the storage device 1400 from the outside. The address signal ADDR is input to the row decoder and the column decoder, and the data signal WDATA is input to the write circuit.

The control logic circuit 1460 processes the control signals (CE, WE, and RE) input from the outside, and generates control signals for the row decoder and the column decoder. The control signal CE is a chip enable signal, the control signal WE is a write enable signal, and the control signal RE is a read enable signal. Signals processed by the control logic circuit 1460 are not limited thereto, and other control signals are input as necessary.

The memory cell array 1470 includes a plurality of memory cells MC arranged in a matrix and a plurality of wirings. Note that the number of wirings that connect the memory cell array 1470 to the row circuit 1420 depends on the structure of the memory cell MC, the number of memory cells MC in a column, and the like. The number of wirings that connect the memory cell array 1470 to the column circuit 1430 depends on the structure of the memory cell MC, the number of memory cells MC in a row, and the like.

Note that FIG. 19A illustrates an example in which the peripheral circuit 1411 and the memory cell array 1470 are formed on the same plane; however, this embodiment is not limited thereto. For example, as illustrated in FIG. 19B, the memory cell array 1470 may be provided to overlap with part of the peripheral circuit 1411. For example, the sense amplifier may be provided below the memory cell array 1470 so that they overlap with each other.

FIG. 20A to FIG. 20H show structure examples of a memory cell applicable to the memory cell MC.

### [DOSRAM]

FIG. 20A to FIG. 20C illustrate circuit structure examples of a memory cell of a DRAM. In this specification and the like, a DRAM using a memory cell including one OS transistor and one capacitor is referred to as a DOSRAM (Dynamic Oxide Semiconductor Random Access Memory) in some cases. A memory cell 1471 illustrated in FIG. 20A includes a transistor M1 and a capacitor CA. Note that the transistor M1 includes a gate (sometimes referred to as a top gate) and a back gate.

A first terminal of the transistor M1 is connected to a first terminal of the capacitor CA. A second terminal of the transistor M1 is connected to a wiring BIL. Agate of the transistor M1 is connected to a wiring WOL. A back gate of the transistor M1 is connected to a wiring BGL. A second terminal of the capacitor CA is connected to a wiring LL.

The wiring BIL functions as a bit line, and the wiring WOL functions as a word line. The wiring LL functions as a wiring for applying a predetermined potential to the second terminal of the capacitor CA. In the time of data writing and data reading, a low-level potential is preferably applied to the wiring LL. The wiring BGL functions as a wiring for applying a potential to the back gate of the transistor M1. When a given potential is applied to the wiring BGL, the threshold voltage of the transistor M1 can be increased or decreased.

The memory cell 1471 in FIG. 20A corresponds to the structure in which the conductor 110 is not electrically connected to the gate of the transistor 300 in the memory device in FIG. 17. That is, the transistor M1 and the capacitor CA correspond to the transistor 200 and the capacitor 100, respectively.

The circuit structure of the memory cell MC is not limited to that of the memory cell 1471, and can be changed. For example, in the memory cell MC, the back gate of the transistor M1 may be connected to the wiring WOL instead of the wiring BGL as in a memory cell 1472 illustrated in FIG. 20B. As another example, the memory cell MC may be configured with a single-gate transistor, that is, the transistor M1 that does not have a back gate, like a memory cell 1473 illustrated in FIG. 20C.

In the case where the semiconductor device described in any of the above embodiments is used in the memory cell 1471 and the like, the transistor 200 can be used as the transistor M1, and the capacitor 100 can be used as the capacitor CA. When an OS transistor is used as the transistor M1, the leakage current of the transistor M1 can be extremely low. That is, with use of the transistor M1, written data can be retained for a long time, and thus the frequency of the refresh operation for the memory cell can be decreased. Alternatively, refresh operation for the memory cell can be unnecessary. In addition, since the transistor M1 has an extremely low leakage current, multi-level data or analog data can be retained in the memory cell 1471, the memory cell 1472, and the memory cell 1473.

In the DOSRAM, when the sense amplifier is provided below the memory cell array 1470 so that they overlap with each other as described above, the bit line can be shortened. This reduces bit line capacitance, which can reduce the storage capacitance of the memory cell.

### [NOSRAM]

FIG. 20D to FIG. 20G each illustrate a circuit structure example of a gain-cell memory cell including two transistors and one capacitor. A memory cell 1474 illustrated in FIG. 20D includes a transistor M2, a transistor M3, and a capacitor CB. Note that the transistor M2 includes a top gate (simply referred to as a gate in some cases) and a back gate. In this specification and the like, a storage device including a gain-cell memory cell using an OS transistor as the transistor M2 is referred to as a NOSRAM (Nonvolatile Oxide Semiconductor RAM) in some cases.

A first terminal of the transistor M2 is connected to a first terminal of the capacitor CB. A second terminal of the transistor M2 is connected to a wiring WBL. The gate of the transistor M2 is connected to the wiring WOL. The back gate of the transistor M2 is connected to the wiring BGL. A second terminal of the capacitor CB is connected to the wiring CAL. A first terminal of the transistor M3 is connected to a wiring RBL, and a second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. During data writing, data retention, and data reading, a high-level potential is preferably applied to the wiring CAL. In the time of data retaining, a low-level potential is preferably applied to the wiring CAL. The wiring BGL functions as a wiring for applying a potential to the back gate of the transistor M2. The threshold voltage of the transistor M2 can be increased or decreased by applying a given potential to the wiring BGL.

Here, the memory cell 1474 illustrated in FIG. 20D corresponds to the storage device illustrated in FIG. 17. That is, the transistor M2, the capacitor CB, the transistor M3, the wiring WBL, the wiring WOL, the wiring BGL, the wiring CAL, the wiring RBL, and the wiring SL correspond to the transistor 200, the capacitor 100, the transistor 300, the wiring 1003, the wiring 1004, the wiring 1006, the wiring 1005, the wiring 1002, and the wiring 1001, respectively.

The circuit structure of the memory cell MC is not limited to that of the memory cell 1474, and can be changed as appropriate. For example, in the memory cell MC, the back gate of the transistor M2 may be connected to the wiring WOL instead of the wiring BGL as in a memory cell 1475 illustrated in FIG. 20E. As another example, the memory cell MC may be configured with a single-gate transistor, that is, the transistor M2 that does not have a back gate, like a memory cell 1476 illustrated in FIG. 20F. As another example, the memory cell MC may have a structure in which the wiring WBL and the wiring RBL are combined into one wiring BIL as in a memory cell 1477 illustrated in FIG. 20G.

In the case where the semiconductor device described in any of the above embodiments is used in the memory cell 1474 and the like, the transistor 200 can be used as the transistor M2, the transistor 300 can be used as the transistor M3, and the capacitor 100 can be used as the capacitor CB. When an OS transistor is used as the transistor M2, the leakage current of the transistor M2 can be extremely low. Consequently, with use of the transistor M2, written data can be retained for a long time, and thus the frequency of the refresh operation for the memory cell can be decreased. Alternatively, refresh operation for the memory cell can be unnecessary. In addition, since the transistor M2 has an extremely low leakage current, multi-level data or analog data can be retained in the memory cell 1474. The same applies to the memory cell 1475 to the memory cell 1477.

Note that the transistor M3 may be a transistor containing silicon in a channel formation region (hereinafter, sometimes referred to as a Si transistor). The Si transistor may be either an n-channel transistor or a p-channel transistor. A Si transistor has higher field-effect mobility than an OS transistor in some cases. Therefore, a Si transistor may be used as the transistor M3 functioning as a reading transistor. Furthermore, the transistor M2 can be stacked over the transistor M3 when a Si transistor is used as the transistor M3, in which case the area occupied by the memory cell can be reduced, leading to high integration of the storage device.

Alternatively, the transistor M3 may be an OS transistor. When an OS transistor is used as each of the transistor M2 and the transistor M3, the circuit of the memory cell array 1470 can be formed using only n-channel transistors.

FIG. 20H illustrates an example of a gain-cell memory cell including three transistors and one capacitor. A memory cell 1478 illustrated in FIG. 20H includes a transistor M4 to a transistor M6 and a capacitor CC. The capacitor CC is provided as appropriate. The memory cell 1478 is electrically connected to the wiring BIL, a wiring RWL, a wiring WWL, the wiring BGL, and a wiring GNDL. The wiring GNDL is a wiring for supplying a low-level potential. Note that the memory cell 1478 may be electrically connected to the wiring RBL and the wiring WBL instead of the wiring BIL.

The transistor M4 is an OS transistor with a back gate, and the back gate is electrically connected to the wiring BGL. Note that the back gate and the gate of the transistor M4 may be electrically connected to each other. Alternatively, the transistor M4 does not necessarily include the back gate.

Note that each of the transistor M5 and the transistor M6 may be an n-channel Si transistor or a p-channel Si transistor. Alternatively, the transistor M4 to the transistor M6 may be OS transistors. In that case, the circuit of the memory cell array 1470 can be formed using only n-channel transistors.

In the case where the semiconductor device described in any of the above embodiments is used in the memory cell 1478, the transistor 200 can be used as the transistor M4, the transistors 300 can be used as the transistor M5 and the transistor M6, and the capacitor 100 can be used as the capacitor CC. When an OS transistor is used as the transistor M4, the leakage current of the transistor M4 can be extremely low.

Note that the structures of the peripheral circuit 1411, the memory cell array 1470, and the like described in this embodiment are not limited to the above. The arrangement and functions of these circuits and the wirings, circuit components, and the like connected to the circuits can be changed, removed, or added as needed. The storage device of one embodiment of the present invention operates fast and can retain data for a long time.

The structure, method, and the like described in this embodiment can be used in an appropriate combination with any of other structures, methods, and the like described in this embodiment or the other embodiments.

### Embodiment 5

In this embodiment, an example of a semiconductor device including a transistor of one embodiment of the present invention will be described with reference to drawings.

### <Structure Example of Semiconductor Device>

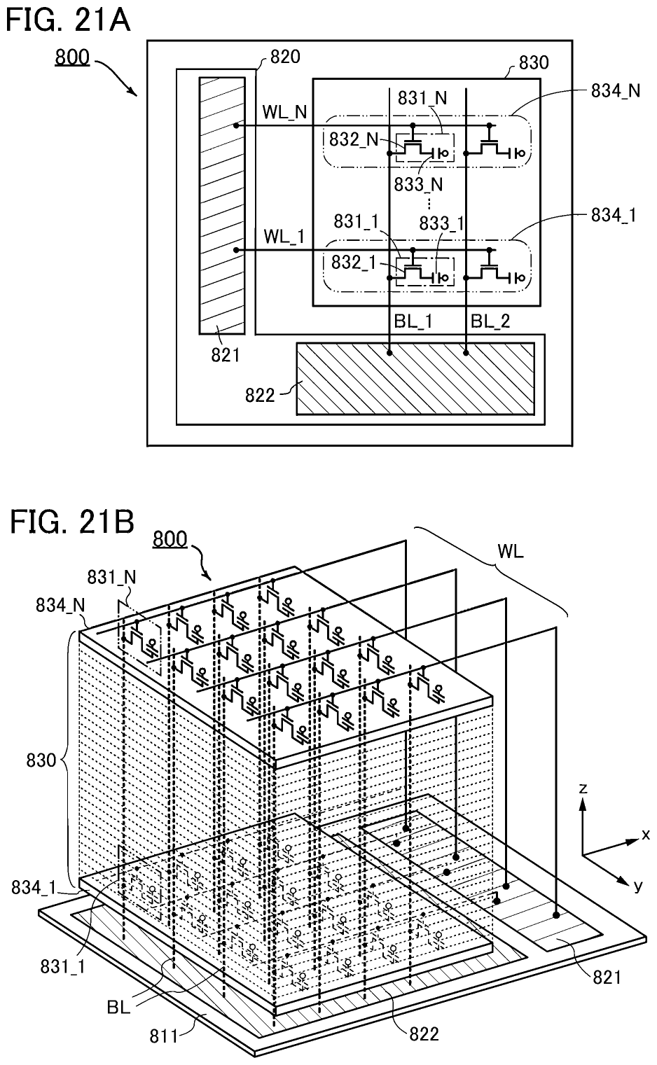

FIG. 21A is a block diagram of a semiconductor device 800 including a transistor of one embodiment of the present invention. FIG. 21B is a perspective schematic view of the semiconductor device 800. The semiconductor device 800 includes a peripheral circuit 820 and a memory cell array 830. The semiconductor device 800 can function as a storage device.

The peripheral circuit 820 includes a row driver 821 and a column driver 822. The row driver 821 and the column driver 822 are simply referred to as driver circuits or drivers in some cases.

The row driver 821 is a circuit having a function of outputting signals for driving the memory cell array 830 to word lines WL. Specifically, the row driver 821 has a function of transmitting word signals to the word lines WL (WL_1 to WL_N are illustrated in FIG. 21A and Nis a natural number greater than or equal to 2). The row driver 821 is sometimes referred to as a word line driver circuit. Note that the row driver 821 includes a decoder circuit for selecting a word line WL in accordance with the designated address, a buffer circuit, and the like. Note that the word lines WL are simply referred to as wirings in some cases.

The column driver 822 is a circuit having a function of outputting signals for driving the memory cell array 830 to bit lines BL. Specifically, the column driver 822 has a function of transmitting data signals to the bit lines BL (BL_1 and BL_2 are illustrated in FIG. 21A). The column driver 822 is sometimes referred to as a bit line driver circuit. Note that the column driver 822 includes a sense amplifier, a precharge circuit, a decoder circuit for selecting a bit line in accordance with the designated address, and the like. Note that the bit lines BL are simply referred to as wirings in some cases. In some drawings, the bit lines BL are denoted by thick lines, thick dotted lines, or the like for enhanced visibility.

The data signal supplied to the bit line BL corresponds to a signal written to a memory cell or a signal read out from the memory cell. The data signal is described as a binary signal having a high-level or low-level potential corresponding to data 1 or data 0. Note that the data signal may be a multilevel signal higher than or equal to a ternary signal. The high-level potential is VDD, and the low-level potential is VSS or a ground potential (GND). A signal supplied to the bit line BL can be, other than the data signal, a precharge potential for reading data, for example. The precharge potential can be VDD/2, for example.

The memory cell array 830 includes, for example, N (N is a natural number greater than or equal to 2) element layers 834_1 to 834_N. The element layer 834_1 includes one or more memory cells 831_1. The memory cell 831_1 includes a transistor 832_1 and a capacitor 833_1. The element layer 834_N includes one or more memory cells 831_N. The memory cell 831_N includes a transistor 832_N and a capacitor 833_N. Note that the element layer is a layer provided with elements such as a capacitor and a transistor and is formed using members such as a conductor, a semiconductor, and an insulator.

The transistor 832_1 to the transistor 832_N function as switches whose on/off is controlled in accordance with the word signals supplied to the word line WL_1 to the word line WL_N. One of a source and a drain of each of the transistor 8321 to the transistor 832_N is connected to any one of the bit lines BL (BL_1 in the drawing).

An OS transistor of one embodiment of the present invention is preferably used as each of the transistors 832 (the transistor 832_1 to the transistor 832_N). The off-state current of an OS transistor is extremely low. The use of an OS transistor as the transistor 832 enables charge corresponding to a predetermined voltage to be retained in the capacitors 833 (the capacitor 833_1 to the capacitor 833_N) at the other of the source and the drain. In other words, data once written to the memory cells 831 (the memory cell 831_1 to the memory cell 831_N) can be retained for a long time. Therefore, the frequency of data refresh operation can be reduced and low power consumption can be achieved.

In addition, the memory cell 831 using an OS transistor can rewrite and read data by charging or discharging of electric charge; thus, a substantially unlimited number of times of data writing and data reading are possible. Unlike a magnetic memory, a resistive random-access memory, or the like, the memory cell 831 using an OS transistor does not go through atomic-level structure change; thus, it is superior in rewrite endurance. Furthermore, unlike a flash memory, the memory cell 831 using an OS transistor does not show instability due to an increase of electron trap centers even when a rewriting operation is repeated.

The memory cell 831 using an OS transistor can be freely provided, for example, over a silicon substrate including a transistor including silicon in a channel formation region (hereinafter, a Si transistor), so that integration can be easily performed. Furthermore, an OS transistor can be manufactured with a manufacturing apparatus similar to that for a Si transistor and thus can be manufactured at low cost.

An OS transistor can be a four-terminal semiconductor element including a back gate electrode in addition to a gate electrode, a source electrode, and a drain electrode. An electric network where input and output of signals flowing between a source and a drain can be independently controlled in accordance with a voltage applied to a gate electrode or a back gate electrode can be constituted. Thus, circuit design with the same ideas as those of an LSI is possible. Furthermore, electrical characteristics of the OS transistor are better than those of a Si transistor in a high-temperature environment. Specifically, the ratio between an on-state current and an off-state current is large even at a high temperature higher than or equal to 125° C. and lower than or equal to 150° C.; thus, favorable switching operation can be performed.

Note that the memory cells illustrated in FIG. 21A can each be referred to as a DOSRAM (Dynamic Oxide Semiconductor Random Access Memory) that uses an OS transistor as a memory. A DOSRAM can be formed using one transistor and one capacitor, so that high density of a memory can be achieved. In addition, with the use of an OS transistor, a data retention period can be extended.

The capacitor 833 has a structure in which an insulator is sandwiched between conductors serving as electrodes. As the conductors forming the electrodes, a semiconductor layer or the like to which conductivity is imparted as well as metal can be used. In addition to the structure in which the capacitor 833 is placed in a position overlapping with the upper side or lower side of the transistor 832, part of the semiconductor layer, electrode, or the like included in the transistor 832 can be used as one electrode of the capacitor 833.

Out of the components described with reference to FIG. 21A, the element layer 834_1 to the element layer 834_N in one embodiment of the present invention are described with reference to a schematic diagram illustrated in FIG. 21B. In FIG. 21B, arrows indicating the X-axis direction, the Y-axis direction, and the Z-axis direction are denoted for easy understanding of the position of each component described in FIG. 21A. Note that in this specification and the like, the x-axis direction, the y-axis direction, and the z-axis direction are referred to as a depth direction, a horizontal direction, and a perpendicular direction, respectively, in some cases.

As illustrated in FIG. 21B, the memory cell array 830 has a structure in which N element layers 834 are stacked. Each of the memory cell 831_1 to the memory cell 831_N included in the element layer 834_1 to the element layer 834_N has a region overlapping with the column driver 822 provided on a silicon substrate 811. In other words, the element layer 834_1 is provided between the silicon substrate 811 and the element layer 834_N.

The transistor of the memory cell 831_1 included in the element layer 834_1 and the transistor of the memory cell 831_N included in the element layer 834_N are connected to each other through the bit line BL provided in the perpendicular direction. The bit line BL is connected to the column driver 822 provided on the silicon substrate 811.

The bit line BL_1 is electrically connected to a semiconductor layer of the transistor 832_1 included in the memory cell 831_1 and a semiconductor layer of the transistor 832_N included in the memory cell 831_N. Alternatively, the bit line BL_1 is provided to be electrically connected to a region functioning as a source or a drain of the transistor 832_1 included in the memory cell 831_1 and a region functioning as a source or a drain of the transistor 832_N included in the memory cell 831_N. Alternatively, the bit line BL_1 is provided in contact with a conductor provided in contact with the region functioning as the source or the drain of the semiconductor layer of the transistor 832_1 included in the memory cell 831_1 and a conductor provided in contact with the region functioning as the source or the drain of the semiconductor layer of the transistor 832_N included in the memory cell 831_N. In other words, the bit line BL is a wiring for electrically connecting one of the source and the drain of the transistor included in the memory cell 831_1, one of the source and the drain of the transistor included in the memory cell 831_N, and the column driver 822 in the perpendicular direction.

It can be said that the bit line BL is provided to extend in a direction (z-axis direction) perpendicular or substantially perpendicular to a plane of the silicon substrate 811 where the column driver 822 is provided. That is, as illustrated in FIG. 21B, the bit line BL is connected to the transistor included in the memory cell 831_1 and the transistor included in the memory cell 831_N and provided in a direction (z-axis direction) perpendicular or substantially perpendicular’ to a surface of the silicon substrate (xy plane). Note that “substantially perpendicular” refers to a state where an arrangement angle is greater than or equal to 85° and less than or equal to 95°.

It is preferable to employ a structure in which the row driver 821 provided on the silicon substrate 811 and the word lines WL provided to extend in the depth direction (x-axis direction) of the element layer 834_1 to the element layer 834_N are connected to each other through an opening portion in a region where the memory cell 831_1 to the memory cell 831_N are not provided in the element layer 834_1 to the element layer 834_N, e.g., a circumference portion of the element layer 834_1 to the element layer 834_N. The row driver 821 provided on the silicon substrate 811 and the word lines WL provided for the element layers may be connected to each other through a wiring provided in a layer above the element layer 8341 to the element layer 834_N.

One embodiment of the present invention uses an OS transistor with extremely low off-state current as a transistor provided in each element layer. Accordingly, the frequency of refresh of data retained in the memory cell can be reduced, and a semiconductor device with reduced power consumption can be obtained. OS transistors can be stacked and provided and can be manufactured in the perpendicular direction by employing the same manufacturing process repeatedly, which can reduce manufacturing cost. Furthermore, in one embodiment of the present invention, the memory density can be increased by stacking the transistors included in the memory cell in not a plane direction but the perpendicular direction, so that the semiconductor device can be downsized. Moreover, since an OS transistor has a smaller variation in electrical characteristics than a Si transistor even in a high-temperature environment, the semiconductor device can function as a highly reliable storage device in which stacked and integrated transistors have a small variation in electrical characteristics. Furthermore, in one embodiment of the present invention, the length of the bit lines between the memory cell array and the column driver can be reduced by provision of the bit lines extending from the memory cell array in the perpendicular direction. Thus, parasitic capacitance of the bit lines can be significantly reduced and a potential can be read even when the data signals retained in the memory cells are multi-level signals.

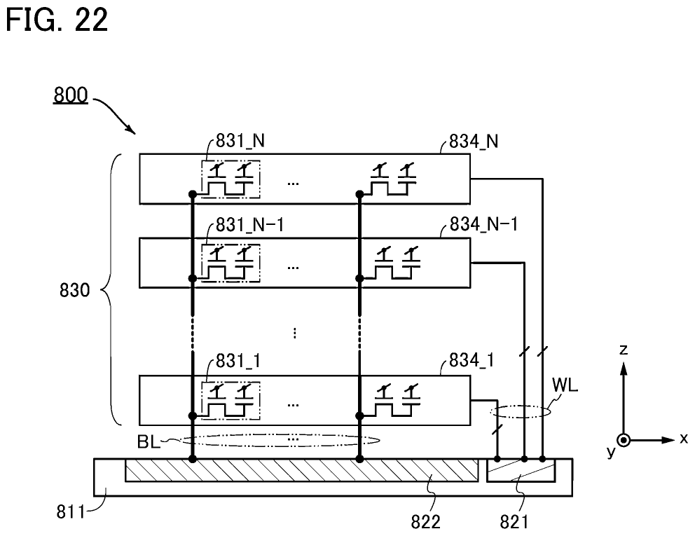

FIG. 22 illustrates a schematic cross-sectional view of the semiconductor device 800 in the xz plane. As illustrated in FIG. 22, the semiconductor device 800 can have a structure where the memory cell 831_1 to the memory cell 831_N provided in the respective element layers 834 and the column driver 822 provided on the silicon substrate 811 are connected to each other with the shortest distance therebetween through the bit line BL provided in the perpendicular direction. The number of memory cells 831 connected to one bit line can be reduced as compared with a structure where the bit lines BL are provided in the plane direction (the x-axis direction and/or the y-axis direction), so that the parasitic capacitance of the bit lines BL can be decreased. Therefore, in reading operation of data retained in the memory cell 831, a potential change of the bit line BL can be detected even when the capacitance of the capacitor 833 is small.

Since the capacitor 833 included in the memory cell 831 can be made small, the capacitor 833 can be provided in the same layer as the transistor 832. The structure in which the capacitor 833 is provided in the same layer as the transistor 832 can reduce the thickness of the element layer 834. As a result, the semiconductor device 800 can be downsized.

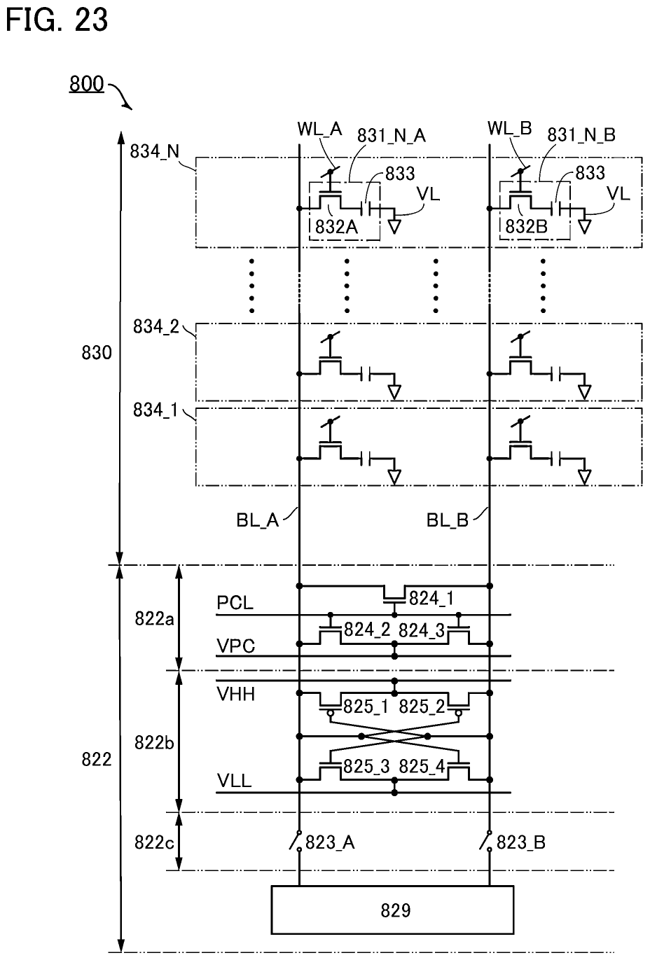

FIG. 23 illustrates a circuit structure example of the column driver 822 electrically connected to the memory cell array 830. FIG. 23 illustrates the element layer 834_1, the element layer 834_2, and the element layer 834_N as the memory cell array 830. In FIG. 23, a memory cell 831_N_A is illustrated as a memory cell of the element layer 834_N connected to a bit line BL_A. The memory cell 831_N_A includes the capacitor 833 and a transistor 832A whose gate is connected to a word line WL_A. In FIG. 23, a memory cell 831_N_B is illustrated as a memory cell of the element layer 834_N connected to a bit line BL_B. The memory cell 831_N_B includes the capacitor 833 and a transistor 832B whose gate is connected to a word line WL_B. The capacitor 833 in each element layer is connected to a wiring VL to which a fixed potential, e.g., a ground potential, is supplied.

FIG. 23 also illustrates a precharge circuit 822a, a sense amplifier 822b, a selection switch 822c, and a write read circuit 829 on the silicon substrate side, as circuits included in the column driver 822. The precharge circuit 822a and the sense amplifier 822b are formed using Si transistors. The selection switch 822c can also be formed using Si transistors.

The precharge circuit 822a is formed using n-channel transistors 824_1 to 824_3. The precharge circuit 822a is a circuit for precharging the bit line BL_A and the bit line BL_B with an intermediate potential VPC corresponding to a potential between VDD and VSS, depending on a precharge signal supplied to a precharge line PCL. The intermediate potential VPC can be expressed by, for example, VPC=(VDD−VSS)/2.

The sense amplifier 822b is formed using p-channel transistors 825_1 and 825_2 and n-channel transistors 825_3 and 8254, which are connected to a wiring VHH or a wiring VLL. The wiring VHH or the wiring VLL is a wiring having a function of supplying VDD or VSS. The transistor 825_1 to the transistor 825_4 are transistors that form an inverter loop. In memory cells 831_N_A and 831_N_B, when the word lines WL_A and WL_B are selected as high levels, potentials of the precharged bit line BL_A and the bit line BL_B are changed, and potentials of the bit line BL_A and the bit line BL_B are set to high supply potentials VDD or low supply potentials VSS in accordance with the change. The potentials of the bit line BL_A and the bit line BL_B can be output to the outside through the write read circuit 829. The bit line BL_A and the bit line BL_B correspond to a bit line pair.

The selection switch 822c includes a switch 823_A and a switch 823_B. The bit line BL_A is electrically connected to the write read circuit 829 through the switch 823_A. The bit line BL_B is electrically connected to the write read circuit 829 through the switch 823_B.

### <Operation Example of Semiconductor Device>

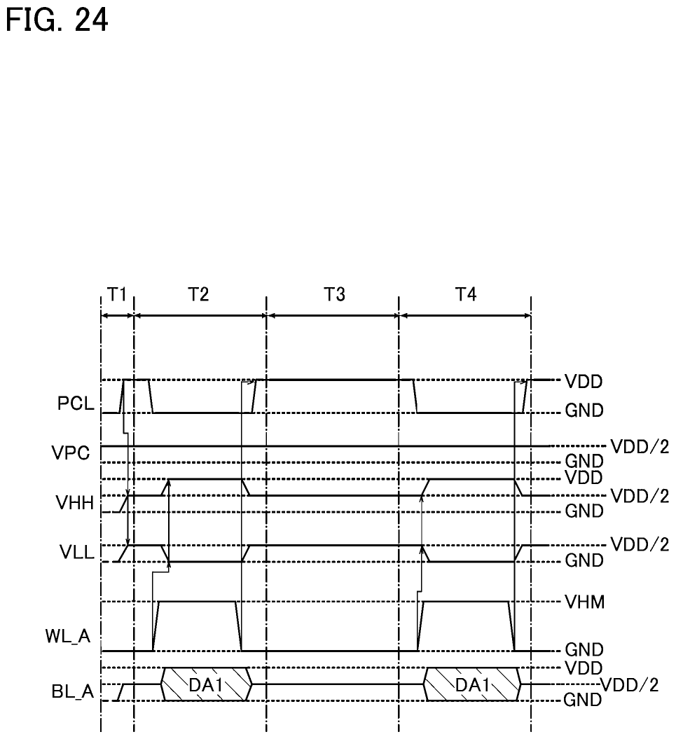

FIG. 24 is a timing chart for describing an operation of the circuit illustrated in FIG. 23. In FIG. 24, Period T1, Period T2, Period T3, and Period T4 correspond to periods for describing an initialization operation, a writing operation, an operation in a non-access state, and a reading operation, respectively. Note that in the description of FIG. 24, the description of the switches 823_A and 823_B included in the selection switch 822c is omitted. The switches 823_A and 823_B are selected as appropriate in the writing operation and the reading operation.

Arrows between waveforms in FIG. 24 are for easy understanding of the operation. For the wiring VPC, the wiring VHH, and the like, waveforms represented by dotted lines show that the potentials are uncertain. In the wiring PCL among signal lines, the high level (H level) is VDD. The high level in WL is VHM (>VDD) but may be VDD.

In Period T1, a potential of VDD/2 is supplied to the wiring VPC, the wiring VHH, and the wiring VLL. The bit line BL_A and the bit line BL_B are each precharged to VDD/2. Precharging of the bit line BL_A and the bit line BL_B is performed by the precharge circuit 822a. By setting the wiring PCL to the high level (H level), the bit line BL_A and the bit line BL_B are precharged and the potential between the bit lines is smoothed.

In Period T2, when access for writing is made, the bit line BL_A (or the bit line BL_B) is brought from the precharge state to a floating state by changing the level of the wiring PCL from the H level to the L level. The word line WL_A is (selected) set to the H level here. After WL_A is selected, VHH is set to VDD, and VLL is set to GND. When the transistor 832A is turned on, data DA1 is written from the write read circuit 829 to the memory cell 831_N_A through the bit line BL_A. After the word line WL_A is brought to the L level, a precharge operation of the bit line BL_A (or the bit line BL_B) starts and the lines are precharged to VDD/2.

In Period T3, the wiring PCL is at the H level and the word line WL_A is at the L level. VPC, VHH, and VLL have VDD/2. The bit line BL_A and the bit line BL_B are precharged to VDD/2. When VHH and VLL each have a potential of VDD/2, a leakage current from the sense amplifier 822b can be reduced.

In Period T4, when access for reading is made, the bit line BL_A (or the bit line BL_B) is brought from the precharge state to a floating state. Next, the word line WL_A is brought to the H level to turn on the transistor 832A. The data DA1 retained in the memory cell 831_N_A is written to the bit line BL_A. After the word line WL_A is brought to the H level, VHH is set to VDD and VLL is set to GND so that the sense amplifier 822b functions as a differential amplifier circuit. Then, the potential of the bit line BL_A is amplified to VDD or GND, which is a potential corresponding to the data DA1. The data DA1 in the bit line BL_A is read by the write read circuit 829.

### <Cross-Sectional Structure Example of Semiconductor Device>

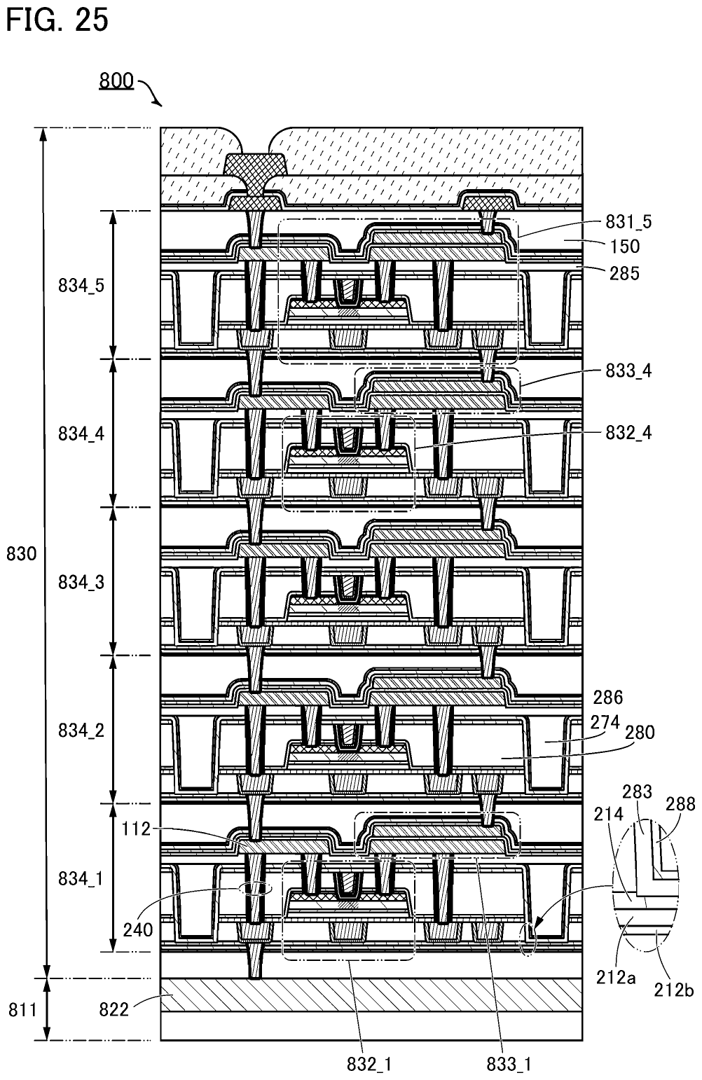

Next, a cross-sectional structure example of the semiconductor device 800 is described. In this embodiment, a cross-sectional structure example of the memory cell array 830 is mainly described. FIG. 25 illustrates a cross-sectional schematic view of part of the semiconductor device 800. Note that the semiconductor device 800 illustrated in FIG. 25 includes the memory cell array 830 including five element layers 834. As described above, the five element layers 834 each include the memory cells 831, and each of the memory cells 831 includes the transistor 832 and the capacitor 833.

The semiconductor device 800 illustrated in FIG. 25 corresponds to the stacked semiconductor device illustrated in FIG. 3. That is, the element layer 834_1 to the element layer 834_5 illustrated in FIG. 25 correspond to the element layer 10_1 to the element layer 10_n illustrated in FIG. 3, where n=5.

For example, the transistor 200 shown in the above embodiment can be used as the transistor 832. The capacitor 100 shown in the above embodiment can be used as the capacitor 833. One of a source and a drain of the transistor 832 included in each of the element layers 834 is electrically connected to one of the source and the drain of the transistor 832 included in another element layer 834 through a conductor such as the conductor 240 or the conductor 112 included in each of the element layers 834. At least part of the conductor 240 and the conductor 112 serves as the bit line BL.

The semiconductor device 800 illustrated in FIG. 25 has a structure in which the transistor 832 is sandwiched by the insulator 212a, the insulator 212b, the insulator 214, the insulator 283, and the insulator 288 in each of the five element layers 834. Furthermore, the insulator 286 is provided to cover the capacitor 833 and the conductor 112 over the transistor 832 in each of the five element layers 834.

As described in the above embodiment, the insulator 212 (the insulator 212a and the insulator 212b), the insulator 283, the insulator 288, and the insulator 286 are insulators having hydrogen barrier properties. In addition, the insulator 214 has a high-performance function of trapping and fixing hydrogen. The transistor is sandwiched (sealed) by the insulators having hydrogen barrier properties and the insulator having a high-performance function of trapping and fixing hydrogen is provided on the further inner side, so that the transistor operates stably to improve the reliability of the semiconductor device. Furthermore, when the insulator having a hydrogen barrier property is provided to cover the wiring and the capacitor electrically connected to the transistor, the amount of hydrogen diffusing into the transistor through the wiring and the capacitor can be reduced.

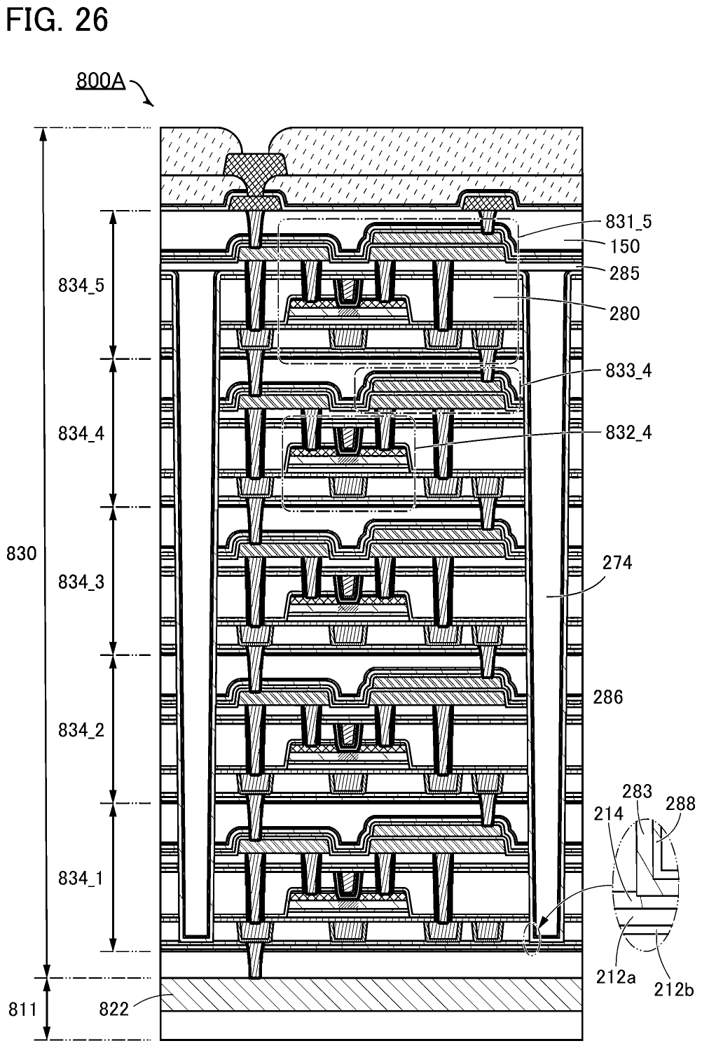

A semiconductor device 800A illustrated in FIG. 26 is a modification example of the semiconductor device 800. The semiconductor device 800 has a structure in which the transistor 832 is sealed by the insulator having a hydrogen barrier property in each of the element layers 834. Meanwhile, in the semiconductor device 800A, the sealing step of the transistor 832 is not performed in each of the element layers 834, but the sealing step of the transistors 832 in the first layer to the N-th layer is performed in the step of forming the N-th element layer 834.

The semiconductor device 800A illustrated in FIG. 26 corresponds to the stacked semiconductor device illustrated in FIG. 4. That is, the element layer 834_1 to the element layer 834_5 illustrated in FIG. 26 correspond to the element layer 10_1 to the element layer 10_n illustrated in FIG. 4, where n=5.

Specifically, when the N-th element layer 834 is formed, the insulators 280 and the like in the first layer to the N-th layer are partly removed to form an opening and part of the insulator 214 or part of the insulator 212 included in the first element layer 834 (the element layer 834_1) is exposed at the bottom of the opening. In a subsequent step, the insulator 283 and the insulator 288 are formed, and all the transistors 832 included in the N element layers 834 are collectively sealed.

The semiconductor device 800A can be manufactured in a smaller number of steps than the semiconductor device 800. This improves the productivity of the semiconductor device. In addition, the manufacturing cost of the semiconductor device can be reduced.

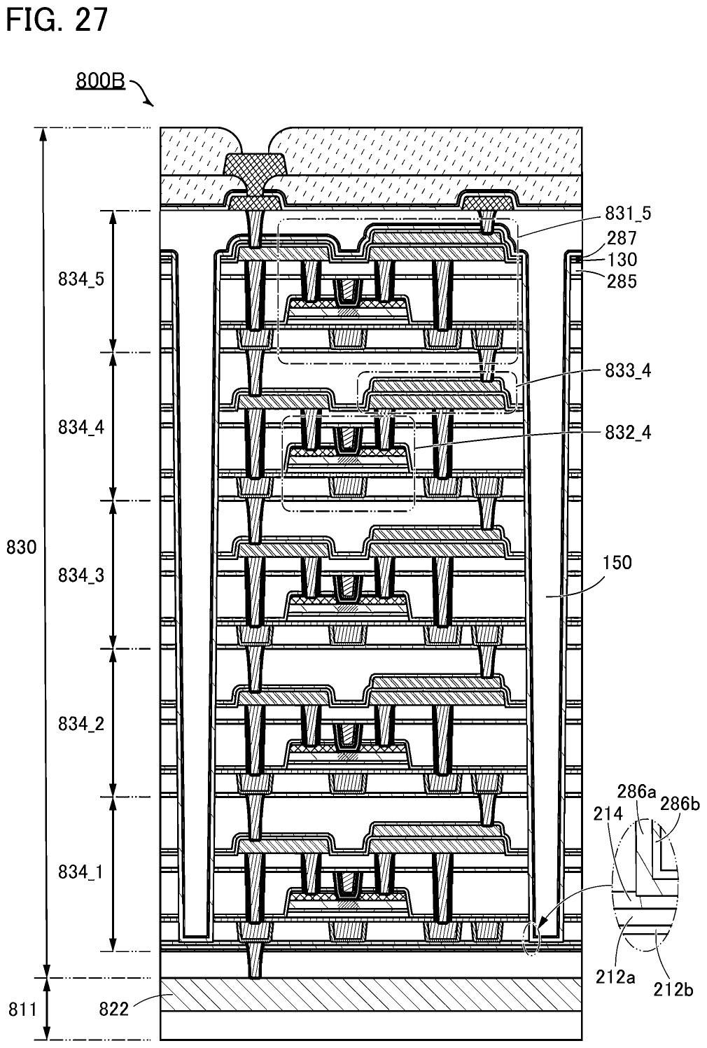

A semiconductor device 800B illustrated in FIG. 27 is a modification example of the semiconductor device 800A. As in the semiconductor device 800B illustrated in FIG. 27, the step of forming the opening for collectively sealing may be performed before the formation of the insulator 286a having a hydrogen barrier property in the fifth element layer 834 (the element layer 834_5).

The semiconductor device 800B illustrated in FIG. 27 corresponds to the stacked semiconductor device illustrated in FIG. 5. That is, the element layer 834_1 to the element layer 834_5 illustrated in FIG. 27 correspond to the element layer 10_1 to the element layer 10_n illustrated in FIG. 5, where n=5.

In the case where sealing is collectively performed as in the semiconductor device 800A and the semiconductor device 800B, the formation of the insulator having a hydrogen barrier property in sealing may be omitted. In the semiconductor device 800B, the formation of the insulator 283 in the element layer 834_2 to the element layer 834_5, the insulator 212 in the element layer 834_2 to the element layer 834_5, and the insulators 286 (the insulator 286a and the insulator 286b) in the element layer 834_1 to the element layer 834_4 is omitted.

The semiconductor device 800B can be manufactured in a smaller number of steps than the semiconductor device 800 and the semiconductor device 800A. This improves the productivity of the semiconductor device. In addition, the manufacturing cost of the semiconductor device can be reduced.

At least part of the structure, method, and the like described in this embodiment can be implemented in appropriate combination with any of those in the other embodiments and the like described in this specification.

### Embodiment 6

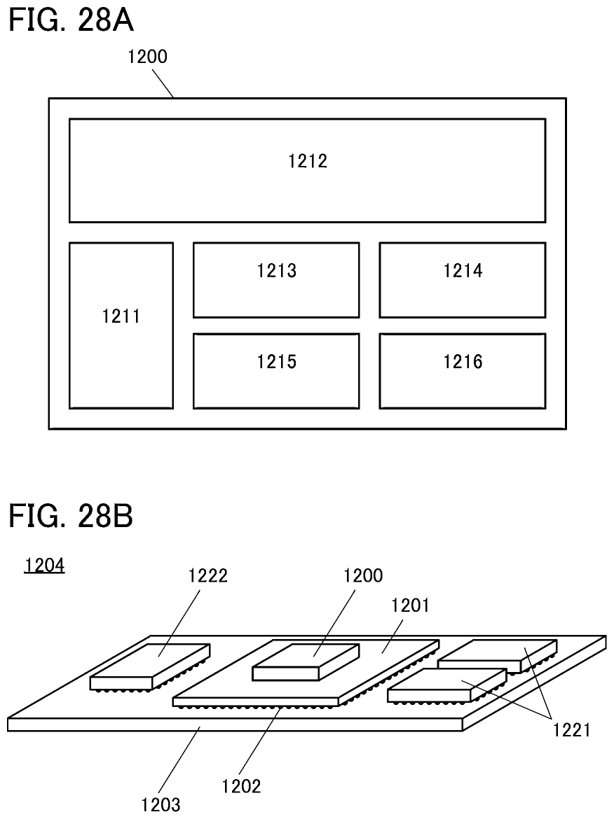

In this embodiment, an example of a chip 1200 on which the semiconductor device of the present invention is mounted will be described with reference to FIG. 28A and FIG. 28B. A plurality of circuits (systems) are mounted on the chip 1200. A technique for integrating a plurality of circuits (systems) into one chip is referred to as system on chip (SoC) in some cases.

As illustrated in FIG. 28A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 28B, the chip 1200 is connected to a first surface of a package board 1201. In addition, a plurality of bumps 1202 are provided on a rear side of the first surface of the package board 1201, and the package board 1201 is connected to a motherboard 1203.

Storage devices such as DRAMs 1221 and a flash memory 1222 may be provided over the motherboard 1203. For example, the DOSRAM described in the above embodiment can be used as the DRAM 1221. In addition, for example, the NOSRAM described in the above embodiment can be used as the flash memory 1222.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The NOSRAM or the DOSRAM described above can be used as the memory. Moreover, the GPU 1212 is suitable for parallel computation of a number of data and thus can be used for image processing or product-sum operation. When an image processing circuit and a product-sum operation circuit using an oxide semiconductor of the present invention are provided in the GPU 1212, image processing and product-sum operation can be performed with low power consumption.

In addition, since the CPU 1211 and the GPU 1212 are provided on the same chip, a wiring between the CPU 1211 and the GPU 1212 can be shortened, and the data transfer from the CPU 1211 to the GPU 1212, the data transfer between memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package board 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic device such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

At least part of the structure, method, and the like described in this embodiment can be implemented in appropriate combination with any of those in the other embodiments and the like described in this specification.

### Embodiment 7

Shown in this embodiment are examples of electronic components and electronic devices in which the storage device or the like described in the above embodiment is incorporated.

### <Electronic Component>

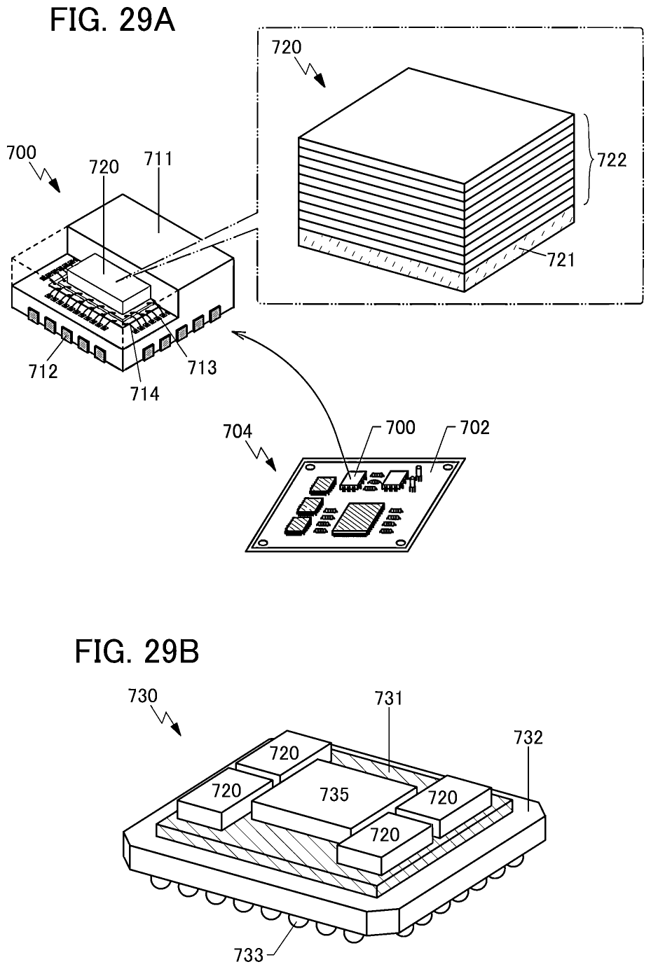

First, examples of an electronic component including a storage device 720 are described with reference to FIG. 29A and FIG. 29B.

FIG. 29A is a perspective view of an electronic component 700 and a substrate (circuit board 704) on which the electronic component 700 is mounted. The electronic component 700 in FIG. 29A includes the storage device 720 in a mold 711. FIG. 29A omits part of the electronic component to show the inside of the electronic component 700. The electronic component 700 includes a land 712 outside the mold 711. The land 712 is electrically connected to an electrode pad 713, and the electrode pad 713 is electrically connected to the storage device 720 via a wire 714. The electronic component 700 is mounted on a printed circuit board 702, for example. A plurality of such electronic components are combined and electrically connected to each other on the printed circuit board 702, which forms the circuit board 704.

The storage device 720 includes a driver circuit layer 721 and a storage circuit layer 722.

FIG. 29B is a perspective view of an electronic component 730. The electronic component 730 is an example of a SiP (System in package) or an MCM (Multi Chip Module). In the electronic component 730, an interposer 731 is provided over a package board 732 (printed circuit board) and a semiconductor device 735 and a plurality of storage devices 720 are provided over the interposer 731.

The electronic component 730 using the storage device 720 as a high bandwidth memory (HBM) is illustrated as an example. An integrated circuit (a semiconductor device) such as a CPU, a GPU, or an FPGA can be used as the semiconductor device 735.

As the package board 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings are provided in a single layer or multiple layers. The interposer 731 has a function of electrically connecting an integrated circuit provided on the interposer 731 to an electrode provided on the package board 732. Accordingly, the interposer is referred to as a “redistribution substrate” or an “intermediate substrate” in some cases. A through electrode may be provided in the interposer 731 to be used for electrically connecting the integrated circuit and the package board 732. In a silicon interposer, a TSV (Through Silicon Via) can also be used as the through electrode.

A silicon interposer is preferably used as the interposer 731. A silicon interposer can be manufactured at lower cost than an integrated circuit because it is not necessary to provide an active element. Meanwhile, since wirings of a silicon interposer can be formed through a semiconductor process, formation of minute wirings, which is difficult for a resin interposer, is easy.

In order to achieve a wide memory bandwidth, many wirings need to be connected to an HBM. Therefore, formation of minute and high-density wirings is required for an interposer on which an HBM is mounted. For this reason, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, the surface of a silicon interposer has high planarity, so that a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on an interposer.

A heat sink (radiator plate) may be provided to overlap with the electronic component 730. In the case of providing a heat sink, the heights of integrated circuits provided on the interposer 731 are preferably the same. In the electronic component 730 of this embodiment, the heights of the storage device 720 and the semiconductor device 735 are preferably the same, for example.

An electrode 733 may be provided on the bottom portion of the package board 732 to mount the electronic component 730 on another substrate. FIG. 29B illustrates an example in which the electrode 733 is formed of a solder ball. Solder balls are provided in a matrix on the bottom portion of the package board 732, whereby a BGA (Ball Grid Array) can be achieved. Alternatively, the electrode 733 may be formed of a conductive pin. When conductive pins are provided in a matrix on the bottom portion of the package board 732, a PGA (Pin Grid Array) can be achieved.

The electronic component 730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

The structure, method, and the like described in this embodiment can be used in an appropriate combination with any of other structures, methods, and the like described in this embodiment or the other embodiments.

### Embodiment 8

In this embodiment, an example of a CPU including a CPU core capable of power gating will be described.

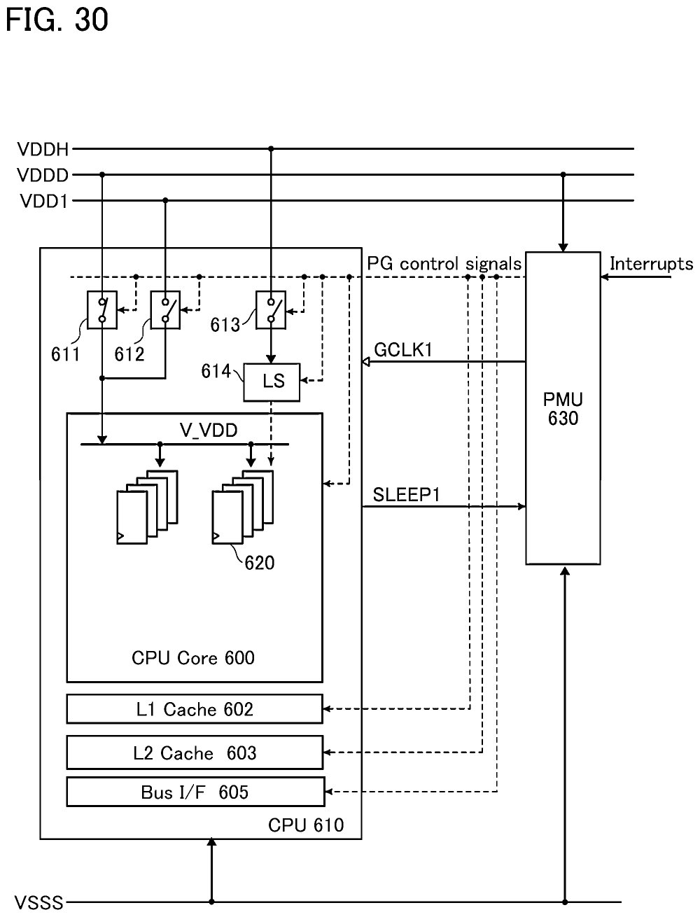

FIG. 30 illustrates a structure example of a CPU 610. The CPU 610 includes a CPU core 600, an L1 cache memory device (L1 Cache) 602, an L2 cache memory device (L2 Cache) 603, a bus interface portion (Bus I/F) 605, a power switch 611, a power switch 612, a power switch 613, and a level shifter (LS) 614. The CPU core 600 includes a flip-flop 620.

Through the bus interface portion 605, the CPU core 600, the L1 cache memory device 602, and the L2 cache memory device 603 are mutually connected to one another.

A PMU 630 generates a clock signal GCLK1 and various PG (power gating) control signals in response to signals such as an interrupt signal (Interrupts) input from the outside and a signal SLEEP1 issued from the CPU 610. The clock signal GCLK1 and the PG control signals are input to the CPU 610. The PG control signals control the power switch 611 to the power switch 613 and the flip-flop 620.

The power switch 611 and the power switch 612 control supply of a voltage VDDD and a voltage VDD1 to a virtual power supply line V_VDD (hereinafter, referred to as a V_VDD line), respectively. The power switch 613 controls supply of a voltage VDDH to the level shifter (LS) 614. A voltage VSSS is input to the CPU 610 and the PMU 630 without through the power switches. The voltage VDDD is input to the PMU 630 without through the power switches.

The voltage VDDD and the voltage VDD1 are drive voltages for a CMOS circuit. The voltage VDD1 is lower than the voltage VDDD and is a drive voltage in asleep state. The voltage VDDH is a drive voltage for an OS transistor and is higher than the voltage VDDD.

The L1 cache memory device 602, the L2 cache memory device 603, and the bus interface portion 605 each include at least a power domain capable of power gating. The power domain capable of power gating is provided with one or a plurality of power switches. These power switches are controlled by the PG control signals.

The flip-flop 620 is used for a register. The flip-flop 620 is provided with a backup circuit. The flip-flop 620 is described below.

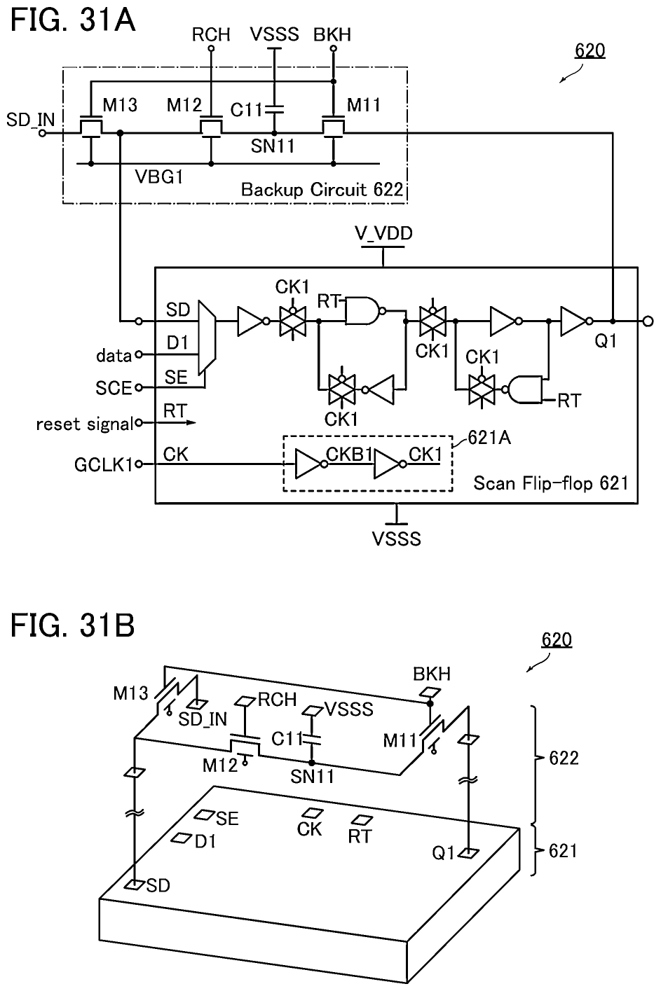

FIG. 31 illustrates a circuit structure example of the flip-flop 620. The flip-flop 620 includes a scan flip-flop 621 and a backup circuit 622.

The scan flip-flop 621 includes a node D1, a node Q1, a node SD, a node SE, a node RT, and a node CK and a clock buffer circuit 621A.

The node D1 is a data input node, the node Q1 is a data output node, and the node SD is a scan test data input node. The node SE is a signal SCE input node. The node CK is a clock signal GCLK1 input node. The clock signal GCLK1 is input to the clock buffer circuit 621A. Respective analog switches in the scan flip-flop 621 are connected to a node CK1 and a node CKB1 of the clock buffer circuit 621A. The node RT is a reset signal input node.

The signal SCE is a scan enable signal, which is generated in the PMU 630. The PMU 630 generates signals BK and RC. The level shifter 614 level-shifts the signals BK and RC to generate signals BKH and RCH. The signal BK is a backup signal and the signal RC is a recovery signal.

The circuit structure of the scan flip-flop 621 is not limited to that in FIG. 31. A flip-flop prepared in a standard circuit library can be used.

The backup circuit 622 includes a node SD_IN and a node SN11, a transistor M11 to a transistor M13, and a capacitor C11.

The node SD_IN is a scan test data input node and is connected to the node Q1 of the scan flip-flop 621. The node SN11 is a retention node of the backup circuit 622. The capacitor C11 is a storage capacitor for retaining the voltage of the node SN11.

The transistor M11 controls electrical continuity between the node Q1 and the node SN11. The transistor M12 controls electrical continuity between the node SN11 and the node SD. The transistor M13 controls electrical continuity between the node SD_IN and the node SD. The on/off of the transistors M11 and M13 is controlled by the signal BKH, and the on/off of the transistor M12 is controlled by the signal RCH.

The transistor of one embodiment of the present invention can be used as the transistor M11 to the transistor M13. The transistors M11 to M13 have back gates in the structure illustrated in this embodiment. The back gates of the transistors M11 to M13 are connected to a power supply line for supplying a voltage VBG1.

At least the transistors M11 and M12 are preferably OS transistors. Because of an extremely low off-state current, which is a feature of the OS transistor, a decrease in the voltage of the node SN11 can be suppressed and almost no power is consumed to retain data; therefore, the backup circuit 622 has a nonvolatile characteristic. Data is rewritten by charge and discharge of the capacitor C11; hence, there is theoretically no limitation on rewrite cycles of the backup circuit 622, and data can be written and read out with low energy.

All of the transistors in the backup circuit 622 are preferably OS transistors. As illustrated in FIG. 31B, the backup circuit 622 can be stacked on the scan flip-flop 621 configured with a silicon CMOS circuit.

The number of elements in the backup circuit 622 is much smaller than the number of elements in the scan flip-flop 621; thus, there is no need to change the circuit structure and layout of the scan flip-flop 621 in order to stack the backup circuit 622. That is, the backup circuit 622 is a backup circuit that has very broad utility. In addition, the backup circuit 622 can be provided in a region where the scan flip-flop 621 is formed; thus, even when the backup circuit 622 is incorporated, the area overhead of the flip-flop 620 can be zero. Thus, the backup circuit 622 is provided in the flip-flop 620, whereby power gating of the CPU core 600 is enabled. The power gating of the CPU core 600 is enabled with high efficiency owing to little energy necessary for the power gating.

When the backup circuit 622 is provided, parasitic capacitance due to the transistor M11 is added to the node Q1. However, the parasitic capacitance is lower than parasitic capacitance due to a logic circuit connected to the node Q1; thus, there is no influence on the operation of the scan flip-flop 621. That is, even when the backup circuit 622 is provided, the performance of the flip-flop 620 does not substantially decrease.

The CPU core 600 can be set to, for example, a clock gating state, a power gating state, or a resting state as a low power consumption state. The PMU 630 selects the low power consumption mode of the CPU core 600 on the basis of the interrupt signal, the signal SLEEP1, and the like. For example, in the case of transition from a normal operation state to a clock gating state, the PMU 630 stops generation of the clock signal GCLK1.

For example, in the case of transition from a normal operation state to a resting state, the PMU 630 performs voltage and/or frequency scaling. For example, when the voltage scaling is performed, the PMU 630 turns off the power switch 611 and turns on the power switch 612 to input the voltage VDD1 to the CPU core 600. The voltage VDD1 is a voltage at which data in the scan flip-flop 621 is not lost. When the frequency scaling is performed, the PMU 630 reduces the frequency of the clock signal GCLKL.

In the case where the CPU core 600 transitions from a normal operation state to a power gating state, data in the scan flip-flop 621 is backed up to the backup circuit 622. When the CPU core 600 is returned from the power gating state to the normal operation state, recovery operation of data in the backup circuit 622 to the scan flip-flop 621 is performed.

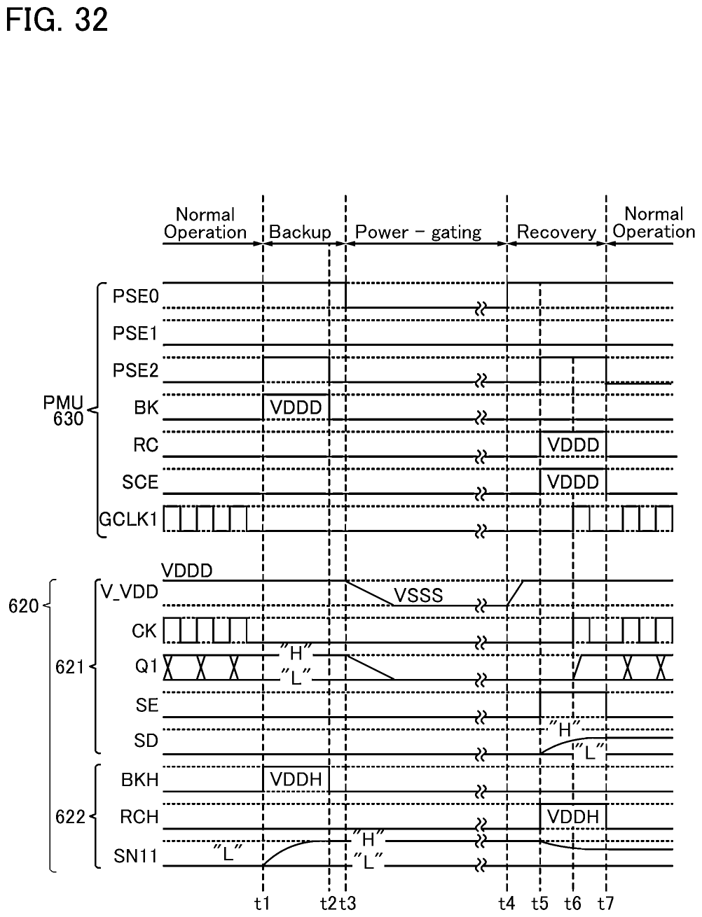

FIG. 32 shows an example of the power gating sequence of the CPU core 600. Note that in FIG. 32, t1 to t7 represent the time. A signal PSE0 to a signal PSE2 are control signals of the power switch 611 to the power switch 613, which are generated in the PMU 630. When the signal PSE0 is at “H”/“L”, the power switch 611 is on/off. The same applies to the signal PSE1 and the signal PSE2.

Before Time t1, a normal operation is performed. The power switch 611 is on, and the voltage VDDD is input to the CPU core 600. The scan flip-flop 621 performs the normal operation. At this time, the level shifter 614 does not need to be operated; thus, the power switch 613 is off and the signals SCE, BK, and RC are each at “L”. The node SE is at “L”; thus, the scan flip-flop 621 stores data in the node D1. Note that in the example of FIG. 32 the node SN11 of the backup circuit 622 is at “L” at Time t1.

A backup operation is described. At Time t1 of operation, the PMU 630 stops the clock signal GCLK1 and sets the signals PSE2 and BK to “H”. The level shifter 614 becomes active and outputs the signal BKH at “H” to the backup circuit 622.

The transistor M11 in the backup circuit 622 is turned on, and data in the node Q1 of the scan flip-flop 621 is written to the node SN11 of the backup circuit 622. When the node Q1 of the scan flip-flop 621 is at “L”, the node SN11 remains at “L”, whereas when the node Q1 is at “H”, the node SN11 becomes “H”.

The PMU 630 sets the signals PSE2 and BK to “L” at Time t2 and sets the signal PSE0 to “L at Time t3. The state of the CPU core 600 transitions to a power gating state at Time t3. Note that at the timing when the signal BK falls, the signal PSE0 may fall.

A power-gating operation is described. When the signal PSE0 is set to “L, data in the node Q1 is lost because the voltage of the V_VDD line decreases. The node SN11 retains data that is stored in the node Q1 at Time t3.

A recovery operation is described. When the PMU 630 sets the signal PSE0 to “H” at Time t4, the power gating state transitions to a recovery state. Charge of the V_VDD line starts, and the PMU 630 sets the signal PSE2, the signal RC, and the signal SCE to “H” in a state where the voltage of the V_VDD line becomes VDDD (at Time t5).

The transistor M12 is turned on, and electric charge in the capacitor C11 is distributed to the node SN11 and the node SD. When the node SN11 is at “H”, the voltage of the node SD increases. The node SE is at “H”; thus, data in the node SD is written to a latch circuit on the input side of the scan flip-flop 621. When the clock signal GCLK1 is input to the node CK at Time t6, data in the latch circuit on the input side is written to the node Q1. That is, data in the node SN11 is written to the node Q1.

When the PMU 630 sets the signal PSE2, the signal SCE, and the signal RC to “L” at Time t7, the recovery operation is terminated.

The backup circuit 622 using an OS transistor is extremely suitable for normally-off computing because both dynamic and static power consumption are low. Note that the CPU 610 including the CPU core 600 including the backup circuit 622 using an OS transistor can be referred to as NoffCPU (registered trademark). The NoffCPU includes a nonvolatile memory, and power supply can be stopped during the time when operation is not needed. Even when the flip-flop 620 is mounted, a decrease in the performance and an increase in the dynamic power of the CPU core 600 can be made hardly to occur.

Note that the CPU core 600 may include a plurality of power domains capable of power gating. In the plurality of power domains, one or a plurality of power switches for controlling voltage input are provided. In addition, the CPU core 600 may include one or a plurality of power domains where power gating is not performed. For example, the power domain where power gating is not performed may be provided with a power gating control circuit for controlling the flip-flop 620 and the power switches 611 to 613.

Note that the application of the flip-flop 620 is not limited to the CPU 610. In the CPU 610, the flip-flop 620 can be used as the register provided in a power domain capable of power gating.

At least part of the structure, method, and the like described in this embodiment can be implemented in appropriate combination with any of those in the other embodiments and the like described in this specification.

### Embodiment 9

In this embodiment, the structure of an integrated circuit 390 of one embodiment of the present invention will be described with reference to drawings.

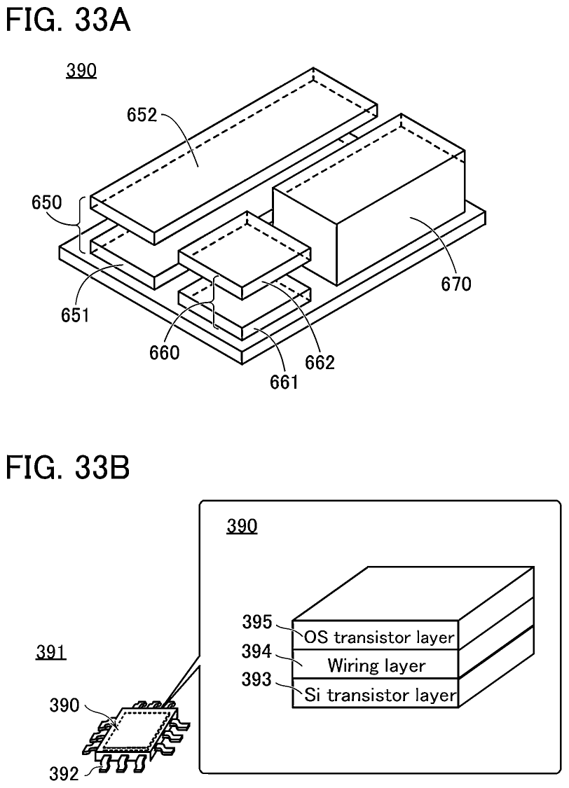

FIG. 33A is a schematic diagram illustrating an example of the integrated circuit 390. The integrated circuit 390 illustrated in FIG. 33A includes a CPU 650, a GPU 660, and a storage device 670.

The CPU 650 includes a backup circuit 652 in the upper layer of a CPU core 651. The GPU 660 includes a memory circuit portion 662 in the upper layer of an arithmetic circuit portion 661. The storage device or the like described in the above embodiment can be used as the storage device 670. In the storage device 670, a memory circuit including OS transistors is stacked over a driver circuit provided in a layer including Si transistors, whereby the memory density can be improved. As the storage device 670, for example, the semiconductor device 800 or the like can be used.

The storage device or the like described in the above embodiment can be used as the backup circuit 652. The storage device or the like described in the above embodiment can be used as the memory circuit portion 662. Although not illustrated, the storage device or the like described in the above embodiment can be used as an internal memory of the CPU core 651.

The integrated circuit 390 illustrated in FIG. 33A is an SoC (System on a Chip) semiconductor device where circuits such as the CPU 650, the GPU 660, and the storage device 670 are tightly coupled. The amount of heat generation tends to increase in SoC; an OS transistor is preferable to a Si Transistor because of having a smaller amount of change in electrical characteristics due to heat than the Si transistor. By integration of the circuits in the three-dimensional direction as illustrated in FIG. 33A, parasitic capacitance can be reduced as compared with a stacked-layer structure using a through silicon via (TSV), for example. In addition, power consumption needed for charging and discharging wirings can be reduced. Consequently, the arithmetic processing efficiency can be improved.

FIG. 33B illustrates a semiconductor chip 391 including the integrated circuit 390 as an example of a semiconductor chip. The semiconductor chip 391 includes leads 392 and the integrated circuit 390. As for the integrated circuit 390, various circuits described in the above embodiment are provided in one die as described with reference to FIG. 33A. The integrated circuit 390 has a stacked-layer structure, which is roughly divided into a layer including Si transistors (a Si transistor layer 393), a wiring layer 394, and a layer including OS transistors (an OS transistor layer 395). Since the OS transistor layer 395 can be provided to be stacked over the Si transistor layer 393, a reduction in the size of the semiconductor chip 391 is facilitated.

Although a QFP (Quad Flat Package) is used as the package of the semiconductor chip 391 in FIG. 33B, the form of the package is not limited thereto. For other structure examples, a DIP (Dual In-line Package) and a PGA (Pin Grid Array), which are of an insertion mount type; an SOP (Small Outline Package), an SSOP (Shrink Small Outline Package), a TSOP (Thin-Small Outline Package), an LCC (Leaded Chip Carrier), a QFN (Quad Flat Non-leaded Package), a BGA (Ball Grid Array), and an FBGA (Fine pitch Ball Grid Array), which are of a surface mount type; a DTP (Dual Tape carrier Package) and a QTP (Quad Tape-carrier Package), which are of a contact mount type; and the like can be used as appropriate.

All the arithmetic circuit and the switching circuit including Si transistors and the memory circuits including OS transistors can be formed in the Si transistor layer 393, the wiring layer 394, and the OS transistor layer 395. In other words, elements included in the semiconductor device can be formed through the same manufacturing process. Thus, the number of steps in the manufacturing process of the IC illustrated in FIG. 33B does not need to be increased even when the number of elements is increased, and accordingly the semiconductor device can be incorporated into the IC at low cost.

According to one embodiment of the present invention described above, a novel semiconductor device and electronic device can be provided. According to one embodiment of the present invention, a semiconductor device and an electronic device having low power consumption can be provided. According to one embodiment of the present invention, a semiconductor device and an electronic device capable of suppressing heat generation can be provided.

At least part of the structure, method, and the like described in this embodiment can be implemented in appropriate combination with any of those in the other embodiments and the like described in this specification.

### Embodiment 10

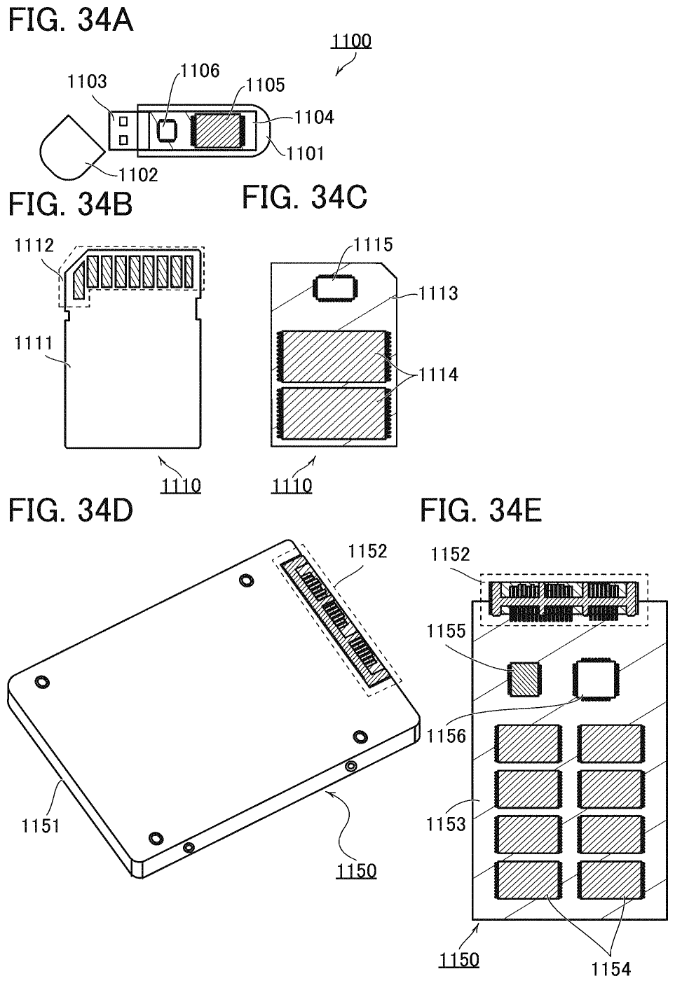

In this embodiment, application examples of the storage device using the semiconductor device described in the above embodiment are described. The semiconductor device described in the above embodiment can be applied to, for example, storage devices of a variety of electronic devices (e.g., information terminals, computers, smartphones, e-book readers, digital cameras (including video cameras), video recording/reproducing devices, and navigation systems). Here, the computers refer not only to tablet computers, notebook computers, and desktop computers, but also to large computers such as server systems. Alternatively, the semiconductor device described in the above embodiment is applied to a variety of removable storage devices such as memory cards (e.g., SD cards), USB memories, and SSDs (solid state drives). FIG. 34A to FIG. 34E schematically illustrate some structure examples of removable memory devices. The semiconductor device described in the above embodiment is processed into a packaged memory chip and used in a variety of storage devices and removable memories, for example.

FIG. 34A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The semiconductor device described in the above embodiment can be incorporated in the memory chip 1105 or the like.

FIG. 34B is a schematic external view of an SD card, and FIG. 34C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the back side of the substrate 1113, the capacity of the SD card 1110 can be increased. In addition, a wireless chip with a radio communication function may be provided on the substrate 1113. With this, data can be read from and written in the memory chip 1114 by radio communication between a host device and the SD card 1110. The semiconductor device described in the above embodiment can be incorporated in the memory chip 1114 or the like.

FIG. 34D is a schematic external view of an SSD, and FIG. 34E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip can be used, for example. When the memory chip 1154 is also provided on the back side of the substrate 1153, the capacity of the SSD 1150 can be increased. The semiconductor device described in the above embodiment can be incorporated in the memory chip 1154 or the like.

At least part of the structure, method, and the like described in this embodiment can be implemented in appropriate combination with any of those in the other embodiments and the like described in this specification.

### Embodiment 11

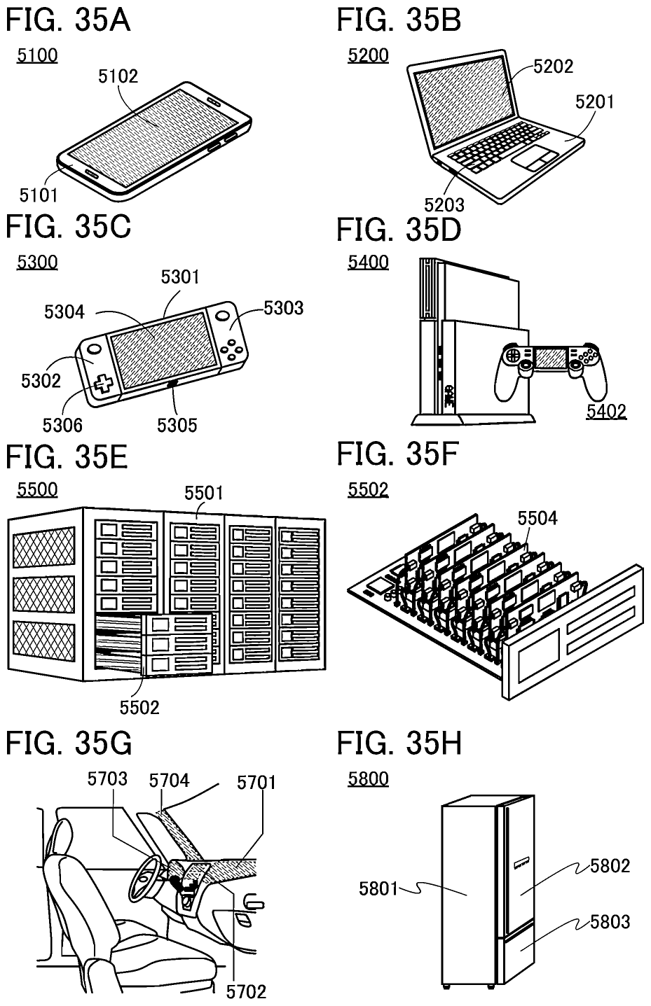

The semiconductor device of one embodiment of the present invention can be used as a chip or a processor such as a CPU or a GPU. FIG. 35A to FIG. 35H illustrate specific examples of electronic devices including a chip or a processor such as a CPU or a GPU of one embodiment of the present invention.

### <Electronic Device and System>

The GPU or the chip of one embodiment of the present invention can be mounted on a variety of electronic devices. Examples of electronic devices include a digital camera, a digital video camera, a digital photo frame, an e-book reader, a mobile phone, a portable game machine, a portable information terminal, and an audio reproducing device in addition to electronic devices provided with a relatively large screen, such as a television device, a monitor for a desktop or notebook information terminal or the like, digital signage, and a large game machine like a pachinko machine. When the GPU or the chip of one embodiment of the present invention is provided in the electronic device, the electronic device can include artificial intelligence.

The electronic device of one embodiment of the present invention may include an antenna. When a signal is received by the antenna, the electronic device can display a video, information, or the like on a display portion. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device of one embodiment of the present invention can have a variety of functions. For example, the electronic device can have a function of displaying a variety of kinds of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium. FIG. 35A to FIG. 35H illustrate examples of electronic devices.

### [Information Terminal]

FIG. 35A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

When the chip of one embodiment of the present invention is applied to the information terminal 5100, the information terminal 5100 can execute an application utilizing artificial intelligence. Examples of the application utilizing artificial intelligence include an application for recognizing a conversation and displaying the content of the conversation on the display portion 5102; an application for recognizing letters, figures, and the like input to the touch panel of the display portion 5102 by a user and displaying them on the display portion 5102; and an application for performing biometric authentication using fingerprints, voice prints, or the like.

FIG. 35B illustrates a notebook information terminal 5200. The notebook information terminal 5200 includes a main body 5201 of the information terminal, a display portion 5202, and a keyboard 5203.

Like the information terminal 5100 described above, when the chip of one embodiment of the present invention is applied to the notebook information terminal 5200, the notebook information terminal 5200 can execute an application utilizing artificial intelligence. Examples of the application utilizing artificial intelligence include design-support software, text correction software, and software for automatic menu generation. Furthermore, with use of the notebook information terminal 5200, novel artificial intelligence can be developed.

Note that although FIG. 35A and FIG. 35B illustrate a smartphone and a notebook information terminal, respectively, as examples of the electronic device in the above description, an information terminal other than a smartphone and a notebook information terminal can be used. Examples of information terminals other than a smartphone and a notebook information terminal include a PDA (Personal Digital Assistant), a desktop information terminal, and a workstation.

### [Game Machines]

FIG. 35C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), an image to be output to the display portion 5304 can be output to another video device (not illustrated). In that case, the housing 5302 and the housing 5303 can each function as an operating unit. Thus, a plurality of players can play a game at the same time. The chip described in the above embodiment can be incorporated into the chip or the like provided on a substrate in the housing 5301, the housing 5302 and the housing 5303.

FIG. 35D illustrates a stationary game machine 5400 as an example of a game machine. A controller 5402 is wired or connected wirelessly to the stationary game machine 5400.

Using the GPU or the chip of one embodiment of the present invention in a game machine such as the portable game machine 5300 and the stationary game machine 5400 achieves a low-power-consumption game machine. Moreover, heat generation from a circuit can be reduced owing to low power consumption; thus, the influence of heat generation on the circuit itself, a peripheral circuit, and a module can be reduced.

Furthermore, when the GPU or the chip of one embodiment of the present invention is applied to the portable game machine 5300, the portable game machine 5300 including artificial intelligence can be achieved.

In general, the progress of a game, the actions and words of game characters, and expressions of an event and the like occurring in the game are determined by the program in the game; however, the use of artificial intelligence in the portable game machine 5300 enables expressions not limited by the game program. For example, it becomes possible to change expressions such as questions posed by the player, the progress of the game, time, and actions and words of game characters.

In addition, when a game requiring a plurality of players is played on the portable game machine 5300, the artificial intelligence can create a virtual game player; thus, the game can be played alone with the game player created by the artificial intelligence as an opponent.

Although the portable game machine and the stationary game machine are shown as examples of game machines in FIG. 35C and FIG. 35D, the game machine using the GPU or the chip of one embodiment of the present invention is not limited thereto. Examples of the game machine to which the GPU or the chip of one embodiment of the present invention is applied include an arcade game machine installed in entertainment facilities (a game center, an amusement park, and the like), and a throwing machine for batting practice installed in sports facilities.

### [Large Computer]

The GPU or the chip of one embodiment of the present invention can be used in a large computer.

FIG. 35E is a diagram illustrating a supercomputer 5500 as an example of a large computer. FIG. 35F is a diagram illustrating a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504 on which the GPU or the chip shown in the above embodiment can be mounted.

The supercomputer 5500 is a large computer mainly used for scientific computation. In scientific computation, an enormous amount of arithmetic operation needs to be processed at a high speed; hence, power consumption is large and chips generate a large amount of heat. Using the GPU or the chip of one embodiment of the present invention in the supercomputer 5500 achieves a low-power-consumption supercomputer. Moreover, heat generation from a circuit can be reduced owing to low power consumption; thus, the influence of heat generation on the circuit itself, a peripheral circuit, and a module can be reduced.

Although a supercomputer is shown as an example of a large computer in FIG. 35E and FIG. 35F, a large computer using the GPU or the chip of one embodiment of the present invention is not limited thereto. Other examples of large computers in which the GPU or the chip of one embodiment of the present invention is usable include a computer that provides service (a server) and a large general-purpose computer (a mainframe).

### [Moving Vehicle]

The GPU or the chip of one embodiment of the present invention can be applied to an automobile, which is a moving vehicle, and the periphery of a driver's seat in the automobile.

FIG. 35G illustrates an area around a windshield inside an automobile, which is an example of a moving vehicle. FIG. 35G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, mileage, a fuel gauge, a gear state, air-condition setting, and the like. In addition, the content, layout, or the like of the display on the display panels can be changed as appropriate to suit the user's preference, so that the design quality can be increased. The display panel 5701 to the display panel 5703 can also be used as lighting devices.

The display panel 5704 can compensate for view obstructed by the pillar (a blind spot) by showing an image taken by an imaging device (not illustrated) provided for the automobile. That is, displaying an image taken by the imaging device provided outside the automobile leads to compensation for the blind spot and an increase in safety. Display of an image that complements for the area that cannot be seen makes it possible to confirm safety more naturally and comfortably. The display panel 5704 can also be used as a lighting device.

Since the GPU or the chip of one embodiment of the present invention can be applied to a component of artificial intelligence, the chip can be used for an automatic driving system of the automobile, for example. The chip can also be used for a system for navigation, risk prediction, or the like. A structure may be employed in which the display panel 5701 to the display panel 5704 display navigation information, risk prediction information, or the like.

Note that although an automobile is described above as an example of a moving vehicle, the moving vehicle is not limited to an automobile. Examples of the moving vehicle include a train, a monorail train, a ship, and a flying vehicle (a helicopter, an unmanned aircraft (a drone), an airplane, and a rocket), and these moving vehicles can each include a system utilizing artificial intelligence when the chip of one embodiment of the present invention is applied to each of these moving vehicles.

### [Household Appliance]

FIG. 35H illustrates an electric refrigerator-freezer 5800 as an example of a household appliance. The electric refrigerator-freezer 5800 includes a housing 5801, a refrigerator door 5802, a freezer door 5803, and the like.

When the chip of one embodiment of the present invention is applied to the electric refrigerator-freezer 5800, the electric refrigerator-freezer 5800 including artificial intelligence can be achieved. Utilizing the artificial intelligence enables the electric refrigerator-freezer 5800 to have a function of automatically making a menu based on foods stored in the electric refrigerator-freezer 5800, expiration dates of the foods, or the like, a function of automatically adjusting temperature to be appropriate for the foods stored in the electric refrigerator-freezer 5800, and the like.

Although the electric refrigerator-freezer is described in this example as a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic devices, the functions of the electronic devices, the application examples of artificial intelligence, their effects, and the like described in this embodiment can be combined as appropriate with the description of another electronic device.

At least part of the structure, method, and the like described in this embodiment can be implemented in appropriate combination with any of those in the other embodiments and the like described in this specification.

### REFERENCE NUMERALS

M1: transistor, M2: transistor, M3: transistor, M4: transistor, M5: transistor, M6: transistor, M11: transistor, M12: transistor, M13: transistor, 10: semiconductor device, 10_n: element layer, 10_n−1: element layer, 10_1: element layer, 11: insulator, 11a: insulator, 11b: insulator, 12: oxide semiconductor element, 13: structure body, 14: conductor, 15: conductor, 15A: conductive film, 18: insulator, 18a: insulator, 18b: insulator, 19: opening, 21: insulator, 21a: insulator, 21b: insulator, 24: insulator, 25: opening, 27: opening, 28: insulator, 28a: insulator, 28b: insulator, 100: capacitor, 110: conductor, 112: conductor, 120: conductor, 130: insulator, 150: insulator, 158: conductor, 160: insulator, 162: conductor, 164: insulator, 166: conductor, 168: insulator, 168a: insulator, 168b: insulator, 200: transistor, 205: conductor, 205a: conductor, 205b: conductor, 210: insulator, 212: insulator, 212a: insulator, 212b: insulator, 214: insulator, 216: insulator, 217: insulator, 218: conductor, 222: insulator, 224: insulator, 230: oxide, 230a: oxide, 230b: oxide, 230ba: region, 230bb: region, 230bc: region, 240: conductor, 240a: conductor, 240b: conductor, 241: insulator, 241a: insulator, 241b: insulator, 242: conductor, 242a: conductor, 242b: conductor, 246: conductor, 246a: conductor, 246b: conductor, 250: insulator, 250a: insulator, 250b: insulator, 252: insulator, 254: insulator, 260: conductor, 260a: conductor, 260b: conductor, 265: sealing portion, 271: insulator, 271a: insulator, 271b: insulator, 274: insulator, 275: insulator, 280: insulator, 282: insulator, 283: insulator, 285: insulator, 286: insulator, 286a: insulator, 286b: insulator, 287: insulator, 288: insulator, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 390: integrated circuit, 391: semiconductor chip, 392: lead, 393: Si transistor layer, 394: wiring layer, 395: OS transistor layer, 400: opening region, 500: semiconductor device, 600: CPU core, 602: cache memory device, 603: cache memory device, 605: bus interface portion, 610: CPU, 611: power switch, 612: power switch, 613: power switch, 614: level shifter, 620: flip-flop, 621: scan flip-flop, 621A: clock buffer circuit, 622: backup circuit, 630: PMU, 650: CPU, 651: CPU core, 652: backup circuit, 660: GPU, 661: arithmetic circuit portion, 662: memory circuit portion, 670: storage device, 700: electronic component, 702: printed circuit board, 704: circuit board, 711: mold, 712: land, 713: electrode pad, 714: wire, 720: storage device, 721: driver circuit layer, 722: storage circuit layer, 730: electronic component, 731: interposer, 732: package board, 733: electrode, 735: semiconductor device, 800: semiconductor device, 800A: semiconductor device, 800B: semiconductor device, 811: silicon substrate, 820: peripheral circuit, 821: row driver, 822: column driver, 822a: precharge circuit, 822b: sense amplifier, 822c: selection switch, 823_A: switch, 823_B: switch, 824_1: transistor, 824_3: transistor, 825_1: transistor, 825_2: transistor, 825_3: transistor, 825_4: transistor, 829: circuit, 830: memory cell array, 831: memory cell, 831_N: memory cell, 831_N_A: memory cell, 831_N_B: memory cell, 831_1: memory cell, 832: transistor, 832_N: transistor, 832_1: transistor, 832A: transistor, 832B: transistor, 833: capacitor, 833_N: capacitor, 833_1: capacitor, 834: element layer, 834_N: element layer, 834_1: element layer, 834_2: element layer, 834_4: element layer, 834_5: element layer, 1001: wiring, 1002: wiring, 1003: wiring, 1004: wiring, 1005: wiring, 1006: wiring, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1200: chip, 1201: package board, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 1400: storage device, 1411: peripheral circuit, 1420: row circuit, 1430: column circuit, 1440: output circuit, 1460: control logic circuit, 1470: memory cell array, 1471: memory cell, 1472: memory cell, 1473: memory cell, 1474: memory cell, 1475: memory cell, 1476: memory cell, 1477: memory cell, 1478: memory cell, 5100: information terminal, 5101: housing, 5102: display portion, 5200: notebook information terminal, 5201: main body, 5202: display portion, 5203: keyboard, 5300: portable game machine, 5301: housing, 5302: housing, 5303: housing, 5304: display portion, 5305: connection portion, 5306: operation key, 5400: stationary game machine, 5402: controller, 5500: supercomputer, 5501: rack, 5502: computer, 5504: substrate, 5701: display panel, 5702: display panel, 5703: display panel, 5704: display panel, 5800: electric refrigerator-freezer, 5801: housing, 5802: refrigerator door, 5803: freezer door

1. A semiconductor device comprising a first device layer to an n-th (n is a natural number of 2 or more) device layer which are stacked over a substrate in order,
wherein each of the first device layer to the n-th device layer comprises a first barrier insulating film, a second barrier insulating film, a third barrier insulating film, an oxide semiconductor device, a first conductor, and a second conductor, and
wherein in each of the first device layer to the n-th device layer,
the oxide semiconductor device is placed over the first barrier insulating film,
the second barrier insulating film is placed to cover the oxide semiconductor device,
the first conductor is placed so as to be electrically connected to the oxide semiconductor device through an opening formed in the second barrier insulating film,
the second conductor is placed over the first conductor,
the third barrier insulating film is placed over the second conductor and the second barrier insulating film, and
the first barrier insulating film to the third barrier insulating film arg configured to inhibit diffusion of hydrogen.

2. The semiconductor device according to claim 1,
wherein the second barrier insulating film is in contact with the first barrier insulating film in a region where the second barrier insulating film does not overlap with the oxide semiconductor device.

3. A semiconductor device comprising a first device layer to an n-th (n is a natural number of 2 or more) device layer which are stacked over a substrate in order,
wherein each of the first device layer to the n-th device layer comprises a first barrier insulating film, a second barrier insulating film, a third barrier insulating film, an oxide semiconductor device, a first conductor, and a second conductor,
wherein in each of the first device layer to the n-th device layer,
the oxide semiconductor device is placed over the first barrier insulating film,
the second barrier insulating film is placed over the oxide semiconductor device,
the first conductor is placed so as to be electrically connected to the oxide semiconductor device through an opening formed in the second barrier insulating film,
the second conductor is placed over the first conductor,
the third barrier insulating film is placed over the second conductor and the second barrier insulating film, and
the first barrier insulating film to the third barrier insulating film arg configured to inhibit diffusion of hydrogen,
wherein an opening reaching the first barrier insulating film in the first device layer is formed in the first device layer to the n-th device layer,
wherein the opening is provided so as to surround the oxide semiconductor devices in the first device layer to the n-th device layer, and
wherein the second barrier insulating film in the n-th device layer is provided to cover the oxide semiconductor devices in the first device layer to the n-th device layer.

4. The semiconductor device according to claim 3,
wherein the second barrier insulating film in the n-th device layer is in contact with the first barrier insulating film in the first device layer in a region where the second barrier insulating film in the n-th device layer does not overlap with the oxide semiconductor device in the first device layer to the n-th device layer.

5. The semiconductor device according to claim 1,
wherein the first barrier insulating film to the third barrier insulating film are silicon nitride.

6. The semiconductor device according to claim 1,
wherein the third barrier insulating film comprises a first layer and a second layer over the first layer, and
wherein the first layer has a lower hydrogen concentration than the second layer.

7. The semiconductor device according to claim 6,
wherein the first layer is an insulating film formed by a sputtering method.

8. The semiconductor device according to claim 6,
wherein the second layer is an insulating film formed by a PEALD method.

9. A semiconductor device comprising a first device layer to an n-th (n is a natural number of 2 or more) device layer which are stacked over a substrate in order,
wherein each of the first device layer to the n-th device layer comprises an oxide semiconductor device, a first conductor, and a second conductor,
wherein the first device layer comprises a first barrier insulating film under the oxide semiconductor device,
wherein the n-th device layer comprises a second barrier insulating film over the second conductor,
wherein the first barrier insulating film and the second barrier insulating film are configured to inhibit diffusion of hydrogen,
wherein in each of the first device layer to the n-th device layer,
the first conductor is placed over the oxide semiconductor device so as to be electrically connected to the oxide semiconductor device, and
the second conductor is placed over the first conductor,
wherein an opening reaching the first barrier insulating film in the first device layer is formed in the first device layer to the n-th device layer,
wherein the opening is provided so as to surround the oxide semiconductor device in the first device layer to the n-th device layer, and
wherein the second barrier insulating film in the n-th device layer is provided to cover the oxide semiconductor device in the first device layer to the n-th device layer.

10. The semiconductor device according to claim 9,
wherein the second barrier insulating film in the n-th device layer is in contact with the first barrier insulating film in the first device layer in a region where the second barrier insulating film in the n-th device layer does not overlap with the oxide semiconductor device in the first device layer to the n-th device layer.

11. The semiconductor device according to claim 9,
wherein the first barrier insulating film and the second barrier insulating film are silicon nitride.

12. The semiconductor device according to claim 9,
wherein the second barrier insulating film comprises a first layer and a second layer over the first layer, and
wherein the first layer has a lower hydrogen concentration than the second layer.

13. The semiconductor device according to claim 12,
wherein the first layer is an insulating film formed by a sputtering method.

14. The semiconductor device according to claim 12,
wherein the second layer is an insulating film formed by a PEALD method.

15. The semiconductor device according claim 1,
wherein the first conductor is placed so as to be embedded in an interlayer insulating film formed over the oxide semiconductor device.

16. The semiconductor device according to claim 1,
wherein the substrate is a silicon substrate.

17. The semiconductor device according to claim 1,
wherein a transistor is formed on the substrate.

18. The semiconductor device according to claim 1,
wherein the oxide semiconductor film included in the oxide semiconductor device comprises one or more of In, Ga, and Zn.
